(19) United States
(12) Patent Application Publication
(10) Pub. No.: US 2014/0306203 A1
(43) Pub. Date: Oct. 16, 2014

(54) METAL COMPLEX AND LIGHT-EMITTING DEVICE COMPRISING THE METAL COMPLEX

(71) Applicants: Sumitomo Chemical Company, Limited, Tokyo (JP); National Institute of Advanced Industrial Science and Technology, Tokyo (JP); Cambridge Display Technology Limited, Cambridgeshire (GB)

(72) Inventors: Nobuhiko AKINO, Ibaraki (JP); Taichi ABE, Ibaraki (JP); Hideo KONNO, Ibaraki (JP); Annette Regine STEUDEL, Cambridgeshire (GB); Kiran Timothy KAMTEKAR, Cambridgeshire (GB)

(73) Assignees: Sumitomo Chemical Company, Limited, Tokyo (JP); National Institute of Advanced Industrial Science and Technology, Tokyo (JP); Cambridge Display Technology Limited, Cambridgeshire (GB)

(21) Appl. No.: 14/250,792

(22) Filed: Apr. 11, 2014

(30) Foreign Application Priority Data
Apr. 15, 2013 (JP) 2013-084955

(51) Int. Cl. H01L 51/00; H01L 51/50

(52) U.S. Cl. CPC H01L 51/0085; H01L 51/50
USPC 257/40; 252/519.21; 548/103

(57) ABSTRACT

A metal complex is provided represented by Formula (1):

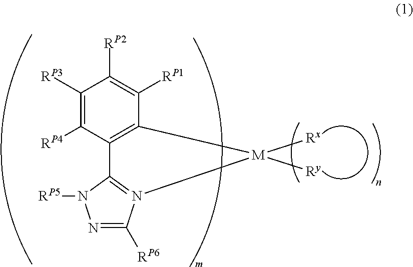

wherein
M represents a prescribed metal atom;
R^{P1}, R^{P2}, R^{P3}, R^{P4}, R^{P5}, and R^{P6} each independently represent a hydrogen atom or a prescribed group, wherein R^{P1} and R^{P2} may be bonded together to form a ring structure, R^{P2} and R^{P3} may be bonded together to form a ring structure, and R^{P3} and R^{P4} may be bonded together to form a ring structure, provided that at least one of R^{P1}, R^{P2}, R^{P3}, and R^{P4} is a dendron and at least one of R^{P5} and R^{P6} is an aryl group or a monovalent heterocyclic group;
m is an integer of 1 to 3 and n is an integer of 0 to 2, wherein m+n is 2 or 3; and
a moiety represented by Formula (2) represents a bidentate ligand:

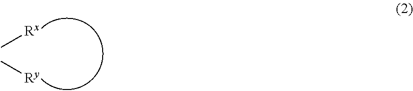

wherein R^{x} and R^{y} each independently represent a prescribed atom.

### CROSS-REFERENCE TO RELATED APPLICATIONS

This application is based upon and claims the benefit of priority to Japanese Patent Application No. 2013-084955, filed Apr. 15, 2013, the entire contents of which are incorporated herein by reference.

### BACKGROUND OF THE INVENTION

1. Field of the Invention

The present invention relates to a metal complex and a light-emitting device comprising the metal complex.

2. Description of the Related Art

A metal complex exhibiting light emission (phosphorescent light emission) from a triplet excited state is known as a light-emitting material used for the light-emitting layer of an organic electroluminescent device (hereinafter, may be abbreviated as “light-emitting device”). The metal complex can be expected to have a luminous efficiency higher than that of a fluorescent material exhibiting light emission from a singlet excited state. For example, FIrpic which is a metal complex having an iridium atom as a metal atom (International Publication No. 2002/15645) and a metal complex having a ligand comprising a triazole ring (International Publication No. 2004/101707 and International Publication No. 2012/070596) are known as a blue light-emitting metal complex exhibiting light emission (phosphorescent light emission) from a triplet excited state.

### SUMMARY OF THE INVENTION

To put an organic electroluminescent device using metal complexes into practical use, the development of metal complexes useful for the manufacture of a light-emitting device has been desired in three primary colors of red, green, and blue. The development of a metal complex useful for the manufacture of a light-emitting device having an excellent luminous efficiency, particularly in a blue region, has been desired in comparison with red and green. Thus, the present invention provides a metal complex useful for the manufacture of a light-emitting device having an excellent luminous efficiency, particularly in a blue region. The present invention also provides a light-emitting device using the metal complex.

As one aspect of the present invention, a metal complex is provided, and the metal complex is represented by Formula (1):

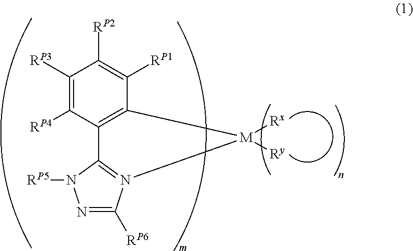

wherein

M represents a ruthenium atom, a rhodium atom, a palladium atom, an osmium atom, an iridium atom, or a platinum atom;

R^{P1}, R^{P2}, R^{P3}, R^{P4}, R^{P5}, and R^{P6} each independently represent a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, a carbamoyl group, an amido group, an acid imido group, an imine residue, a substituted amino group, a substituted silyl group, a substituted silyloxy group, a substituted silylthio group, a substituted silylamino group, a monovalent heterocyclic group, a heteroaryloxy group, a heteroarylthio group, an arylalkenyl group, an arylalkynyl group, a substituted carboxy group, or a cyano group, wherein R^{P1} and R^{P2} may be bonded to each other to form a ring structure together with carbon atoms to which R^{P1} and R^{P2} are individually bonded, R^{P2} and R^{P3} may be bonded to each other to form a ring structure together with carbon atoms to which R^{P2} and R^{P3} are individually bonded, and R^{P3} and R^{P4} may be bonded to each other to form a ring structure together with carbon atoms to which R^{P3} and R^{P4} are individually bonded, with the proviso that at least one of R^{P1}, R^{P2}, R^{P3}, and R^{P4} is a dendron and at least one of R^{P5} and R^{P6} is an aryl group or a monovalent heterocyclic group;

m is an integer of 1 to 3 and n is an integer of 0 to 2, wherein m+n is 2 or 3; and
a moiety represented by Formula (2) represents a bidentate ligand:

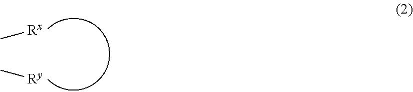

wherein R^{x} and R^{y} are atoms bonded to a metal atom M and each independently represent a carbon atom, an oxygen atom, or a nitrogen atom.

As another aspect of the present invention, a composition is provided, and the composition comprises the above-mentioned metal complex and a charge transport material.

Additionally, as another aspect of the present invention, a composition is provided, and the composition comprises: the above-mentioned metal complex; and a solvent or a dispersion medium.

Additionally, as another aspect of the present invention, a film is provided, and the film comprises the above-mentioned metal complex.

Additionally, as another aspect of the present invention, a light-emitting device is provided, and a light-emitting device comprising: electrodes including an anode and a cathode; and a layer that is provided between the electrodes and that contains the above-mentioned metal complex.

Additionally, as another aspect of the present invention, a planar light source and an illumination apparatus are provided, they each comprise the above-mentioned light-emitting device.

The present invention can provide a metal complex useful for the manufacture of a light-emitting device having an excellent luminous efficiency, particularly in a blue region. According to a preferred embodiment of the present invention, a metal complex useful for the manufacture of a light-emitting device having excellent brightness lifetime, particularly in a blue region, can be provided. Furthermore, the present invention can provide a light-emitting device using the metal complex.

### DETAILED DESCRIPTION OF THE PREFERRED EMBODIMENTS

The present invention is described below in detail.

In the present specification, Me represents a methyl group; Et represents an ethyl group; n-Pr represents an n-propyl group; i-Pr represents an isopropyl group; n-Bu represents an n-butyl group; tBu, t-Bu, and a t-butyl group each represent a tert-butyl group; and t-octyl represents a group represented by the formula below. In the present specification, a hydrogen atom may be a deuterium atom.

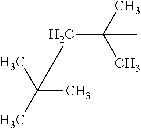

<Metal Complex>

The metal complex of the present invention is described.

The metal complex of the present invention is a metal complex comprising m ligand(s), which is comprised of a benzene ring and a triazole ring. Specifically, it is the metal complex represented by Formula (1).

The metal complex represented by Formula (1) is comprised of ligand(s) the number of which is defined by a subscript m and bidentate ligand(s) represented by Formula (2) the number of which is defined by a subscript n. Hereinafter, a simple expression “ligand” means both the ligand the number of which is defined by the subscript m and the bidentate ligand the number of which is defined by the subscript n.

In Formula (1), m is an integer of 1 to 3, and n is an integer of 0 to 2, wherein m+n is 2 or 3, preferably n is 0 or 1, and more preferably n is 0, wherein m+n which is the total number of ligands which can be boned to the metal atom M is to satisfy the valence of the metal atom M. For example, when the metal atom is an iridium atom, m is 1, 2, or 3, n is 0, 1, or 2, and m+n is 3. Preferably, m=3 and n=0, or m=2 and n=1, and more preferably, m=3 and n=0. The metal atom M can be coordinated to a nitrogen atom of the triazole ring and can be covalently bonded to a carbon atom of the benzene ring. The solid lines extending from M indicate such bonds (the same shall apply hereinafter).

The metal complex represented by Formula (1) is preferably a metal complex represented by Formula (3) below (i.e. n=0).

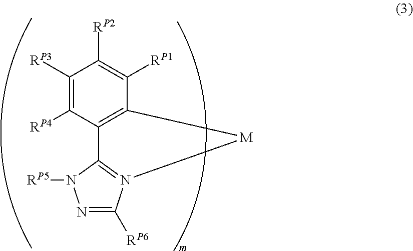

In Formula (3), M, R^{P1}, R^{P2}, R^{P3}, R^{P4}, R^{P5}, R^{P6}, and m are the same as defined above.

In the metal complex of the present invention, R^{P1}, R^{P2}, R^{P3}, R^{P4}, R^{P5}, and R^{P6} each independently represent a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, a carbamoyl group, an amido group, an acid imido group, an imine residue, a substituted amino group, a substituted silyl group, a substituted silyloxy group, a substituted silylthio group, a substituted silylamino group, a monovalent heterocyclic group, a heteroaryloxy group, a heteroarylthio group, an arylalkenyl group, an arylalkynyl group, a substituted carboxy group, or a cyano group. R^{P1} and R^{P2} may be bonded to each other to form a ring structure together with carbon atoms to which R^{P1} and R^{P2} are individually bonded, R^{P2} and R^{P3} may be bonded to each other to form a ring structure together with carbon atoms to which R^{P2} and R^{P3} are individually bonded, and R^{P3} and R^{P4} may be bonded to each other to form a ring structure together with carbon atoms to which R^{P3} and R^{P4} are individually bonded. At least one of R^{P1}, R^{P2}, R^{P3}, and R^{P4} is a dendron described below, and at least one of R^{P5} and R^{P6} is an aryl group or a monovalent heterocyclic group.

R^{P1}, R^{P2}, R^{P3}, R^{P4}, R^{P5}, and R^{P6} are preferably a hydrogen atom, a halogen atom, an alkyl group, an alkyloxy group, an aryl group, or a monovalent heterocyclic group, and more preferably a hydrogen atom, an alkyl group, an aryl group, or a monovalent heterocyclic group.

At least one of R^{P5} and R^{P6} is an aryl group or a monovalent heterocyclic group, and preferably R^{P5} is an aryl group or a monovalent heterocyclic group. The monovalent heterocyclic group is preferably a monovalent aromatic heterocyclic group. R^{P5} is more preferably an aryl group, further preferably a phenyl group optionally having a substituent, and particularly preferably a phenyl group comprising an alkyloxy group with the number of carbon atom(s) of 1 to 12 as a substituent or a phenyl group comprising an alkyl group with the number of carbon atom(s) of 1 to 12 as a substituent. When R^{P5} is an aryl group or a monovalent heterocyclic group, R^{P6} is preferably an alkyl group.

In the metal complex of the present invention, at least one of R^{P1}, R^{P2}, R^{P3}, and R^{P4} is a dendron for enhancing the solubility of the metal complex in an organic solvent and the application and film formation properties and/or for introducing further functionalities (for example, a charge transport property) into the metal complex.

In the present invention, the dendron means a group having a regular dendritic-branched-structure (dendrimer structure) which has a branching point of an atom or a ring. In the metal complex of the present invention, the atom or the ring is directly bonded to a carbon atom constituting the benzene ring in Formula (1), and preferably, the ring is directly bonded to a carbon atom constituting the benzene ring in Formula (1). A highly branched giant molecule having dendrons may be called a dendrimer. Such a giant molecule is described in, for example, WO02/066575, WO02/066552, and WO02/067343 and is designed and synthesized for the purpose of imparting various functions. Examples of such a dendron may include a group having a unit structure represented by Formula (D-a) below and a group having a unit structure represented by Formula (D-b) below. Preferably, the dendron is a group having a unit structure represented by Formula (D-a).

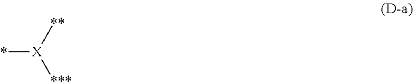

In Formula (D-a), the symbols of *, **, and *** each represent a bond, and X represents a trivalent atom or a trivalent cyclic group, and X is preferably a trivalent cyclic group.

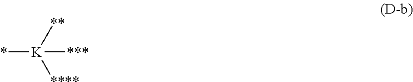

In Formula (D-b), the symbols of *, **, ***, and **** each represent a bond, and K represents a tetravalent atom or a tetravalent cyclic group, and K is preferably a tetravalent cyclic group.

As described above, in the metal complex of the present invention, a trivalent atom or a trivalent cyclic group represented by X constituting a dendron or a tetravalent atom or a tetravalent cyclic group represented by K constituting a dendron, is directly bonded to a carbon atom constituting the benzene ring in Formula (1) through the bond *. Accordingly, the metal complex of the present invention does not correspond to a structure in which a trivalent atom or a trivalent cyclic group represented by X or a tetravalent atom or a tetravalent cyclic group represented by K, is not directly bonded to a carbon atom constituting the benzene ring in Formula (1) through the bond *, for example, a structure in which a unit structure represented by Formula (D-a′) or a unit structure represented by Formula (D-b′) is directly bonded to a carbon atom constituting the benzene ring in Formula (1) through the bond *.

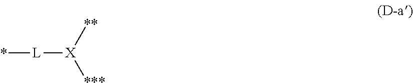

In Formula (D-a′), the symbols of *, **, and *** each represent a bond; X represents a trivalent atom or a trivalent cyclic group; and L represents a divalent atom or a divalent cyclic group.

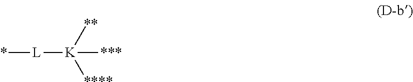

In Formula (D-b′), the symbols of *, **, ***, and **** each represent a bond; K represents a tetravalent atom or a tetravalent cyclic group; and L represents a divalent atom or a divalent cyclic group.

In Formula (D-a), the atom represented by X is a trivalent atom. Examples thereof may include a nitrogen atom, a phosphorus atom, a carbon atom bonded with one hydrogen atom, and a silicon atom bonded with one hydrogen atom.

The ring represented by X is a trivalent cyclic group. Examples thereof may include a trivalent non-aromatic carbocyclic group, a trivalent aromatic carbocyclic group, and a trivalent heterocyclic group. The trivalent non-aromatic carbocyclic group may be, for example, a trivalent cyclic alkyl group. The trivalent cyclic alkyl group is the same as a group remaining after removing two hydrogen atoms from a cyclic alkyl group described below with respect to R^{P1}, R^{P2}, R^{P3}, R^{P4}, R^{P5}, and R^{P6}. Examples and preferred examples thereof conform to such a cyclic alkyl group. The trivalent aromatic carbocyclic group is the same as a group remaining after removing two hydrogen atoms from an aryl group described below with respect to R^{P1}, R^{P2}, R^{P3}, R^{P4}, R^{P5}, and R^{P6}. Examples and preferred examples thereof conform to such an aryl group. The trivalent heterocyclic group is the same as a group remaining after removing two hydrogen atoms from a monovalent heterocyclic group described below with respect to R^{P1}, R^{P2}, R^{P3}, R^{P4}, R^{P5}, and R^{P6}. Examples and preferred examples thereof conform to such a monovalent heterocyclic group. The atom or the ring represented by X is preferably a trivalent aromatic carbocyclic group or a trivalent heterocyclic group, more preferably a trivalent aromatic carbocyclic group or a trivalent aromatic heterocyclic group, further preferably a trivalent aromatic carbocyclic group, and particularly preferably a trivalent group remaining after removing three hydrogen atoms directly bonded to carbon atoms constituting a benzene ring from the benzene ring.

In Formula (D-b), the atom represented by K is a tetravalent atom. Examples thereof may include a carbon atom and a silicon atom. The ring represented by K is a tetravalent cyclic group. Examples thereof may include a tetravalent non-aromatic carbocyclic group, a tetravalent aromatic carbocyclic group, and a tetravalent heterocyclic group. The tetravalent non-aromatic carbocyclic group may be, for example, a tetravalent cyclic alkyl group. The tetravalent cyclic alkyl group is the same as a group remaining after removing three hydrogen atoms from a cyclic alkyl group described below with respect to R^{P1}, R^{P2}, R^{P3}, R^{P4}, R^{P5}, and R^{P6}. Examples and preferred examples thereof conform to such a cyclic alkyl group. The tetravalent aromatic carbocyclic group is the same as a group remaining after removing three hydrogen atoms from an aryl group described below with respect to R^{P1}, R^{P2}, R^{P3}, R^{P4}, R^{P5}, and R^{P6}. Examples and preferred examples thereof conform to such an aryl group. The tetravalent heterocyclic group is the same as a group remaining after removing three hydrogen atoms from a monovalent heterocyclic group described below with respect to R^{P1}, R^{P2}, R^{P3}, R^{P4}, R^{P5}, and R^{P6}. Examples and preferred examples thereof conform to such a monovalent heterocyclic group. The atom or the cyclic group represented by K is preferably a tetravalent aromatic carbocyclic group or a tetravalent heterocyclic group, more preferably a tetravalent aromatic carbocyclic group or a tetravalent aromatic heterocyclic group, further preferably a tetravalent aromatic carbocyclic group, and particularly preferably a tetravalent group remaining after removing four hydrogen atoms directly bonded to a carbon atom constituting a benzene ring from the benzene ring.

The degree of branching of the dendrimer structure is called a “generation”. Although the dendron is not limited so long as the dendron has a branching structure having one or more generation(s), the number of generations is 1 to 4, preferably 1 to 3, more preferably 1 or 2, and further preferably 1. For example, a dendron having a branching structure of a first generation is represented by Formula (D-a-g1) below or Formula (D-b-g1) below and a dendron having a branching structure of a second generation is represented by Formula (D-a-g2) or Formula (D-b-g2):

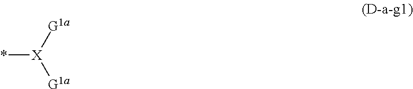

In Formula (D-a-g1), the symbol of * represents a bond; X represents a trivalent atom or a trivalent cyclic group and is preferably a trivalent cyclic group; and two G^{1a}s each represent a monovalent group and may be the same as or different from each other;

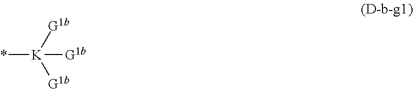

In Formula (D-b-g1), the symbol of * represents a bond; K represents a tetravalent atom or a tetravalent cyclic group and is preferably a tetravalent cyclic group; and three G^{1b}s each represent a monovalent group and may be the same as or different from each other;

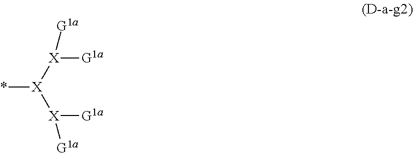

In Formula (D-a-g2), the symbol of * represents a bond; X represents a trivalent atom or a trivalent cyclic group and is preferably a trivalent cyclic group; and four G^{1a}s each represent a monovalent group and may be the same as or different from each other; and

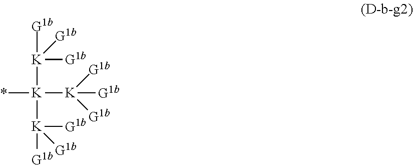

In Formula (D-b-g2), the symbol of * represents a bond; K represents a tetravalent atom or a tetravalent cyclic group and is preferably a tetravalent cyclic group; and nine G^{1b}s each represent a monovalent group and may be the same as or different from each other.

In Formulae (D-a-g1) and (D-a-g2), the definition, examples, and preferred examples of the trivalent atom and the trivalent cyclic group represented by X are the same as those represented by X in Formula (D-a).

In Formulae (D-b-g1) and (D-b-g2), the definition, examples, and preferred examples of the tetravalent atom and the tetravalent cyclic group represented by K are the same as those represented by K in Formula (D-b).

In Formulae (D-a-g1), (D-a-g2), (D-b-g1), and (D-b-g2), a monovalent group represented by G^{1a} or G^{1b} is an aryl group or a monovalent heterocyclic group. The definition, examples, and preferred examples of the aryl group and the monovalent heterocyclic group which are represented by G^{1a} or G^{1b} are the same as those of these groups described below with respect to R^{P1}, R^{P2}, R^{P3}, R^{P4}, R^{P5}, and R^{P6}. The monovalent group represented by G^{1a} or G^{1b} is preferably an aryl group or a monovalent aromatic heterocyclic group, more preferably an aryl group, and further preferably a phenyl group. The monovalent group represented by G^{1a} or G^{1b} may further have 1 to 5 substituent(s). Examples of such a substituent may include a halogen atom, an alkyl group, an alkyloxy group, an alkylthio group, an aryl group, an acyloxy group, an arylthio group, an arylalkyl group, an arylalkyloxy group, an arylalkylthio group, an acyl group, an acyloxy group, a carbamoyl group, an amido group, an acid imido group, an imine residue, a substituted amino group, a substituted silyl group, a substituted silyloxy group, a substituted silylthio group, a substituted silylamino group, a monovalent heterocyclic group, a heteroaryloxy group, a heteroarylthio group, an arylalkenyl group, an arylalkynyl group, a substituted carboxy group, and a cyano group, which are described below with respect to R^{P1}, R^{P2}, R^{P3}, R^{P4}, R^{P5}, and R^{P6}. Such a substituent is preferably an alkyl group or an alkyloxy group, and more preferably an alkyl group.

In Formulae (D-a-g1) and (D-a-g2), a plurality of G^{1a}s may be the same as or different from each other and are preferably the same as each other. Dendrons represented by Formulae (D-a-g1) and (D-a-g2) may be a symmetric structure with respect to the axis of the bond * to X.

In Formulae (D-b-g1) and (D-b-g2), a plurality of G^{1b}s may be the same as or different from each other and are preferably the same as each other.

The dendron is preferably a dendron represented by Formula (D-1) or (D-2) below, and more preferably a dendron represented by Formula (D-1):

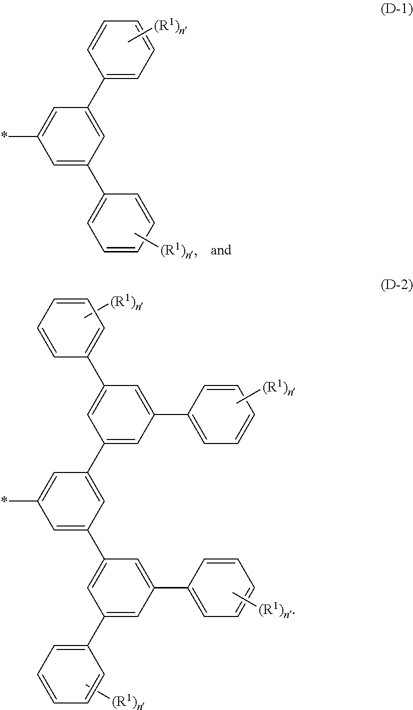

### In Formulae (D-1) and (D-2),

the symbol of * represents a bond;

R¹ represents a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, a carbamoyl group, an amido group, an acid imido group, an imine residue, a substituted amino group, a substituted silyl group, a substituted silyloxy group, a substituted silylthio group, a substituted silylamino group, a monovalent heterocyclic group, a heteroaryloxy group, a heteroarylthio group, an arylalkenyl group, an arylalkynyl group, a substituted carboxy group, or a cyano group, wherein when more than one R¹ is presents, a plurality of R¹s may be the same as or different from each other; and

n′ is an integer of 0 to 5, wherein when more than one n′ is present, a plurality of n's may be the same as or different from each other.

In Formulae (D-1) and (D-2), the definition, examples, and preferred examples of a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, a carbamoyl group, an amido group, an acid imido group, an imine residue, a substituted amino group, a substituted silyl group, a substituted silyloxy group, a substituted silylthio group, a substituted silylamino group, a monovalent heterocyclic group, a heteroaryloxy group, a heteroarylthio group, an arylalkenyl group, an arylalkynyl group, and a substituted carboxy group which are represented by R¹ are the same as those of these groups described below with respect to R^{P1}, R^{P2}, R^{P3}, R^{P4}, R^{P5}, and R^{P6}. The group represented by R¹ is preferably an alkyl group or an alkyloxy group, and more preferably an alkyl group. When more than one R¹ is present, a plurality of R¹s may be the same as or different from each other and are preferably the same as each other.

In Formulae (D-1) and (D-2), n′ is an integer of 0 to 5, preferably 0 to 3, more preferably 0 to 2, and further preferably 0 or 1.

In the metal complex of the present invention, at least one of R^{P1}, R^{P2}, R^{P3}, and R^{P4} is a dendron. The substitution position capable of introducing the dendron on the benzene ring of the ligand may be any positions of R^{P1}, R^{P2}, R^{P3}, and R^{P4} and is preferably the position of R^{P2} or R^{P3}, and further preferably the position of R^{P3}.

The triazole ring of the ligand may comprise a dendron. The substitution position capable of introducing the dendron on the triazole may be any positions of R^{P5} and R^{P6} and is preferably the position of R^{P5}.

The metal atom M as the metal atom of the metal complex of the present invention is a ruthenium atom, a rhodium atom, a palladium atom, an osmium atom, an iridium atom, or a platinum atom. These metal atoms can exert a spin-orbit interaction on the metal complex and can produce an intersystem crossing between a singlet state and a triplet state. The metal atom M is preferably an osmium atom, an iridium atom, or a platinum atom, further preferably an iridium atom or a platinum atom, and particularly preferably an iridium atom.

The group represented by R^{P1}, R^{P2}, R^{P3}, R^{P4}, R^{P5}, and R^{P6} is described below.

Examples of the halogen atom represented by R^{P1}, R^{P2}, R^{P3}, R^{P4}, R^{P5}, and R^{P6} may include a fluorine atom, a chlorine atom, a bromine atom, and an iodine atom, and the halogen atom is preferably a fluorine atom.

The alkyl group represented by R^{P1}, R^{P2}, R^{P3}, R^{P4}, R^{P5}, and R^{P6} may be any one of a straight chain alkyl group, a branched alkyl group, and a cyclic alkyl group. The straight chain alkyl group has the number of carbon atom(s) of usually 1 to 12, and preferably 3 to 10. The branched alkyl group has the number of carbon atoms of usually 3 to 12, and preferably 3 to 10. The cyclic alkyl group has the number of carbon atoms of usually 3 to 12, and preferably 3 to 10. Although the alkyl group may have a substituent, the number of carbon atom(s) of the substituent is not included in the number of carbon atom(s) of any of the straight chain, branched, and cyclic alkyl groups.

Examples of such an alkyl group may include a methyl group, an ethyl group, a propyl group, an isopropyl group, a butyl group, an isobutyl group, a tert-butyl group, a pentyl group, a hexyl group, a cyclohexyl group, a heptyl group, an octyl group, a 2-ethylhexyl group, a nonyl group, a decyl group, a 3,7-dimethyloctyl group, a lauryl group, a trifluoromethyl group, a pentafluoroethyl group, a perfluorobutyl group, a perfluorohexyl group, and a perfluorooctyl group. Among them, a pentyl group, a hexyl group, an octyl group, a 2-ethylhexyl group, a decyl group, and a 3,7-dimethyloctyl group are preferred.

The alkyloxy group represented by R^{P1}, R^{P2}, R^{P3}, R^{P4}, R^{P5}, and R^{P6} may be any one of a straight chain alkyloxy group, a branched alkyloxy group, and a cyclic alkyloxy group. The straight chain alkyloxy group has the number of carbon atom(s) of usually 1 to 12, and preferably 3 to 10. The branched alkyloxy group has the number of carbon atoms of usually 3 to 12, and preferably 3 to 10. The cyclic alkyloxy group has the number of carbon atoms of usually 3 to 12, and preferably 3 to 10. Although the alkyloxy group may have a substituent, the number of carbon atom(s) of the substituent is not included in the number of carbon atom(s) of any of the straight chain, branched, and cyclic alkyloxy groups.

Examples of such an alkyloxy group may include a methyloxy group, an ethyloxy group, a propyloxy group, an isopropyloxy group, a butyloxy group, an isobutyloxy group, a tert-butyloxy group, a pentyloxy group, a hexyloxy group, a cyclohexyloxy group, a heptyloxy group, an octyloxy group, a 2-ethylhexyloxy group, a nonyloxy group, a decyloxy group, a 3,7-dimethyloctyloxy group, a lauryloxy group, a trifluoromethyloxy group, a pentafluoroethyloxy group, a perfluorobutyloxy group, a perfluorohexyloxy group, a perfluorooctyloxy group, a methyloxymethyloxy group, and a 2-methyloxyethyloxy group. Among them, a pentyloxy group, a hexyloxy group, an octyloxy group, a 2-ethylhexyloxy group, a decyloxy group, and a 3,7-dimethyloctyloxy group are preferred.

The alkylthio group represented by R^{P1}, R^{P2}, R^{P3}, R^{P4}, R^{P5}, and R^{P6} may be any one of a straight chain alkylthio group, a branched alkylthio group, and a cyclic alkylthio group. The straight chain alkylthio group has the number of carbon atom(s) of usually 1 to 12, and preferably 3 to 10. The branched alkylthio group has the number of carbon atoms of usually 3 to 12, and preferably 3 to 10. The cyclic alkylthio group has the number of carbon atoms of usually 3 to 12, and preferably 3 to 10. Although the alkylthio group may have a substituent, the number of carbon atom(s) of the substituent is not included in the number of carbon atom(s) of any of the straight chain, branched, and cyclic alkylthio groups.

Examples of such an alkylthio group may include a methylthio group, an ethylthio group, a propylthio group, an isopropylthio group, a butylthio group, an isobutylthio group, a tert-butylthio group, a pentylthio group, a hexylthio group, a cyclohexylthio group, a heptylthio group, an octylthio group, a 2-ethylhexylthio group, a nonylthio group, a decylthio group, a 3,7-dimethyloctylthio group, a laurylthio group, and a trifluoromethylthio group. Among them, a pentylthio group, a hexylthio group, an octylthio group, a 2-ethylhexylthio group, a decylthio group, and a 3,7-dimethyloctylthio group are preferred.

The aryl group represented by R^{P1}, R^{P2}, R^{P3}, R^{p4}, R^{P5}, and R^{P6} has the number of carbon atoms of usually 6 to 60, and preferably 6 to 48. Although the aryl group may have a substituent, the number of carbon atom(s) of the substituent is not included in the number of carbon atom(s) of the aryl group.

Examples of such an aryl group may include a phenyl group, a C₁₋₁₂ alkyloxyphenyl group (“C₁₋₁₂ alkyloxy” means that the alkyloxy moiety has the number of carbon atom(s) of 1 to 12, and the same shall apply hereinafter), a C₁₋₁₂ alkylphenyl group (“C₁₋₁₂ alkyl” means that the alkyl moiety has the number of carbon atom(s) of 1 to 12, and the same shall apply hereinafter), a 1-naphthyl group, a 2-naphthyl group, a 1-anthracenyl group, a 2-anthracenyl group, a 9-anthracenyl group, and a pentafluorophenyl group. Among them, a C₁₋₁₂ alkyloxyphenyl group and a C₁₋₁₂ alkylphenyl group are preferred. Here, the aryl group means a group remaining after removing one hydrogen atom directly bonded to a carbon atom constituting the ring of an aromatic hydrocarbon, from the aromatic hydrocarbon. Examples of the aromatic hydrocarbon may include a fused ring, and a moiety constituted of two or more rings selected from independent benzene ring(s) and fused ring(s) in which two or more rings are bonded directly or are bonded through a vinylene group.

The above C₁₋₁₂ alkyl is alkyl having the number of carbon atom(s) of 1 to 12 and is the same as the alkyl group described and exemplified above. Accordingly, examples of C₁₋₁₂ alkyloxy with respect to the group may include methyloxy, ethyloxy, propyloxy, isopropyloxy, butyloxy, isobutyloxy, tert-butyloxy, pentyloxy, hexyloxy, cyclohexyloxy, heptyloxy, octyloxy, 2-ethylhexyloxy, nonyloxy, decyloxy, 3,7-dimethyloctyloxy, and lauryloxy. Examples of C₁₋₁₂ alkylphenyl with respect to the group may include methylphenyl, ethylphenyl, dimethylphenyl, propylphenyl, mesityl, methylethylphenyl, isopropylphenyl, butylphenyl, isobutylphenyl, tert-butylphenyl, pentylphenyl, isoamylphenyl, hexylphenyl, heptylphenyl, octylphenyl, nonylphenyl, decylphenyl, and dodecylphenyl. The same shall apply hereinafter.

The aryloxy group represented by R^{P1}, R^{P2}, R^{P3}, R^{P4}, R^{P5}, and R^{P6} has the number of carbon atoms of usually 6 to 60, and preferably 7 to 48. Although the aryloxy group may have a substituent, the number of carbon atom(s) of the substituent is not included in the number of carbon atom(s) of the aryloxy group.

Examples of such an aryloxy group may include a phenyloxy group, a C₁₋₁₂ alkyloxyphenyloxy group, a C₁₋₁₂ alkylphenyloxy group, a 1-naphthyloxy group, a 2-naphthyloxy group, and a pentafluorophenyloxy group. Among them, a C₁₋₁₂ alkyloxyphenyloxy group and a C₁₋₁₂ alkylphenyloxy group are preferred.

The arylthio group represented by R^{P1}, R^{P2}, R^{P3}, R^{P4}, R^{P5}, and R^{P6} has the number of carbon atoms of usually 6 to 60, and preferably 7 to 48. Although the arylthio group may have a substituent, the number of carbon atom(s) of the substituent is not included in the number of carbon atom(s) of the arylthio group.

Examples of such an arylthio group may include a phenylthio group, a C₁₋₁₂ alkyloxyphenylthio group, a C₁₋₁₂ alkylphenylthio group, a 1-naphthylthio group, a 2-naphthylthio group, and a pentafluorophenylthio group. Among them, a C₁₋₁₂ alkyloxyphenylthio group and a C₁₋₁₂ alkylphenylthio group are preferred.

The arylalkyl group represented by R^{P1}, R^{P2}, R^{P3}, R^{P4}, R^{P5}, and R^{P6} has the number of carbon atoms of usually 7 to 60, and preferably 7 to 48. Although the arylalkyl group may have a substituent, the number of carbon atom(s) of the substituent is not included in the number of carbon atom(s) of the arylalkyl group.

Examples of such an arylalkyl group may include a phenyl-C₁₋₁₂ alkyl group, a C₁₋₁₂ alkyloxypheny-C₁₋₁₂ alkyl group, a C₁₋₁₂ alkylphenyl-C₁₋₁₂ alkyl group, a 1-naphthyl-C₁₋₁₂ alkyl group, and a 2-naphthyl-C₁₋₁₂ alkyl group. Among them, a C₁₋₁₂ alkyloxyphenyl-C₁₋₁₂ alkyl group and a C₁₋₁₂ alkylphenyl-C₁₋₁₂ alkyl group are preferred.

The arylalkyloxy group represented by R^{P1}, R^{P2}, R^{P3}, R^{P4}, R^{P5} and R^{P6} has the number of carbon atoms of usually 7 to 60, and preferably 7 to 48. Although the arylalkyloxy group may have a substituent, the number of carbon atom(s) of the substituent is not included in the number of carbon atom(s) of the arylalkyloxy group.

Examples of such an arylalkyloxy group may include a phenyl-C₁₋₁₂ alkyloxy group such as a phenylmethyloxy group, a phenylethyloxy group, a phenylbutyloxy group, a phenylpentyloxy group, a phenylhexyloxy group, a phenylheptyloxy group, and a phenyloctyloxy group, a C₁₋₁₂ alkyloxyphenyl-C₁₋₁₂ alkyloxy group, a C₁₋₁₂ alkylphenyl-C₁₋₁₂ alkyloxy group, a 1-naphthyl-C₁₋₁₂ alkyloxy group, and a 2-naphthyl-C₁₋₁₂ alkyloxy group. Among them, a C₁₋₁₂ alkyloxyphenyl-C₁₋₁₂ alkyloxy group and a C₁₋₁₂ alkylphenyl-C₁₋₁₂ alkyloxy group are preferred.

The arylalkylthio group represented by R^{P1}, R^{P2}, R^{P3}, R^{P4}, R^{P5}, and R^{P6} has the number of carbon atoms of usually 7 to 60, and preferably 7 to 48. Although the arylalkylthio group may have a substituent, the number of carbon atom(s) of the substituent is not included in the number of carbon atom(s) of the arylalkylthio group.

Examples of such an arylalkylthio group may include a phenyl-C₁₋₁₂ alkylthio group, a C₁₋₁₂ alkyloxyphenyl-C₁₋₁₂ alkylthio group, a C₁₋₁₂ alkylphenyl-C₁₋₁₂ alkylthio group, a 1-naphthyl-C₁₋₁₂ alkylthio group, and a 2-naphthyl-C₁₋₁₂ alkylthio group. Among them, a C₁₋₁₂ alkyloxyphenyl-C₁₋₁₂ alkylthio group and a C₁₋₁₂ alkylphenyl-C₁₋₁₂ alkylthio group are preferred.

The acyl group represented by R^{P1}, R^{P2}, R^{P3}, R^{P4}, R^{P5}, and R^{P6} has the number of carbon atoms of usually 2 to 20, and preferably 2 to 18. Although the acyl group may have a substituent, the number of carbon atom(s) of the substituent is not included in the number of carbon atom(s) of the acyl group.

Examples of such an acyl group may include an acetyl group, a propionyl group, a butyryl group, an isobutyryl group, a pivaloyl group, a benzoyl group, a trifluoroacetyl group, and a pentafluorobenzoyl group.

The acyloxy group represented by R^{P1}, R^{P2}, R^{P3}, R^{P4}, R^{P5}, and R^{P6} has the number of carbon atoms of usually 2 to 20, and preferably 2 to 18. Although the acyloxy group may have a substituent, the number of carbon atom(s) of the substituent is not included in the number of carbon atom(s) of the acyloxy group.

Examples of such an acyloxy group may include an acetoxy group, a propionyloxy group, a butyryloxy group, an isobutyryloxy group, a pivaloyloxy group, a benzoyloxy group, a trifluoroacetyloxy group, and a pentafluorobenzoyloxy group.

The carbamoyl group represented by R^{P1}, R^{P2}, R^{P3}, R^{P4}, R^{P5}, and R^{P6} may have a substituent and has the number of carbon atom(s), including the number of carbon atom(s) of the substituent, of usually 1 to 20, and preferably 2 to (that is, the carbamoyl group is represented by a general formula: NR^{a}R^{b}—CO—, and R^{a} and R^{b} each independently represent a hydrogen atom, an alkyl group, an aryl group, an arylalkyl group or a monovalent heterocyclic group.

Examples of such a carbamoyl group may include an aminocarbonyl group, a methylaminocarbonyl group, a dimethylaminocarbonyl group, an ethylaminocarbonyl group, a propylaminocarbonyl group, and a butylaminocarbonyl group.

The amido group represented by R^{P1}, R^{P2}, R^{P3}, R^{P4}, R^{P5}, and R^{P6} may have a substituent and has the number of carbon atom(s), including the number of carbon atom(s) of the substituent, of usually 1 to 20, and preferably 2 to 18 (that is, the amido group is represented by a general formula: R^{c}—CO—NR^{d}—, wherein R^{c} and R^{d} each independently represent a hydrogen atom, an alkyl group, an aryl group, an arylalkyl group or a monovalent heterocyclic group.

Examples of such an amido group may include a formamido group, an acetamido group, a propioamido group, a butyramido group, a benzamido group, a trifluoroacetamido group, a pentafluorobenzamido group, a diformamido group, a diacetamido group, a dipropioamido group, a dibutyramido group, a dibenzamido group, a ditrifluoroacetamido group, and a dipentafluorobenzamido group.

The acid imido group represented by R^{P1}, R^{P2}, R^{P3}, R^{P4}, R^{P5}, and R^{P6} means a monovalent group obtained by removing one hydrogen atom bonded to a nitrogen atom of an acid imide, from the acid imide. The acid imide group has the number of carbon atoms of usually 2 to 60, and preferably 2 to 48. Although the acid imido group may have a substituent, the number of carbon atom(s) of the substituent is not included in the number of carbon atom(s) of the acid imido group.

Examples of such an acid imido group may include groups represented by the structural formulae below.

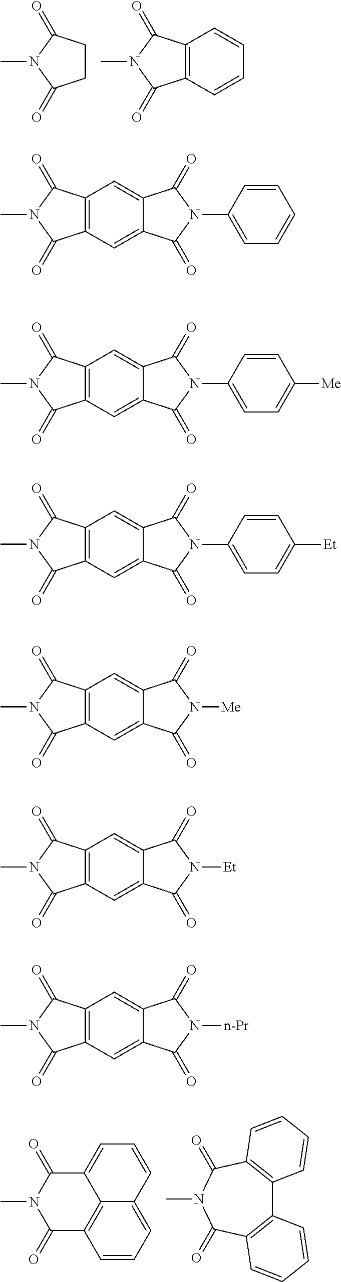

In the above formulae, a line extending from a nitrogen atom represents a bond; Me represents a methyl group, Et represents an ethyl group, and n-Pr represents an n-propyl group; and the same shall apply hereinafter.

The imine residue represented by R^{P1}, R^{P2}, R^{P3}, R^{P4}, R^{P5}, and R^{P6} means a monovalent group remaining after removing one hydrogen atom from an imine compound (that is, the imine compound is an organic compound having —N═C— in the molecule thereof. Examples thereof may include aldimine, ketimine, and a compound in which a hydrogen atom bonded to a nitrogen atom in the molecule of any one of aldimine and ketimine is substituted with an alkyl group or other groups). The imine residue has the number of carbon atoms of usually 2 to 20, and preferably 2 to 18. Although the imine residue may have a substituent, the number of carbon atom(s) of the substituent is not included in the number of carbon atom(s) of the imine residue.

Examples of such an imine residue may include groups represented by the following structural formulae.

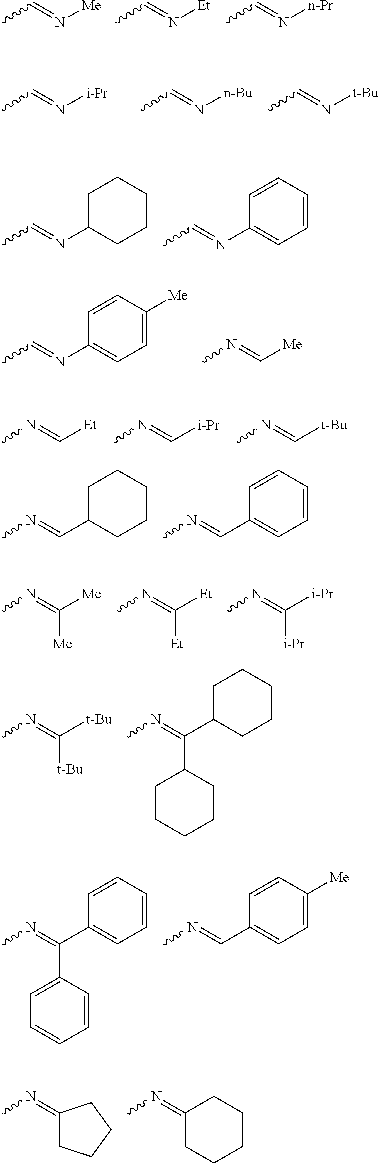

In the above formulae, i-Pr represents an isopropyl group, n-Bu represents an n-butyl group, and t-Bu represents a tert-butyl group; and a bond indicated by a wavy line means that the bond is a “bond indicated by a wedge-shape” and/or a “bond indicated by a broken line”. Here, the “bond indicated by a wedge-shape” means a bond projecting from the surface of the paper toward the front, and the “bond indicated by a broken line” means a bond projecting from the surface of the paper toward the back.

The substituted amino group represented by R^{P1}, R^{P2}, R^{P3}, R^{P4}, R^{P5}, and R^{P6} means an amino group substituted with one or two group(s) selected from the group consisting of an alkyl group, an aryl group, an arylalkyl group, and a monovalent heterocyclic group. Although the alkyl group, the aryl group, the arylalkyl group, and the monovalent heterocyclic group may have a substituent, the number of carbon atom(s) of the substituent is not included in the number of carbon atom(s) of the substituted amino group. The substituted amino group has the number of carbon atom(s) of usually 1 to 60, and preferably 2 to 48.

Examples of such a substituted amino group may include a methylamino group, a dimethylamino group, an ethylamino group, a diethylamino group, a propylamino group, a dipropylamino group, an isopropylamino group, a diisopropylamino group, a butylamino group, an isobutylamino group, a tert-butylamino group, a pentylamino group, a hexylamino group, a cyclohexylamino group, a heptylamino group, an octylamino group, a 2-ethylhexylamino group, a nonylamino group, a decylamino group, a 3,7-dimethyloctylamino group, a laurylamino group, a cyclopentylamino group, a dicyclopentylamino group, a cyclohexylamino group, a dicyclohexylamino group, a pyrrolidyl group, a piperidyl group, a ditrifluoromethylamino group, a phenylamino group, a diphenylamino group, a C₁₋₁₂ alkyloxyphenylamino group, a di (C₁₋₁₂ alkyloxyphenyl)amino group, a di (C₁₋₁₂ alkylphenyl)amino group, a 1-naphthylamino group, a 2-naphthylamino group, a pentafluorophenylamino group, a pyridylamino group, a pyridazinylamino group, a pyrimidylamino group, a pyrazylamino group, a triazylamino group, a phenyl-C₁₋₁₂ alkylamino group, a C₁₋₁₂ alkyloxyphenyl-C₁₋₁₂ alkylamino group, a C₁₋₁₂ alkylphenyl-C₁₋₁₂ alkylamino group, a di (C₁₋₁₂ alkyloxyphenyl-C₁₋₁₂ alkyl)amino group, a di (C₁₋₁₂ alkylphenyl-C₁₋₁₂ alkyl)amino group, a 1-naphthyl-C₁₋₁₂ alkylamino group, and a 2-naphthyl-C₁₋₁₂ alkylamino group.

The substituted silyl group represented by R^{P1}, P^{P2}, R^{P3}, R^{P4}, R^{P5}, and R^{P6} means a silyl group substituted with one, two, or three group(s) selected from the group consisting of an alkyl group, an aryl group, an arylalkyl group, and a monovalent heterocyclic group. Although the alkyl group, the aryl group, the arylalkyl group, and the monovalent heterocyclic group may have a substituent, the number of carbon atom(s) of the substituent is not included in the number of carbon atom(s) of the substituted silyl group. The substituted silyl group has the number of carbon atom(s) of usually 1 to 60, and preferably 3 to 48.

Examples of such a substituted silyl group may include a trimethylsilyl group, a triethylsilyl group, a tripropylsilyl group, a triisopropylsilyl group, a dimethylisopropylsilyl group, a diethylisopropylsilyl group, a tert-butylsilyldimethylsilyl group, a pentyldimethylsilyl group, a hexyldimethylsilyl group, a heptyldimethylsilyl group, an octyldimethylsilyl group, a 2-ethylhexyl-dimethylsilyl group, a nonyldimethylsilyl group, a decyldimethylsilyl group, a 3,7-dimethyloctyl-dimethylsilyl group, a lauryldimethylsilyl group, a phenyl-C₁₋₁₂ alkylsilyl group, a C₁₋₁₂ alkyloxyphenyl-C₁₋₁₂ alkylsilyl group, a C₁₋₁₂ alkylphenyl-C₁₋₁₂ alkylsilyl group, a 1-naphthyl-C₁₋₁₂ alkylsilyl group, a 2-naphthyl-C₁₋₁₂ alkylsilyl group, a phenyl-C₁₋₁₂ alkyldimethylsilyl group, a triphenylsilyl group, a tri-p-xylylsilyl group, a tribenzylsilyl group, a diphenylmethylsilyl group, a tert-butyldiphenylsilyl group, and a dimethylphenylsilyl group.

The substituted silyloxy group represented by R^{P1}, R^{P2}, R^{P3}, R^{P4}, R^{P5}, and R^{P6} means a silyloxy group substituted with one, two, or three group(s) selected from the group consisting of an alkyl group, an aryl group, an arylalkyl group, and a monovalent heterocyclic group. The substituted silyloxy group has the number of carbon atom(s) of usually 1 to 60, and preferably 3 to 48. Although the alkyl group, the aryl group, the arylalkyl group, and the monovalent heterocyclic group may have a substituent, the number of carbon atom(s) of the substituent is not included in the number of carbon atom(s) of the substituted silyloxy group.

Examples of such a substituted silyloxy group may include a trimethylsilyloxy group, a triethylsilyloxy group, a tripropylsilyloxy group, a triisopropylsilyloxy group, a dimethylisopropylsilyloxy group, a diethylisopropylsilyloxy group, a tert-butylsilyldimethylsilyloxy group, a pentyldimethylsilyloxy group, a hexyldimethylsilyloxy group, a heptyldimethylsilyloxy group, an octyldimethylsilyloxy group, a 2-ethylhexyl-dimethylsilyloxy group, a nonyldimethylsilyloxy group, a decyldimethylsilyloxy group, a 3,7-dimethyloctyl-dimethylsilyloxy group, a lauryldimethylsilyloxy group, a phenyl-C₁₋₁₂ alkylsilyloxy group, a C₁₋₁₂ alkyloxyphenyl-C₁₋₁₂ alkylsilyloxy group, a C₁₋₁₂ alkylphenyl-C₁₋₁₂ alkylsilyloxy group, a 1-naphthyl-C₁₋₁₂ alkylsilyloxy group, a 2-naphthyl-C₁₋₁₂ alkylsilyloxy group, a phenyl-C₁₋₁₂ alkyldimethylsilyloxy group, a triphenylsilyloxy group, a tri-p-xylylsilyloxy group, a tribenzylsilyloxy group, a diphenylmethylsilyloxy group, a tert-butyldiphenylsilyloxy group, and a dimethylphenylsilyloxy group.

The substituted silylthio group represented by R^{P1}, R^{P2}, R^{P3}, R^{P4}, R^{P5}, and R^{P6} means a silylthio group substituted with one, two, or three group(s) selected from the group consisting of an alkyl group, an aryl group, an arylalkyl group, and a monovalent heterocyclic group. The substituted silylthio group has the number of carbon atom(s) of usually 1 to 60, and preferably 3 to 48. Although the alkyl group, the aryl group, the arylalkyl group, and the monovalent heterocyclic group may have a substituent, the number of carbon atom(s) of the substituent is not included in the number of carbon atom(s) of the substituted silylthio group.

Examples of such a substituted silylthio group may include a trimethylsilylthio group, a triethylsilylthio group, a tripropylsilylthio group, a triisopropylsilylthio group, a dimethylisopropylsilylthio group, a diethylisopropylsilylthio group, a tert-butylsilyldimethylsilylthio group, a pentyldimethylsilylthio group, a hexyldimethylsilylthio group, a heptyldimethylsilylthio group, an octyldimethylsilylthio group, a 2-ethylhexyl-dimethylsilylthio group, a nonyldimethylsilylthio group, a decyldimethylsilylthio group, a 3,7-dimethyloctyl-dimethylsilylthio group, a lauryldimethylsilylthio group, a phenyl-C₁₋₁₂ alkylsilylthio group, a C₁₋₁₂ alkyloxyphenyl-C₁₋₁₂ alkylsilylthio group, a C₁₋₁₂ alkylphenyl-C₁₋₁₂ alkylsilylthio group, a 1-naphthyl-C₁₋₁₂ alkylsilylthio group, a 2-naphthyl-C₁₋₁₂ alkylsilylthio group, a phenyl-C₁₋₁₂ alkyldimethylsilylthio group, a triphenylsilylthio group, a tri-p-xylylsilylthio group, a tribenzylsilylthio group, a diphenylmethylsilylthio group, a tert-butyldiphenylsilylthio group, and a dimethylphenylsilylthio group.

The substituted silylamino group represented by R^{P1}, R^{P2}, R^{P3}, R^{P4}, R^{P5}, and R^{P6} means a silylamino group substituted with one, two, or three group(s) selected from the group consisting of an alkyl group, an aryl group, an arylalkyl group, and a monovalent heterocyclic group. The substituted silylamino group has the number of carbon atom(s) of usually 1 to 60, and preferably 3 to 48. Although the alkylamino group, the arylamino group, the arylalkylamino group, and the monovalent heterocyclic amino group may have a substituent, the number of carbon atom(s) of the substituent is not included in the number of carbon atom(s) of the substituted silylamino group.

Examples of such a substituted silylamino group may include a trimethylsilylamino group, a triethylsilylamino group, a tripropylsilylamino group, a triisopropylsilylamino group, a dimethylisopropylsilylamino group, a diethylisopropylsilylamino group, a tert-butylsilyldimethylsilylamino group, a pentyldimethylsilylamino group, a hexyldimethylsilylamino group, a heptyldimethylsilylamino group, an octyldimethylsilylamino group, a 2-ethylhexyl-dimethylsilylamino group, a nonyldimethylsilylamino group, a decyldimethylsilylamino group, a 3,7-dimethyloctyl-dimethylsilylamino group, a lauryldimethylsilylamino group, a phenyl-C₁₋₁₂ alkylsilylamino group, a C₁₋₁₂ alkyloxyphenyl-C₁₋₁₂ alkylsilylamino group, a C₁₋₁₂ alkylphenyl-C₁₋₁₂ alkylsilylamino group, a 1-naphthyl-C₁₋₁₂ alkylsilylamino group, a 2-naphthyl-C₁₋₁₂ alkylsilylamino group, a phenyl-C₁₋₁₂ alkyldimethylsilylamino group, a triphenylsilylamino group, a tri-p-xylylsilylamino group, a tribenzylsilylamino group, a diphenylmethylsilylamino group, a tert-butyldiphenylsilylamino group, and a dimethylphenylsilylamino group.

The monovalent heterocyclic group represented by R^{P1}, R^{P2}, R^{P3}, R^{P4}, R^{P5}, and R^{P6} means a group remaining after removing from a heterocyclic compound, one hydrogen atom directly bonded to a carbon atom or hetero atom constituting the ring of the heterocyclic compound. The monovalent heterocyclic group has the number of carbon atoms of usually 4 to 60, and preferably 4 to 20. Although the monovalent heterocyclic group may have a substituent, the number of carbon atom(s) of the substituent is not included in the number of carbon atom(s) of the monovalent heterocyclic group. Here, the heterocyclic compound refers to, among cyclic organic compounds, an organic compound comprising not only a carbon atom but also at least one hetero atom such as an oxygen atom, a sulfur atom, a nitrogen atom, a phosphorus atom, and a boron atom, as a ring constituting atom.

Examples of such a monovalent heterocyclic group may include: a monovalent aromatic heterocyclic group such as a thienyl group, a C₁₋₁₂ alkylthienyl group, a pyrrolyl group, a furyl group, a pyridyl group, a C₁₋₁₂ alkylpyridyl group, a piperidyl group, a quinolyl group, and an isoquinolyl group; and a monovalent non-aromatic heterocyclic group such as pyrrolidinyl, piperidinyl, piperazinyl, pyranyl, and tetrahydropyranyl. Among them, the monovalent aromatic heterocyclic group is preferred. As the monovalent aromatic heterocyclic group, among the above-described groups, a thienyl group, a C₁₋₁₂ alkylthienyl group, a pyridyl group, and a C₁₋₁₂ alkylpyridyl group are preferred.

The heteroaryloxy group represented by R^{P1}, R^{P2}, R^{P3}, R^{P4}, R^{P5}, and R^{P6} has the number of carbon atoms of usually 6 to 60, and preferably 7 to 48. Although the heteroaryloxy group may have a substituent, the number of carbon atom(s) of the substituent is not included in the number of carbon atom(s) of the heteroaryloxy group.

Examples of such a heteroaryloxy group may include a thienyloxy group, a C₁₋₁₂ alkyloxythienyloxy group, a C₁₋₁₂ alkylthienyloxy group, a pyridyloxy group, a C₁₋₁₂ alkyloxypyridyloxy group, a C₁₋₁₂ alkylpyridyloxy group, and an isoquinolyloxy group. Among them, a C₁₋₁₂ alkyloxypyridyloxy group and a C₁₋₁₂ alkylpyridyloxy group are preferred.

Examples of the C₁₋₁₂ alkylpyridyloxy group may include a methylpyridyloxy group, an ethylpyridyloxy group, a dimethylpyridyloxy group, a propylpyridyloxy group, a 1,3,5-trimethylpyridyloxy group, a methylethylpyridyloxy group, an isopropylpyridyloxy group, a butylpyridyloxy group, an isobutylpyridyloxy group, a tert-butylpyridyloxy group, a pentylpyridyloxy group, an isoamylpyridyloxy group, a hexylpyridyloxy group, a heptylpyridyloxy group, an octylpyridyloxy group, a nonylpyridyloxy group, a decylpyridyloxy group, and a dodecylpyridyloxy group.

The heteroarylthio group represented by R^{P1}, R^{P2}, R^{P3}, R^{P4}, R^{P5}, and R^{P6} has the number of carbon atoms of usually 6 to 60, and preferably 7 to 48. Although the heteroarylthio group may have a substituent, the number of carbon atom(s) of the substituent is not included in the number of carbon atom(s) of the heteroarylthio group.

Examples of such a heteroarylthio group may include a pyridylthio group, a C₁₋₁₂ alkyloxypyridylthio group, a C₁₋₁₂ alkylpyridylthio group, and an isoquinolylthio group, and among them, a C₁₋₁₂ alkyloxypyridylthio group and a C₁₋₁₂ alkylpyridylthio group are preferred.

The arylalkenyl group represented by R^{P1}, R^{P2}, R^{P3}, R^{P4}, R^{P5}, and R^{P6} has the number of carbon atoms of usually 7 to 60, and preferably 7 to 48. Although the arylalkenyl group may have a substituent, the number of carbon atom(s) of the substituent is not included in the number of carbon atom(s) of the arylalkenyl group.

Examples of such an arylalkenyl group may include a phenyl-C₂₋₁₂ alkenyl group (“C₂₋₁₂ alkenyl” means that the alkenyl moiety has the number of carbon atoms of 2 to 12, and the same shall apply hereinafter), a C₁₋₁₂ alkyloxyphenyl-C₂₋₁₂ alkenyl group, a C₁₋₁₂ alkylphenyl-C₂₋₁₂ alkenyl group, a 1-naphthyl-C₂₋₁₂ alkenyl group, and a 2-naphthyl-C₂₋₁₂ alkenyl group. Among them, a C₁₋₁₂ alkyloxyphenyl-C₂-C₁₂ alkenyl group and a C₂₋₁₂ alkylphenyl-C₁₋₁₂ alkenyl group are preferred.

Examples of the C₂₋₁₂ alkenyl may include ethenyl, 1-propenyl, 2-propenyl, 2-methyl-1-propenyl, 1-butenyl, 2-butenyl, 3-butenyl, 3-methyl-2-butenyl, 1-pentenyl, 2-pentenyl, 3-pentenyl, 4-pentenyl, 4-methyl-3-pentenyl, 1-hexenyl, 3-hexenyl, and 5-hexenyl.

The arylalkynyl group represented by R^{P1}, R^{P2}, R^{P3}, R^{P4}, R^{P5}, and R^{P6} has the number of carbon atoms of usually 7 to 60, and preferably 7 to 48. Although the arylalkynyl group may have a substituent, the number of carbon atom(s) of the substituent is not included in the number of carbon atom(s) of the arylalkynyl group.

Examples of such an arylalkynyl group may include a phenyl-C₂₋₁₂ alkynyl group (“C₂₋₁₂ alkynyl” means that the alkynyl moiety has the number of carbon atoms of 2 to 12, and the same shall apply hereinafter), a C₁₋₁₂ alkyloxyphenyl-C₂₋₁₂ alkynyl group, a C₁₋₁₂ alkylphenyl-C₂₋₁₂ alkynyl group, a 1-naphthyl-C₂₋₁₂ alkynyl group, and a 2-naphthyl-C₂₋₁₂ alkynyl group. Among them, a C₁₋₁₂ alkyloxyphenyl-C₂-C₁₂ alkynyl group and a C₁₋₁₂ alkylphenyl-C₂₋₁₂ alkynyl group are preferred.

Examples of the above C₂₋₁₂ alkynyl may include ethynyl, 1-propynyl, 2-propynyl, 1-butynyl, 2-butynyl, 3-butynyl, 1-pentynyl, 2-pentynyl, 3-pentynyl, 4-pentynyl, 1-hexynyl, 2-hexynyl, 3-hexynyl, 4-hexynyl, 5-hexynyl, 1-heptynyl, and 1-octynyl.

The substituted carboxy group represented by R^{P1}, R^{P2}, R^{P3}, R^{P4}, R^{P5}, and R^{P6} (the substituted carboxy group is represented by a general formula: R^{e}—O—CO—, wherein R^{e} represents an alkyl group, an aryl group, an arylalkyl group, or a monovalent heterocyclic group) has the number of carbon atom(s) of usually 1 to 60, and preferably 2 to 48 and means a carboxy group substituted with an alkyl group, an aryl group, an arylalkyl group, or a monovalent heterocyclic group. Although the alkyl group, the aryl group, the arylalkyl group, or the monovalent heterocyclic group may have a substituent, the number of carbon atom(s) of the substituent is not included in the number of carbon atom(s) of the substituted carboxy group.

Examples of such a substituted carboxy group may include a methyloxycarbonyl group, an ethyloxycarbonyl group, a propyloxycarbonyl group, an isopropyloxycarbonyl group, a butyloxycarbonyl group, an isobutyloxycarbonyl group, a tert-butyloxycarbonyl group, a pentyloxycarbonyl group, a hexyloxycarbonyl group, a cyclohexyloxycarbonyl group, a heptyloxycarbonyl group, an octyloxycarbonyl group, a 2-ethylhexyloxycarbonyl group, a nonyloxycarbonyl group, a decyloxycarbonyl group, a 3,7-dimethyloctyloxycarbonyl group, a dodecyloxycarbonyl group, a trifluoromethyloxycarbonyl group, a pentafluoroethyloxycarbonyl group, a perfluorobutyloxycarbonyl group, a perfluorohexyloxycarbonyl group, a perfluorooctyloxycarbonyl group, a pyridyloxycarbonyl group, and a naphthyloxycarbonyl group.

When the above-described groups have a substituent, examples of the substituent may include a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, a carbamoyl group, an amido group, an acid imido group, an imine residue, a substituted amino group, a substituted silyl group, a substituted silyloxy group, a substituted silylthio group, a substituted silylamino group, a monovalent heterocyclic group, a heteroaryloxy group, a heteroarylthio group, an arylalkenyl group, an arylalkynyl group, a substituted carboxy group, and a cyano group. The detail of these groups is the same as that of the groups described and exemplified above. The substituent is preferably a halogen atom, an alkyl group, an alkyloxy group, an aryl group, or a monovalent heterocyclic group, and more preferably an alkyl group, an aryl group, or a monovalent heterocyclic group. When the above-described groups have a substituent, the number of substituents is usually 1 to 3, preferably 1 to 2, and more preferably 1.

In the metal complex of the present invention, any one of R^{P1} to R⁴ may be a substituent having electron-withdrawing characteristics and, for example, may be a fluorine atom or a substituent containing a fluorine atom. In the present invention, the fluorine atom or the substituent containing a fluorine atom represents a monovalent group represented by CₚF_{q}HᵣOₛ. Here, p represents an integer selected from 1 to 10, q represents an integer selected from 1 to (2p+1), r represents an integer selected from 0 to (2p+1), s represents 0 or 1. Examples of the monovalent group may include groups represented by Formulae (F1) to (F14) and Formulae (F24) to (F32).

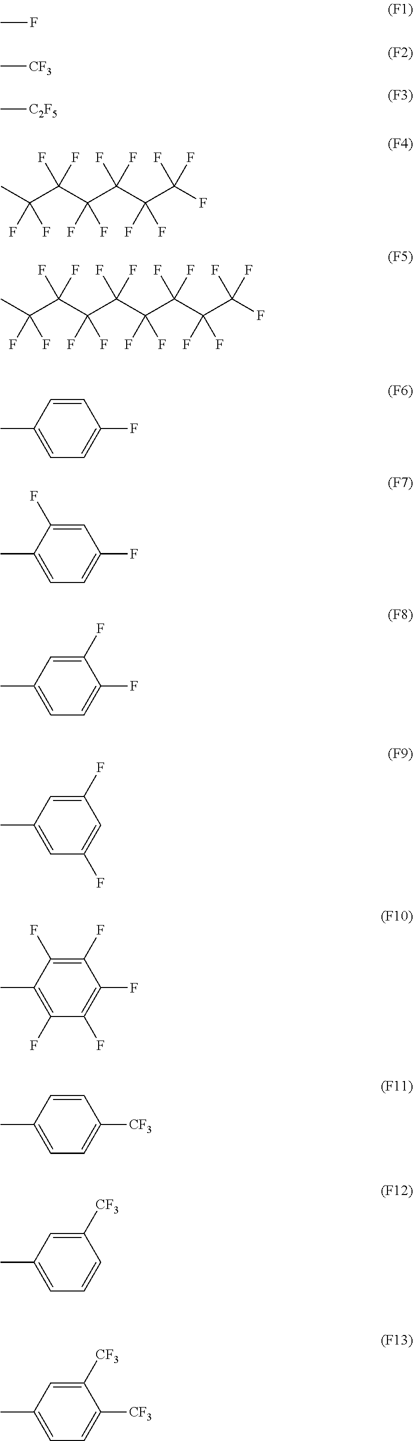

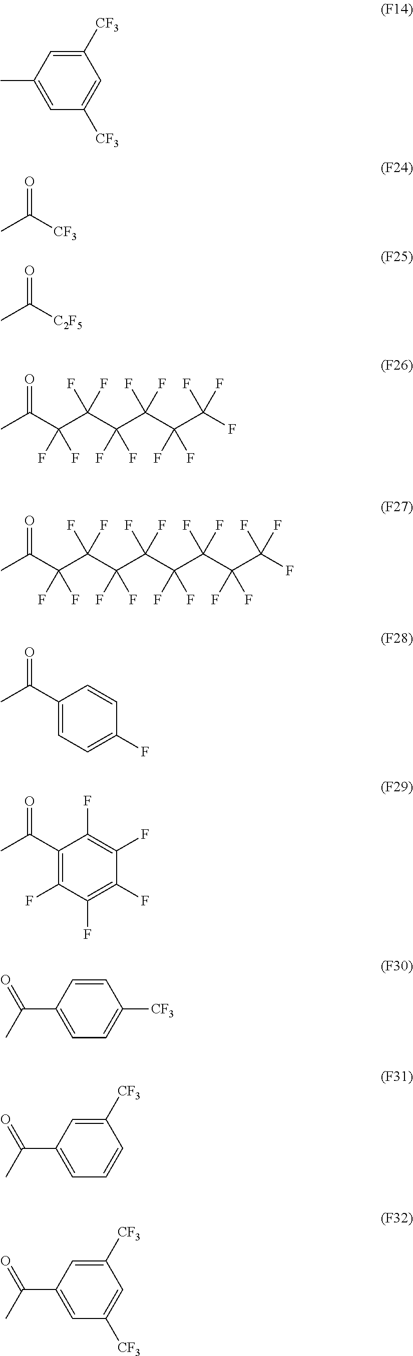

From the viewpoint of the chemical stability of the metal complex of the present invention, in the monovalent group represented by CₚF_{q}HᵣOₛ, is preferably 0, and accordingly, the monovalent group is preferably a group represented by a formula from Formulae (F1) to (F14).

Although the bidentate ligand which is a moiety represented by Formula (2) is not limited so long as the bidentate ligand is a ligand having two coordination positions, the bidentate ligand is preferably monoanionic so that the metal complex of the present invention is neutral. Examples of the bidentate ligand may include the following structures.

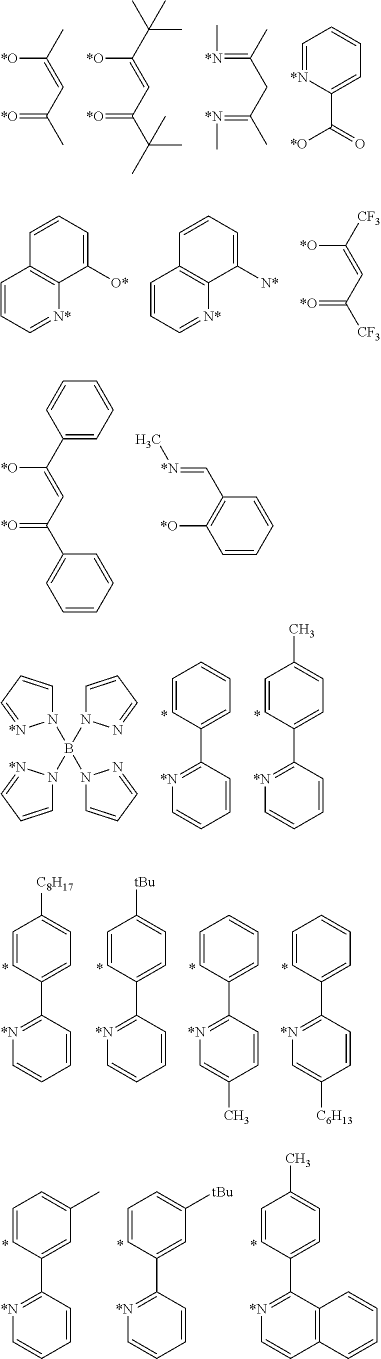

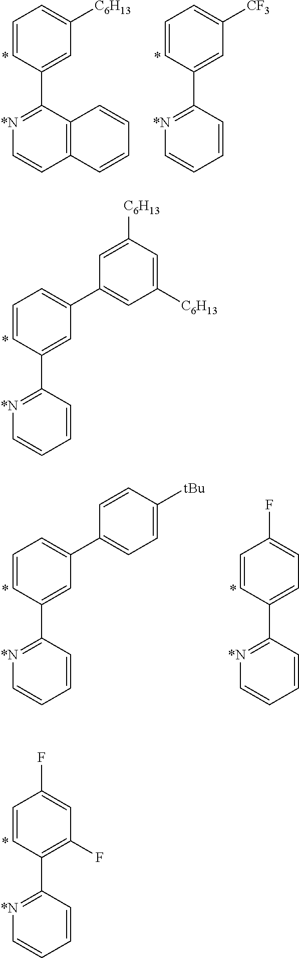

In the above formulae, the symbol of * represents a position bonded to the metal atom M.

In a preferred embodiment, the metal complex of the present invention is a metal complex having a structure represented by Formula (1a) or (1b) below in which R^{P2} or R^{P3} is a dendron. More preferably, the metal complex of the present invention is a metal complex represented by Formula (1c) below in which R^{P3} is a dendron and R^{P5} is an aryl group.

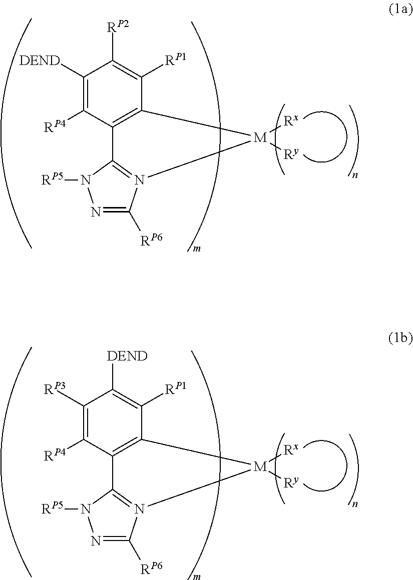

In Formula (1a) or Formula (1b), M, R^{P1}, R^{P2}, R^{P3}, R^{P4}, R^{P5}, R^{P6}, R^{x}, R^{y}, m, and n represent the same as defined above; and DEND represents a dendron.

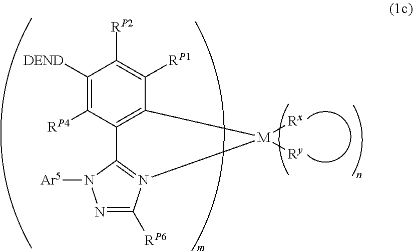

In Formula (1c), M, R^{P1}, R^{P2}, R^{P3}, R^{P4}, R^{P5}, R^{P6}, R^{x}, R^{y}, m, n, and DEND represent the same as defined above; and Ar⁵ represents an aryl group.

Although the peak wavelength of the emission spectrum of the metal complex of the present invention is not limited, it is preferably 430 nm to 630 nm, more preferably 430 nm to 580 nm, further preferably 430 nm to 530 nm, and particularly preferably 430 nm to 490 nm.

The peak wavelength of the emission spectrum of the metal complex of the present invention can be evaluated, for example, by: dissolving the metal complex in an organic solvent such as xylene, toluene, chloroform, and tetrahydrofuran to prepare a diluted solution (the concentration of the metal complex in the solution is in a range of, for example, 1×10⁻⁶ to 1×10⁻⁷ mol/L) of the metal complex; and measuring the PL spectrum of the diluted solution.

Specific examples of the metal complex of the present invention may include metal complexes having structures represented by the following formulae:

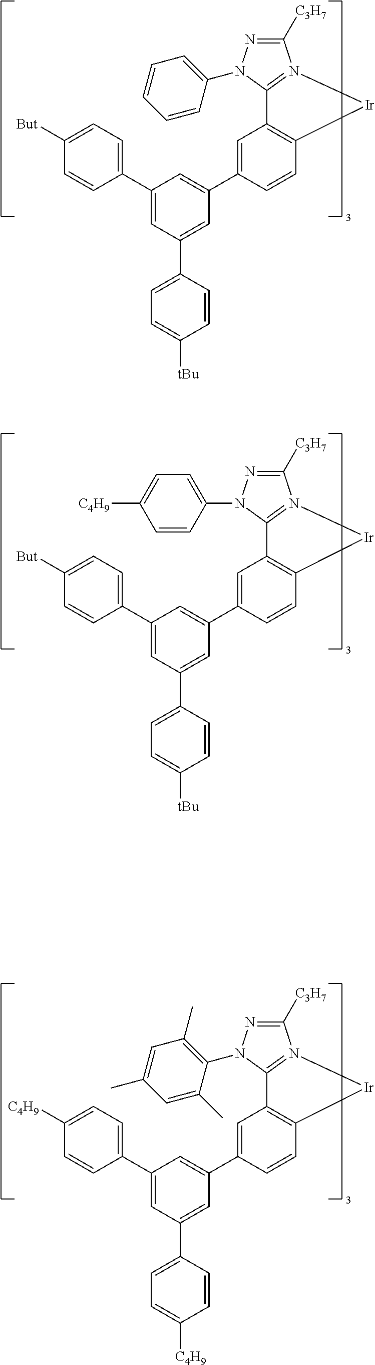

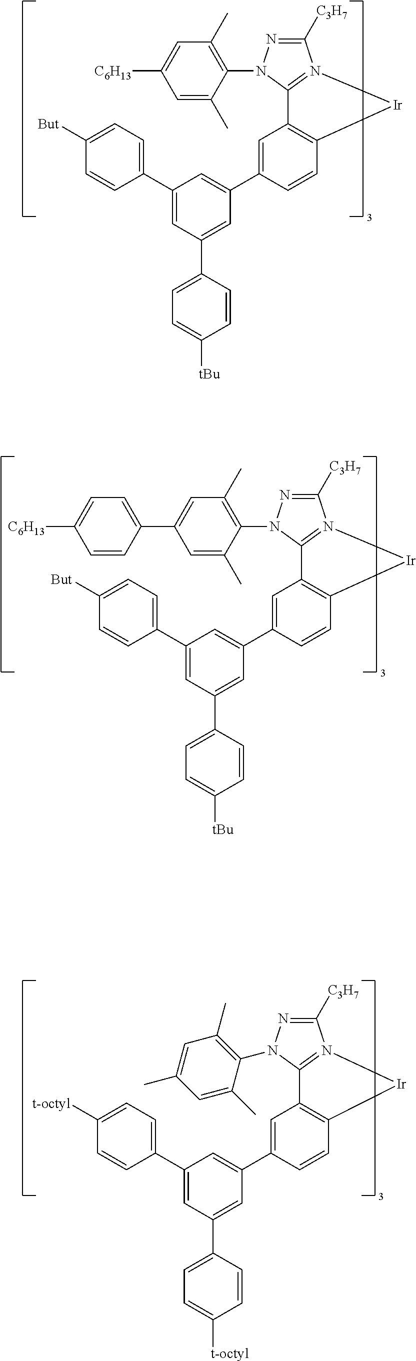

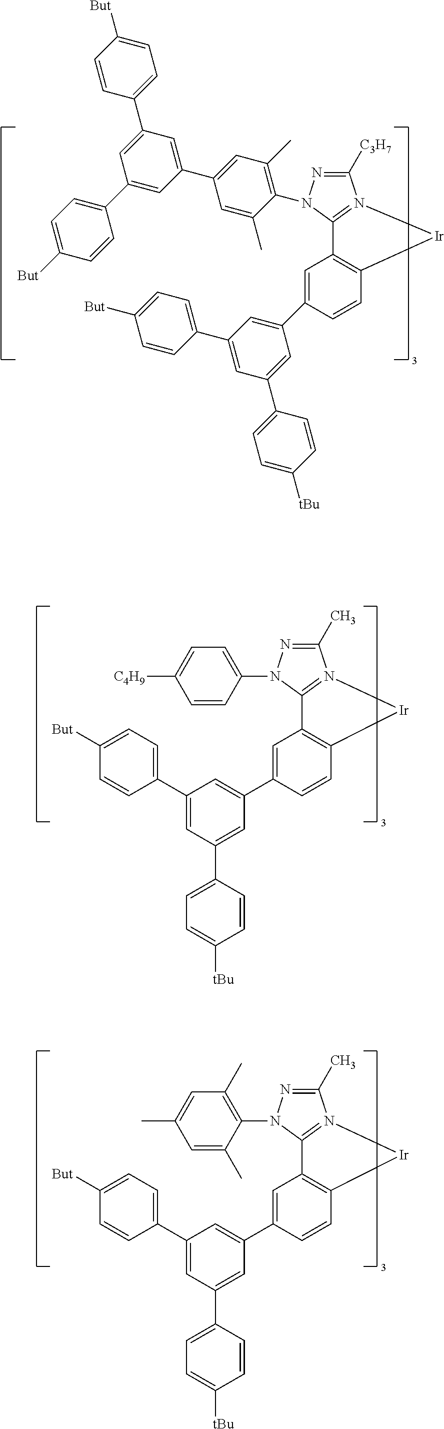

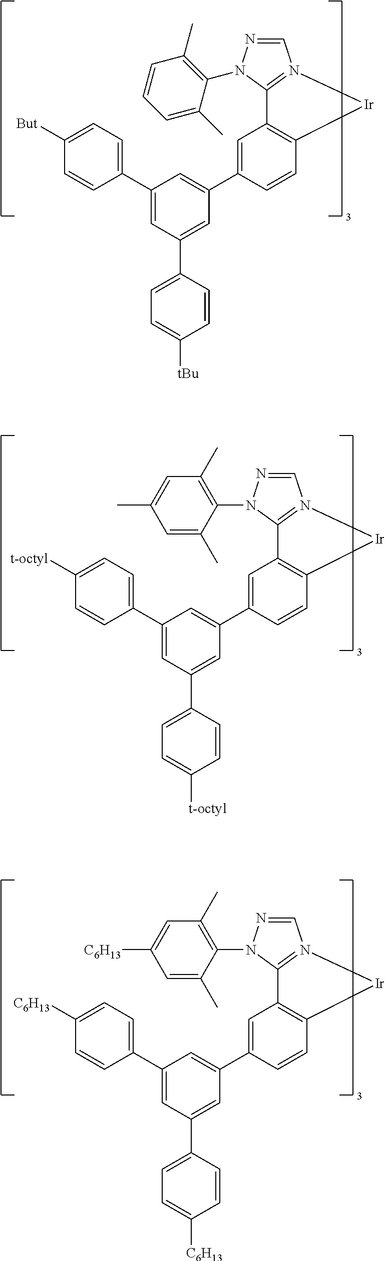

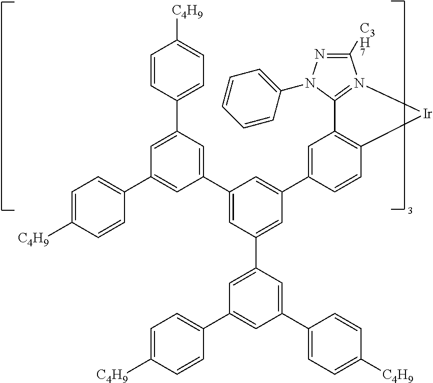

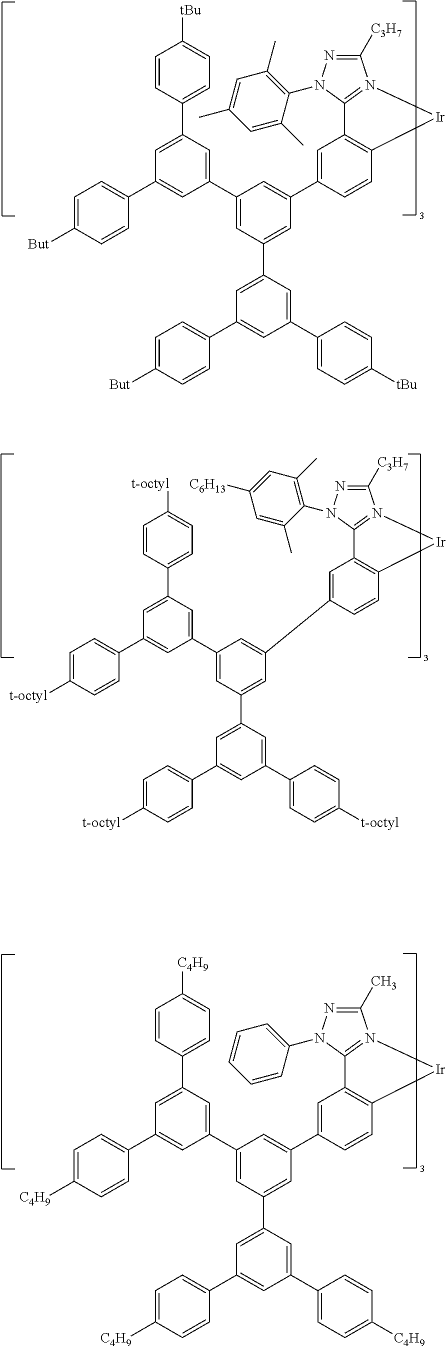

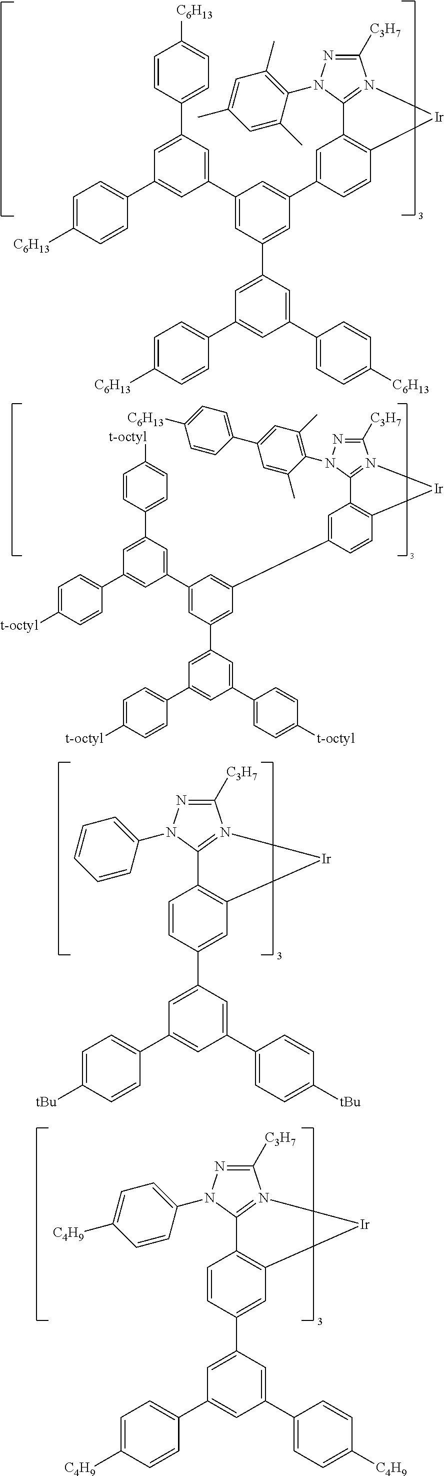

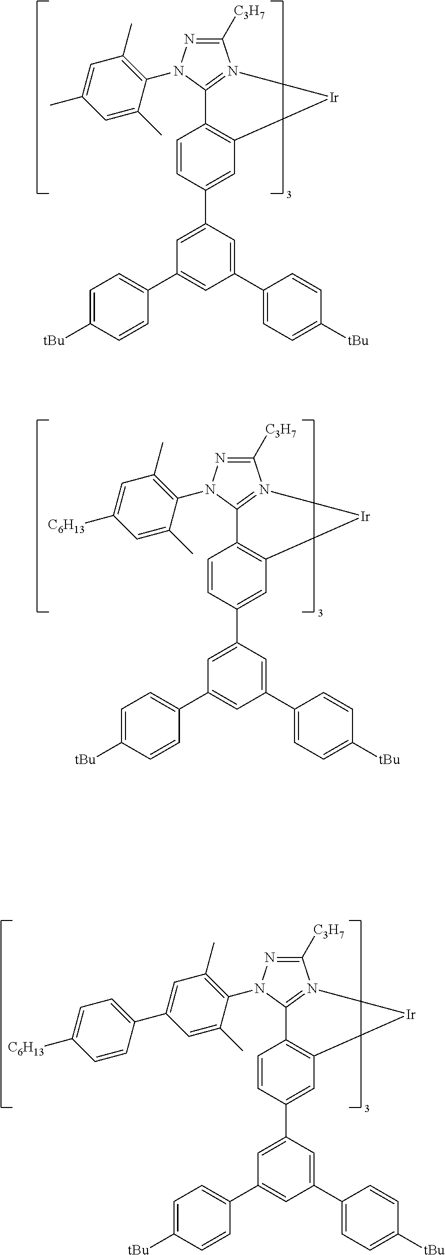

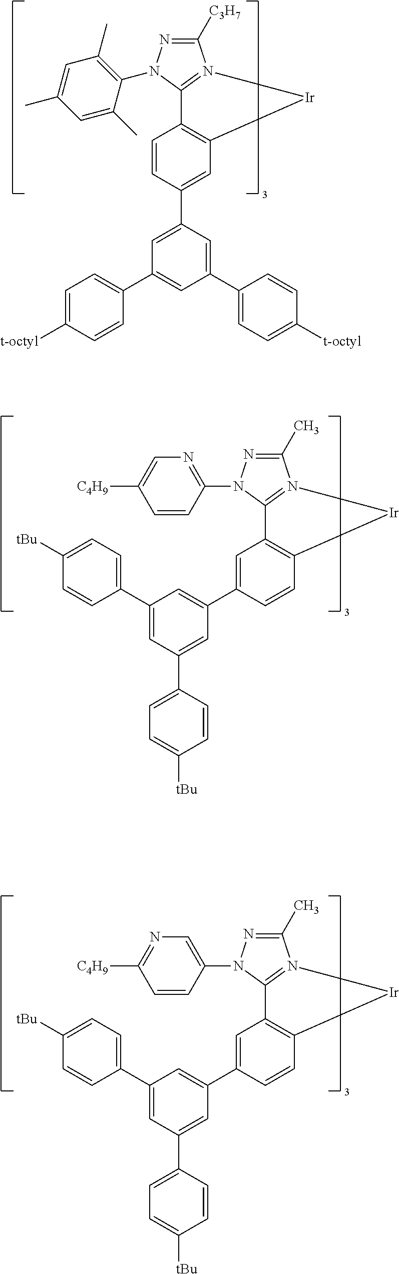

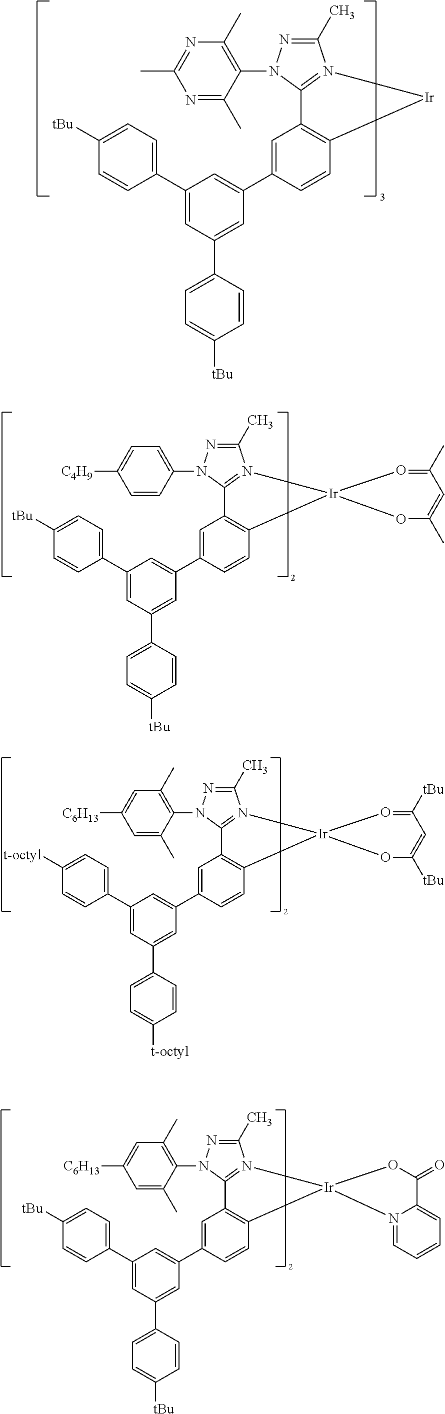

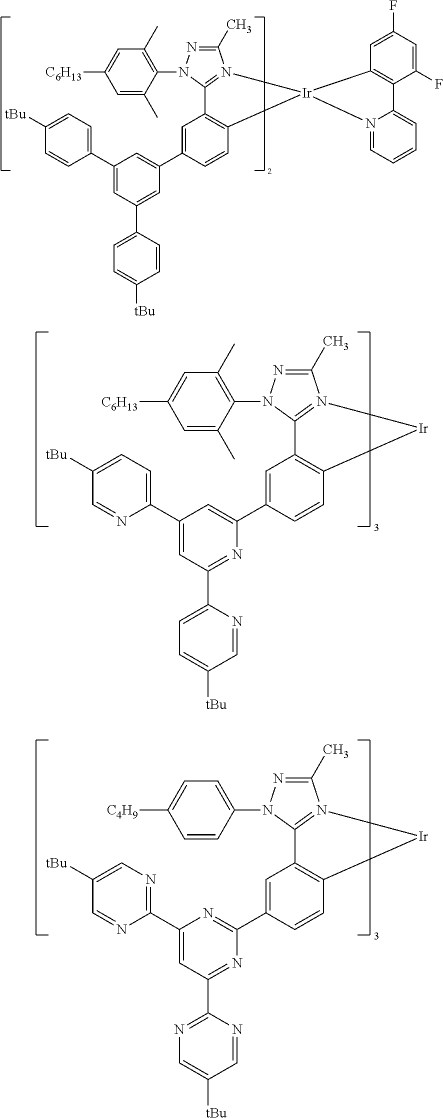

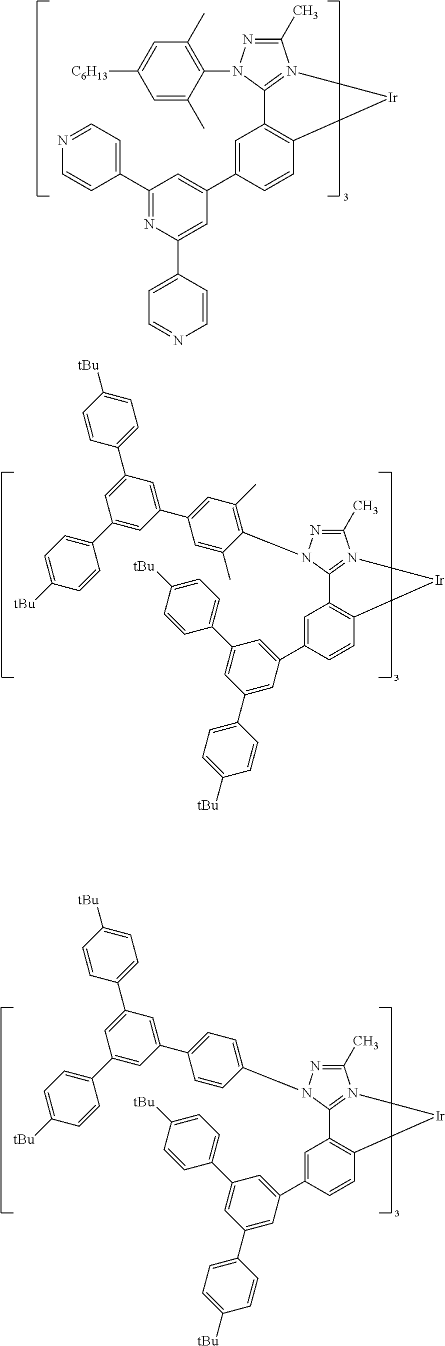

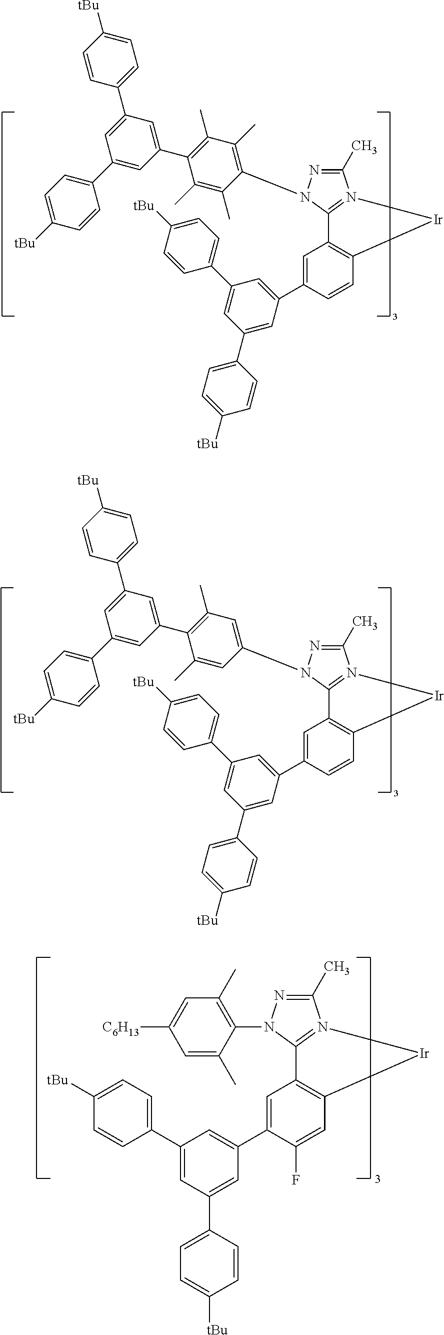

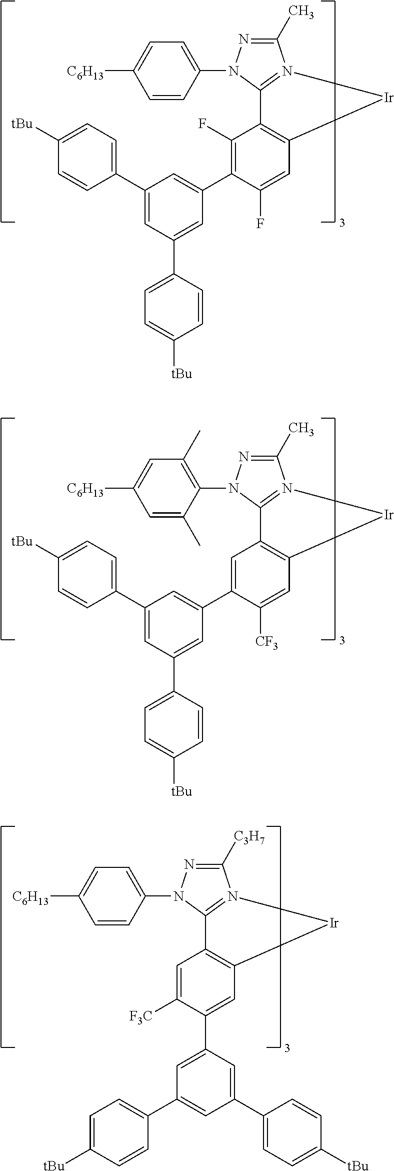

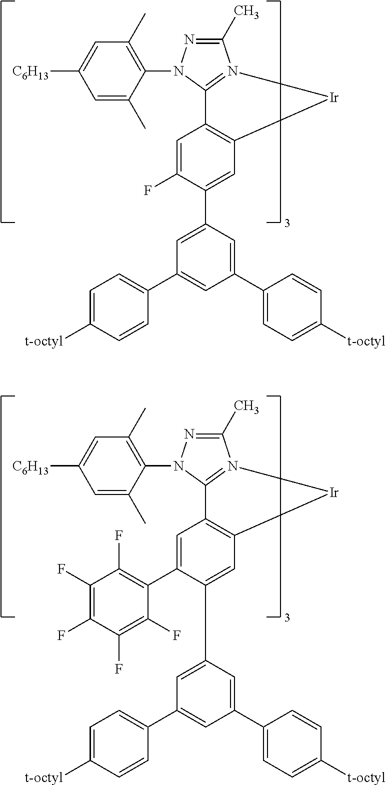

### Method for Manufacturing Metal Complex

Next, the synthesis method of the metal complex of the present invention is described.

The metal complex of the present invention can be synthesized, for example, by allowing a compound as a ligand to react with a metal compound in a solution. If necessary, a base, a silver chloride compound, or other compounds may exist in the reaction system. The metal complex of the present invention can also be synthesized by a coupling reaction of a metal complex having a 5-phenyl-1,2,4-triazole derivative as a ligand with an aromatic heterocyclic compound or a moiety of dendron.

Examples of the method for complexation (that is, the method for allowing a compound as a ligand to react with a metal compound in a solution), may include for a complex having an iridium atom, methods described in: J. Am. Chem. Soc. 1984, 106, 6647; Inorg. Chem. 1991, 30, 1685; Inorg. Chem. 1994, 33, 545; Inorg. Chem. 2001, 40, 1704; Chem. Lett., 2003, 32, 252; etc., for a complex having a platinum atom, methods described in: Inorg. Chem., 1984, 23, 4249; Chem. Mater. 1999, 11, 3709; Organometallics, 1999, 18, 1801; etc., and for a complex having a palladium atom, methods described in J. Org. Chem., 1987, 52, 73, etc.

Although the reaction temperature for the complexation is not limited, the reaction can be effected usually at a temperature between a melting point and a boiling point of a solvent, and the temperature is preferably from −78° C. to a boiling point of a solvent.

Although the reaction time is not limited, it is usually from 30 minutes to 30 hours. When a microwave reaction apparatus is used for the complexation reaction, the reaction can be effected at a temperature not only between a melting point and a boiling point of a solvent but also higher than the boiling point, and although the reaction time is not limited, it is usually from several minutes to several hours.

The compound as a ligand can be synthesized, for example, by Suzuki coupling, Grignard coupling, Stille coupling, or the like between 5-phenyl-1,2,4-triazole and an aromatic heterocyclic compound or a moiety of dendron. If necessary, the compound can be synthesized by: dissolving reactants in an organic solvent, and for example; and effecting a reaction at a temperature that is a melting point or higher and a boiling point or lower of the organic solvent, using a base, an appropriate catalyst, etc. These syntheses can employ methods described in, for example: “Organic Syntheses”, Collective Volume VI, pp. 407-411, John Wiley & Sons, Inc., 1988; Chem. Rev., vol. 106, p. 2651 (2006); Chem. Rev., vol. 102, p. 1359 (2002); Chem. Rev., vol. 95, p. 2457 (1995); and J. Organomet. Chem., vol. 576, p. 147 (1999).

The aromatic heterocyclic compound can be synthesized by methods described in: HOUBEN-WEYL METHODS OF ORGANIC CHEMISTRY 4^{TH} EDITION, vol. E9b, p. 1 (GEORG THIEME VERLAG STUTTGART); HOUBEN-WEYL METHODS OF ORGANIC CHEMISTRY 4^{TH} EDITION, vol. E9c, p. 667 (GEORG THIEME VERLAG STUTTGART); or the like.

The identification and the analysis of the obtained compound can be performed by a CHN elementary analysis, an NMR analysis, an MS analysis, and X-ray crystal structure analysis.

<Composition>

The composition of the present invention comprises the metal complex of the present invention and a charge transport material and may further comprise a light-emitting material.

The charge transport material is classified into a hole transport material and an electron transport material. Specifically, an organic compound (a small molecular organic compound and/or a polymer organic compound) can be used for the charge transport material.

Examples of the hole transport material may include aromatic amines, carbazole derivatives, and polyparaphenylene derivatives, which are publicly known as hole transport materials for an organic electroluminescent device. Examples of the electron transport material may include materials publicly known as an electron transport material for an organic electroluminescent device such as metal complexes of oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, and 8-hydroxyquinoline and derivatives thereof. The small molecular organic compound as the charge transport material means a host compound and a charge transport compound used for a small molecular organic electroluminescent device. Specific examples thereof may include compounds described in “Organic EL display” (co-authored by Shizuo Tokito, Chihaya Adachi, and Hideyuki Murata, Ohmsha, Ltd.) p. 107, “Monthly Display” (vol. 9, No. 9, 2003, pp. 26-30), Japanese Patent Application Laid-open No. 2004-244400, Japanese Patent Application Laid-open No. 2004-277377, and the like. Preferably, the lowest excited triplet energy of a charge transport material is higher than that of a metal complex, for obtaining satisfactory light emission from the metal complex.

Specific examples of the small molecular organic compound as the charge transport material include the following compounds.

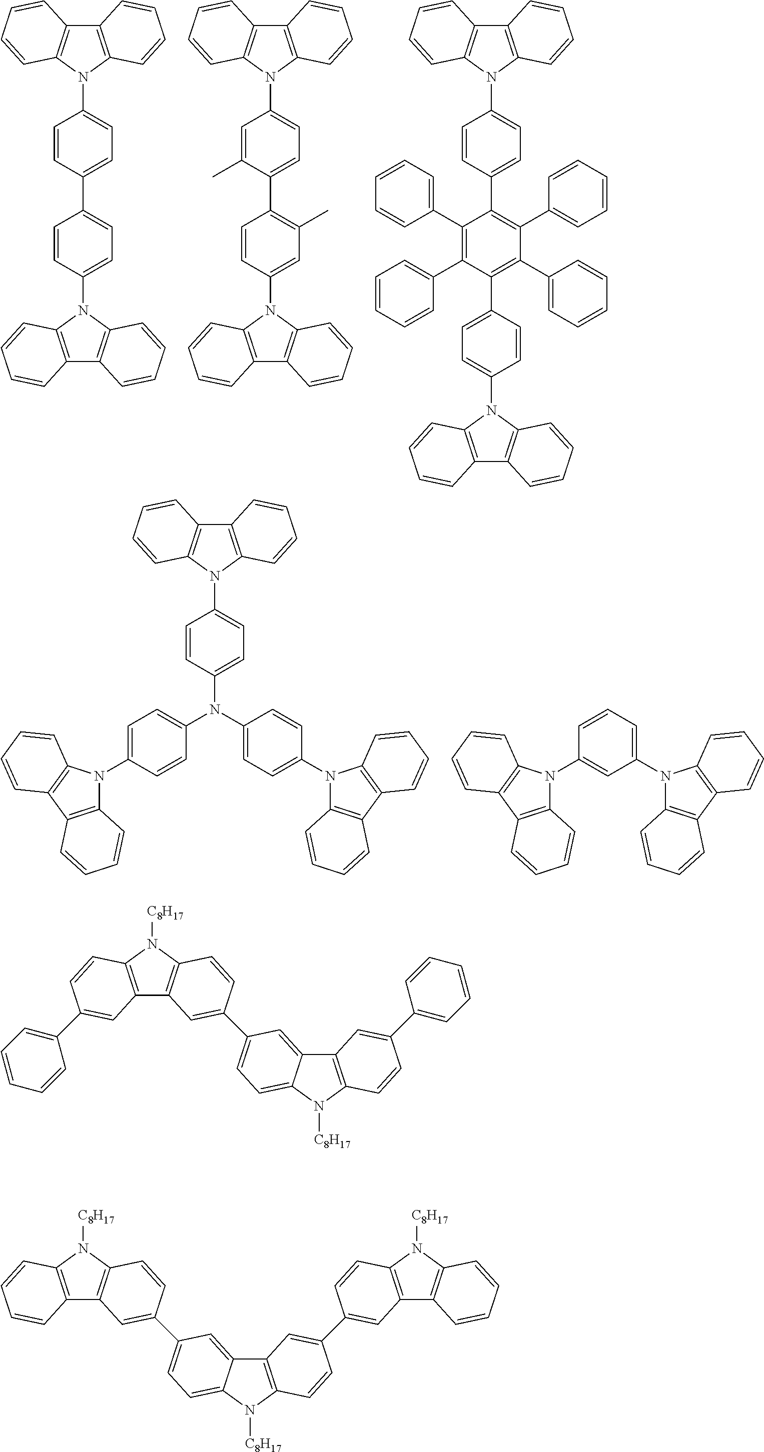

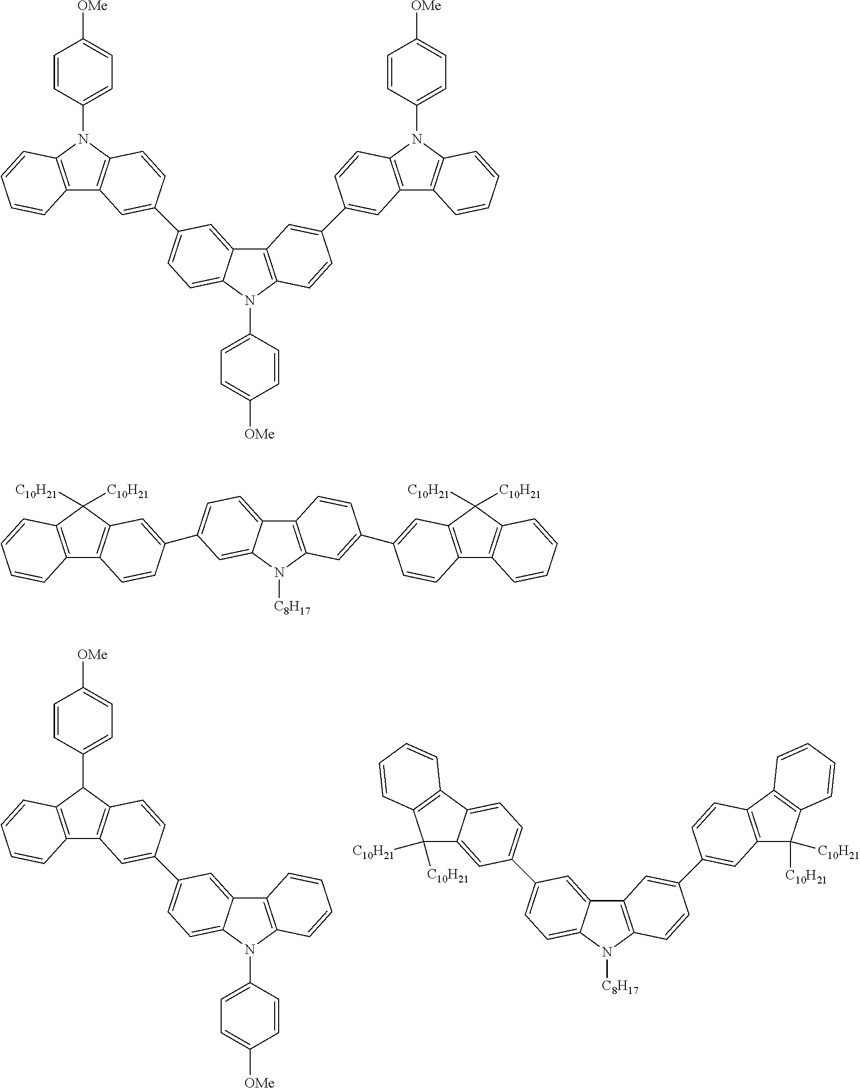

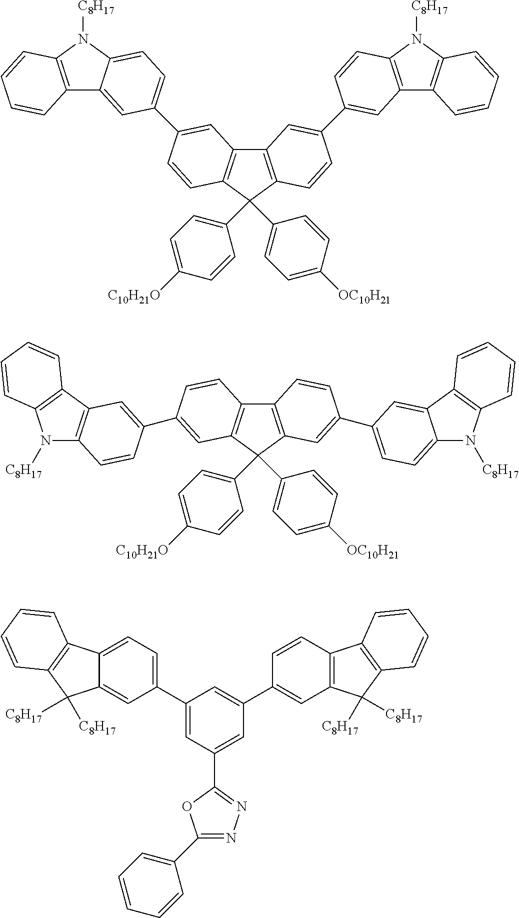

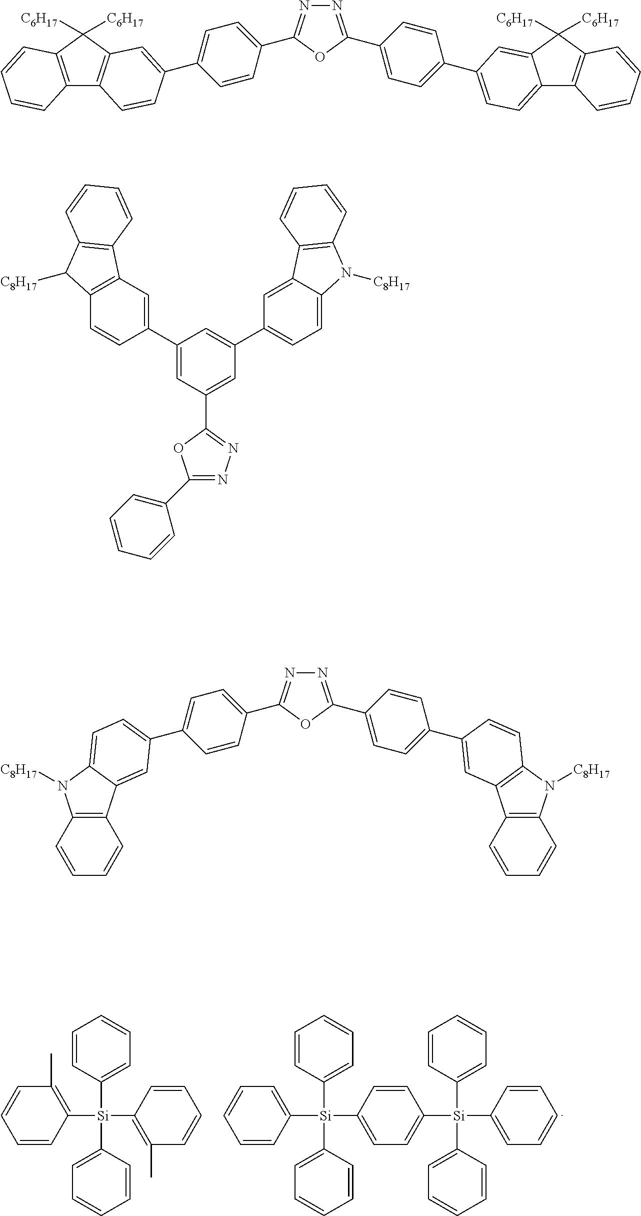

Examples of the polymer organic compound as the charge transport material may include non-conjugated polymer compounds and conjugated polymer compounds. Examples of the non-conjugated polymer compound may include a polyvinyl carbazole. A polymer compound comprises a unit selected from a phenylene group optionally having a substituent, a fluorene-diyl group optionally having a substituent, a dibenzothiophene-diyl group optionally having a substituent, a dibenzofuran-diyl group optionally having a substituent, and a dibenzosilole-diyl group optionally having a substituent; and copolymers of these groups with each other. Specific examples of the conjugated polymer compound may include polymer compounds having as a partial structure of a repeating unit thereof, a benzene ring optionally having a substituent. Further specific examples thereof may include polymer compounds described in, for example, Japanese Patent Application Laid-open No. 2003-231741, Japanese Patent Application Laid-open No. 2004-059899, Japanese Patent Application Laid-open No. 2004-002654, Japanese Patent Application Laid-open No. 2004-292546, U.S. Pat. No. 5,708,130, WO99/54385, WO00/46321, WO02/077060, “Organic EL display” (co-authored by Shizuo Tokito, Chihaya Adachi, and Hideyuki Murata, Ohmsha, Ltd.) p. 111, “Monthly Display” (vol. 9, No. 9, 2002), pp. 47-51), and the like.

The polymer organic compound as the charge transport material is preferably a compound comprising a group represented by Formula (I):

—Ar— (I)

(wherein Ar represents an arylene group, a divalent heterocyclic group, or a divalent aromatic amine residue, wherein these groups may have a substituent).

Examples of the arylene group represented by Ar in Formula (I) may include a phenylene group optionally having a substituent, a naphthylene group optionally having a substituent, and a divalent group represented by Formula (4a).

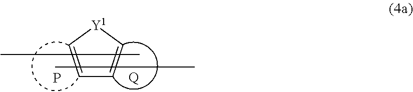

In Formula (4a), the ring P and the ring Q each independently represent an aromatic ring. Y¹ represents —C(R¹¹)(R¹²)—, —C(R¹⁴)(R¹⁵)—C(R¹⁶)(R¹⁷)—, or —C(R³²)═C(R³³)—. When a choice in which two ring-constitution elements are contained in Y¹ is selected from the choices of Y¹ below, the ring comprising Y¹ forms a 6-membered ring. When a choice in which one ring-constitution element is contained in Y¹ is selected from the choices of Y¹ below, the ring comprising Y¹ forms a 5-membered ring. The ring P may or may not exist. When the ring P exists, two bonds exist on the ring P or the ring Q or one bond exists on the ring P while the other bond exists on the ring Q. When the ring P does not exist, two bonds exist on the 5-membered or 6-membered ring comprising Y¹; two bonds exist on the ring Q; or one bond exists on the 5-membered or 6-membered ring comprising Y¹ while the other bond exists on the ring Q. The ring P, the ring Q, and the 5-membered or 6-membered ring comprising Y¹ may each independently have at least one substituent selected from the group consisting of an alkyl group, an alkyloxy group, an alkylthio group, an aryl group, an aryloxy group, an arylthio group, an arylalkyl group, an arylalkyloxy group, an arylalkylthio group, an arylalkenyl group, an arylalkynyl group, an amino group, a substituted amino group, a silyl group, a substituted silyl group, a halogen atom, an acyl group, an acyloxy group, an imine residue, a carbamoyl group, an amido group, an acid imido group, a monovalent heterocyclic group, a carboxy group, a substituted carboxy group, and a cyano group.

R¹¹, R¹², R¹⁴ to R¹⁷, R³², and R³³ each independently represent a hydrogen atom, an alkyl group, an alkyloxy group, an alkylthio group, an aryl group, an aryloxy group, an arylthio group, an arylalkyl group, an arylalkyloxy group, an arylalkylthio group, an arylalkenyl group, an arylalkynyl group, an amino group, a substituted amino group, a silyl group, a substituted silyl group, a silyloxy group, a substituted silyloxy group, a monovalent heterocyclic group, or a halogen atom.

In Formula (4a), an alkyl group, an alkyloxy group, an alkylthio group, an aryl group, an aryloxy group, an arylthio group, an arylalkyl group, an arylalkyloxy group, an arylalkylthio group, an arylalkenyl group, an arylalkynyl group, an amino group, a substituted amino group, a silyl group, a substituted silyl group, a halogen atom, an acyl group, an acyloxy group, an imine residue, a carbamoyl group, an amido group, an acid imido group, a monovalent heterocyclic group, a carboxy group, a substituted carboxy group, and a cyano group which are substituents which the ring P, the ring Q, and the 5-membered or 6-membered ring comprising Y¹ may have, are the same as the groups described and exemplified above as the groups represented by R^{P1}, R^{P2}, R^{P3}, R^{P4}, R^{P5}, and R^{P6}.

In Formula (4a), an alkyl group, an alkyloxy group, an alkylthio group, an aryl group, an aryloxy group, an arylthio group, an arylalkyl group, an arylalkyloxy group, an arylalkylthio group, an arylalkenyl group, an arylalkynyl group, an amino group, a substituted amino group, a silyl group, a substituted silyl group, a silyloxy group, a substituted silyloxy group, a monovalent heterocyclic group, and a halogen atom represented by R¹¹, R¹², R¹⁴ to R¹⁷, R³², and R³³ are the same as the groups described and exemplified above as the groups represented by R^{P1}, R^{P2}, R^{P3}, R^{P4}, R^{P5}, and R^{P6}.

In Formula (1), the divalent heterocyclic group represented by Ar refers to a group remaining after removing from a heterocyclic compound, two hydrogen atoms directly bonded to a carbon atom or a hetero atom constituting the ring of the heterocyclic compound. The divalent heterocyclic group may have a substituent. The heterocyclic compound refers to, among organic compounds having a cyclic structure, an organic compound comprising not only a carbon atom, but also one or more types of hetero atoms selected from the group consisting of an oxygen atom, a nitrogen atom, a silicon atom, a germanium atom, a tin atom, a phosphorus atom, a boron atom, a sulfur atom, a selenium atom, and a tellurium atom, as an element constituting the ring. Among divalent heterocyclic groups, a divalent aromatic heterocyclic group is preferred. The number of carbon atoms of the divalent heterocyclic group without the substituent is usually 3 to 60. The number of carbon atoms of the divalent heterocyclic group with the substituent is usually 3 to 100.

In Formula (1), examples of the arylene group represented by Ar may include a divalent group represented by Formula (5).

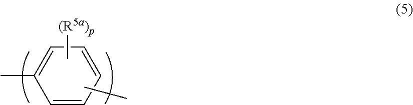

In Formula (5), p is 0, 1, 2, 3, or 4, and preferably 1 or 2; R^{5a} represents a substituent, and examples of the substituent may include a C₁₋₂₀ alkyl group and a phenyl group optionally having a substituent, wherein when more than one R^{5a} is present, a plurality of R^{5a}s may be the same as or different from each other.

The group represented by Formula (5) may have any one of 1,4 bonding, 1,2 bonding, and 1,3 bonding. Preferred examples of the group represented by Formula (5) may include groups represented by Formula (5) which have 1,4 bonding and in which p is 0, 1, 2, or 3. More preferred examples thereof may include groups having a structure represented by Formula (5a).

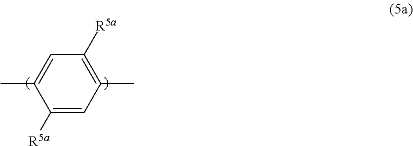

The charge transport material is classified into a hole transport material and an electron transport material. The charge transport material usually includes a material comprising a charge transport group. The electron transport material may include an electron transport group, and preferred examples thereof may include a group represented by Formula (7).

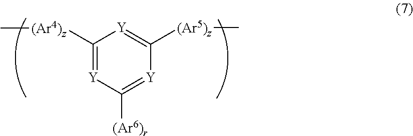

In Formula (7), Ar⁴ and Ar⁵ each independently represent an arylene group or a divalent heterocyclic group; z represents 0, 1, 2, or 3; Ar⁶ represents an aryl group or a monovalent heterocyclic group; r represents 0 or 1; and Y represents a nitrogen atom or —C(R^{7a})═, wherein R^{7a} represents a hydrogen atom or a substituent and preferred examples of the substituent may include a C₁₋₁₀ alkyl group.

Ar⁴ and Ar⁵ are preferably a phenylene group optionally having a substituent. Ar⁶ is preferably a phenyl group optionally having a substituent and is preferably a phenyl group comprising a C₁₋₂₀ alkyl group as a substituent.

It is preferred that all of three Ys be a nitrogen atom. When all of three Ys are —C(R^{7a})═, it is preferred that at least one of Ar⁴, Ar⁵, and Ar⁶ be a heterocyclic group comprising a nitrogen atom.

Ar⁴, Ar⁵, and Ar⁶ may have a substituent. Examples of the substituent may include a C₁₋₂₀ alkyl group and a C₁₋₂₀ alkoxy group.

The charge transport group may include a repeating unit capable of polymerization or an extended repeating unit comprising at least one charge transport group. Examples of the extended repeating unit may include groups represented by Formula (8).

(Ar³)_{q}-Sp-CT-Sp-(Ar³)_{q} (8)

In Formula (8), CT represents a charge transport group; Ar³s each independently represent a divalent aromatic carbocyclic group optionally having a substituent or a divalent heterocyclic group optionally having a substituent; q represents an integer of 1 or more, wherein two qs may be the same as or different from each other; and Sp represents a spacer group capable of breaking conjugation between Ar³ and CT.

Sp is preferably a C₁₋₂₀ branched, straight chain, or cyclic alkylene group, and more preferably a C₁₋₂₀ straight chain alkylene group.

Examples of the group represented by CT may include groups represented by Formula (7).

Ar³ is preferably a divalent aromatic carbocyclic group optionally having a substituent, and more preferably a phenylene group optionally having a substituent or a fluorene-diyl group optionally having a substituent. Examples of the substituent which Ar³ may have may include a C₁₋₂₀ alkyl group.

q is preferably 1.

In Formula (1), examples of the divalent heterocyclic group represented by Ar may include a divalent group represented by Formula (4b).

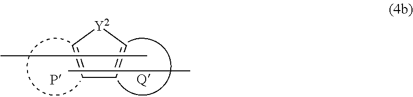

### In Formula (4b),

the ring P′ and the ring Q′ each independently represent an aromatic ring. Y² represents —O—, —S—, —Se—, —B(R⁶)—, —Si(R⁷)(R⁸)—, —P(R⁹)—, (═O)—, —N(R¹³)—, —O—C(R¹⁸)(R¹⁹)—, —S—C(R²⁰)(R²¹)—N—O(R²²)(R²³)—Si(R²⁴)(R²⁵)—C(R²⁶)(R²⁷)—, —Si(R²⁸)(R²⁹)—Si(R³⁰)(R³¹)(R³⁴)—, —N═C(R³⁴)—, or —Si(R³⁵)═C(R³⁶)—. When a choice in which two ring-constitution elements are contained in Y² is selected from the choices of Y² below, the ring comprising Y² forms a 6-membered ring. When a choice in which one ring-constitution elements are contained in Y² is selected from the choices of Y² below, the ring comprising Y² forms a 5-membered ring. The ring P′ may or may not exist. When the ring P′ exists, two bonds exist on the ring P′ or the ring Q′; or one bond exists on the ring P′ and the other bond exists on the ring Q′. When the ring P′ does not exist, two bonds exist on the 5-membered or 6-membered ring comprising Y²; two bonds exist on the ring Q′; or one bond exists on the 5-membered or 6-membered ring comprising Y² and the other bond exists on the ring Q′. The ring P′, the ring Q′, and the 5-membered or 6-membered ring comprising Y² may each independently have at least one substituent selected from the group consisting of an alkyl group, an alkyloxy group, an alkylthio group, an aryl group, an aryloxy group, an arylthio group, an arylalkyl group, an arylalkyloxy group, an arylalkylthio group, an arylalkenyl group, an arylalkynyl group, an amino group, a substituted amino group, a silyl group, a substituted silyl group, a halogen atom, an acyl group, an acyloxy group, an imine residue, a carbamoyl group, an amido group, an acid imido group, a monovalent heterocyclic group, a carboxy group, a substituted carboxy group, and a cyano group.

R⁶ to R¹⁰, R¹³, R¹⁸ to R³¹, and R³⁴ to R³⁶ each independently represent a hydrogen atom, an alkyl group, an alkyloxy group, an alkylthio group, an aryl group, an aryloxy group, an arylthio group, an arylalkyl group, an arylalkyloxy group, an arylalkylthio group, an arylalkenyl group, an arylalkynyl group, an amino group, a substituted amino group, a silyl group, a substituted silyl group, a silyloxy group, a substituted silyloxy group, a monovalent heterocyclic group, or a halogen atom.

In Formula (4b), An alkyl group, an alkyloxy group, an alkylthio group, an aryl group, an aryloxy group, an arylthio group, an arylalkyl group, an arylalkyloxy group, an arylalkylthio group, an arylalkenyl group, an arylalkynyl group, an amino group, a substituted amino group, a silyl group, a substituted silyl group, a halogen atom, an acyl group, an acyloxy group, an imine residue, a carbamoyl group, an amido group, an acid imido group, a monovalent heterocyclic group, a carboxy group, a substituted carboxy group, and a cyano group which are substituents which the ring P′, the ring Q′, and the 5-membered or 6-membered ring comprising Y² may have are the same as the groups described and exemplified above as the groups represented by R^{P1}, R^{P2}, R^{P3}, R^{P4}, R^{P5}, and R^{P6}.

In Formula (4b), an alkyl group, an alkyloxy group, an alkylthio group, an aryl group, an aryloxy group, an arylthio group, an arylalkyl group, an arylalkyloxy group, an arylalkylthio group, an arylalkenyl group, an arylalkynyl group, an amino group, a substituted amino group, a silyl group, a substituted silyl group, a silyloxy group, a substituted silyloxy group, a monovalent heterocyclic group, and a halogen atom represented by R⁶ to R¹⁰, R¹³, R¹⁸ to R³¹, and R³⁴ to R³⁶ are the same as thegroups described and exemplified above as the groups represented by R^{P1}, R^{P2}, R^{P3}, R^{P4}, R^{P5}, and R^{P6}.

In Formula (I), the divalent aromatic amine residue represented by Ar means a group remaining after removing two hydrogen atoms from an aromatic amine. The divalent aromatic amine residue may have a substituent described below. The divalent aromatic amine residue has the number of carbon atoms of usually 5 to 100, and preferably 15 to 60. In the number of carbon atom(s) of the divalent aromatic amine residue, the number of carbon atom(s) of the substituent is not included.

In Formula (1), examples of the divalent aromatic amine residue represented by Ar may include a divalent group represented by Formula (6).

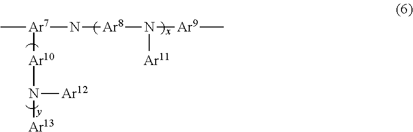

### In Formula (6),

Ar⁷, Ar⁸, Ar⁹, and Ar¹⁰ each independently represent an arylene group or a divalent heterocyclic group; Ar¹¹, Ar¹², and Ar¹³ each independently represent an aryl group or a monovalent heterocyclic group; Ar⁷ to Ar¹³ may have a substituent; and

x and y are each independently 0 or 1.

In Formula (6), the arylene group represented by Ar⁷ to Ar¹⁰ means a group remaining after removing, from an aromatic hydrocarbon, two hydrogen atoms directly bonded to a carbon atom constituting the ring of the aromatic hydrocarbon. Examples of the aromatic hydrocarbon may include a fused ring, and a moiety constituted of two or more rings selected from independent benzene ring(s) and fused ring(s) in which two or more rings are bonded directly or bonded through a vinylene group. The arylene group may have a substituent. The number of carbon atoms of the arylene group without the substituent is usually 6 to 60, and preferably 6 to 20. The number of carbon atoms of the arylene group with the substituent is usually 6 to 100.

In Formula (6), the divalent heterocyclic group represented by Ar⁷ to Ar¹⁰ is the same as the divalent heterocyclic group described and exemplified above as the divalent heterocyclic group represented by Ar.

In Formula (6), the aryl group and the monovalent heterocyclic group represented by Ar¹¹ to Ar¹³ are the same as the groups described and exemplified above as the aryl group and the monovalent heterocyclic group represented by R^{P1}, R^{P2}, R^{P3}, R^{P4}, R^{P5}, and R^{P6}.

In Formula (6), the arylene group, the divalent heterocyclic group, the aryl group, and the monovalent heterocyclic group may have at least one substituent selected from the group consisting of an alkyl group, an alkyloxy group, an alkylthio group, an aryl group, an aryloxy group, an arylthio group, an arylalkyl group, an arylalkyloxy group, an arylalkylthio group, an arylalkenyl group, an arylalkynyl group, an amino group, a substituted amino group, a silyl group, a substituted silyl group, a halogen atom, an acyl group, an acyloxy group, an imine residue, a carbamoyl group, an amido group, an acid imido group, a monovalent heterocyclic group, a carboxy group, a substituted carboxy group, a cyano group, and a nitro group. These substituents are the same as the groups described and exemplified above as the groups represented by R^{P1}, R^{P2}, R^{P3}, R^{P4}, R^{P5}, and R^{P6}.

Examples of the groups represented by Formula (4a) and Formula (4b) may include groups represented by Formula (4-1), Formula (4-2), Formula (4-3), Formula (4-4) or Formula (4-5):

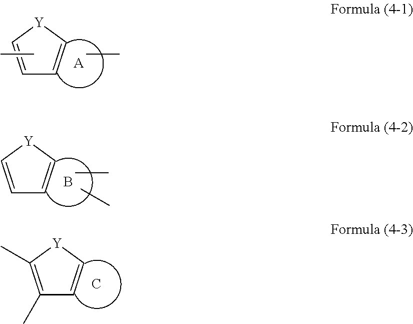

wherein,

the ring A, the ring B, and the ring C each independently represent an aromatic ring;

Y represents the same as the above Y¹ or the same as the above Y²;

the ring A, the ring B, the ring C, and the 5-membered or 6-membered ring comprising Y may each independently have one or more substituent(s) selected from the group consisting of an alkyl group, an alkyloxy group, an alkylthio group, an aryl group, an aryloxy group, an arylthio group, an arylalkyl group, an arylalkyloxy group, an arylalkylthio group, an arylalkenyl group, an arylalkynyl group, an amino group, a substituted amino group, a silyl group, a substituted silyl group, a halogen atom, an acyl group, an acyloxy group, an imine residue, a carbamoyl group, an amido group, an acid imido group, a monovalent heterocyclic group, a carboxy group, a substituted carboxy group, and a cyano group.

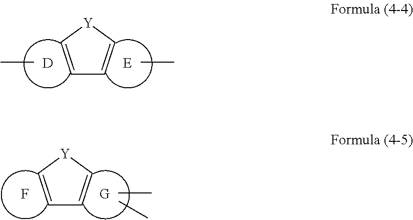

wherein

the ring D, the ring E, the ring F, and the ring G each independently represent an aromatic ring;

Y represents the same as the above Y¹ or the same as the above Y²;

the ring D, the ring E, the ring F, the ring G, and the 5-membered or 6-membered ring comprising Y may each independently have one or more substituent(s) selected from the group consisting of an alkyl group, an alkyloxy group, an alkylthio group, an aryl group, an aryloxy group, an arylthio group, an arylalkyl group, an arylalkyloxy group, an arylalkylthio group, an arylalkenyl group, an arylalkynyl group, an amino group, a substituted amino group, a silyl group, a substituted silyl group, a halogen atom, an acyl group, an acyloxy group, an imine residue, a carbamoyl group, an amido group, an acid imido group, a monovalent heterocyclic group, a carboxy group, a substituted carboxy group, and a cyano group. The groups represented by Formula (4a) and Formula (4b) are preferably a group represented by Formula (4-4) or Formula (4-5).

In Formula (4-1) to Formula (4-5), Y is preferably —S—, —O—, —C(R¹¹)(R¹²)— or —N(R¹³)— from the viewpoint of the luminous efficiency of the light-emitting device manufactured using the composition of the present invention, and more preferably —S—, —O—, or —N(R¹³)—.

Examples of the aromatic rings in Formulae (4-1) to (4-5) may include: aromatic carbocyclic rings such as a benzene ring, a naphthalene ring, an anthracene ring, a tetracene ring, a pentacene ring, a pyrene ring, and a phenanthrene ring; and aromatic heterocyclic rings such as a pyridine ring, a phenanthroline ring, a quinoline ring, an isoquinoline ring, a thiophene ring, a furan ring, and a pyrrole ring.

Preferred examples of the substituent which the group represented by Formulae (4-1) to (4-5) may have may include an alkyl group, an alkyloxy group, an alkylthio group, an aryl group, an aryloxy group, an arylthio group, an arylalkyl group, an arylalkyloxy group, an arylalkylthio group, an arylalkenyl group, an arylalkynyl group, an amino group, a substituted amino group, a silyl group, a substituted silyl group, an acyloxy group, an imine residue, a carbamoyl group, an amido group, an acid imido group, a monovalent heterocyclic group, a carboxy group, and a substituted carboxy group, and more preferred example thereof may include an alkyl group, an alkyloxy group, an aryl group, and a monovalent heterocyclic group.

The polymer organic compound as the charge transport material is, for example, a polymer organic compound comprising groups below (that is, groups removed parentheses from the following examples), and particularly preferably a polymer organic compound comprising the following structures as repeating units.

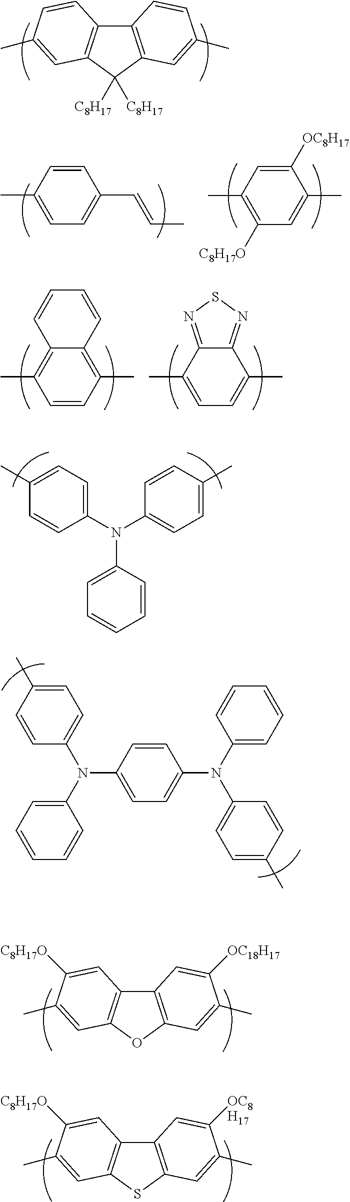

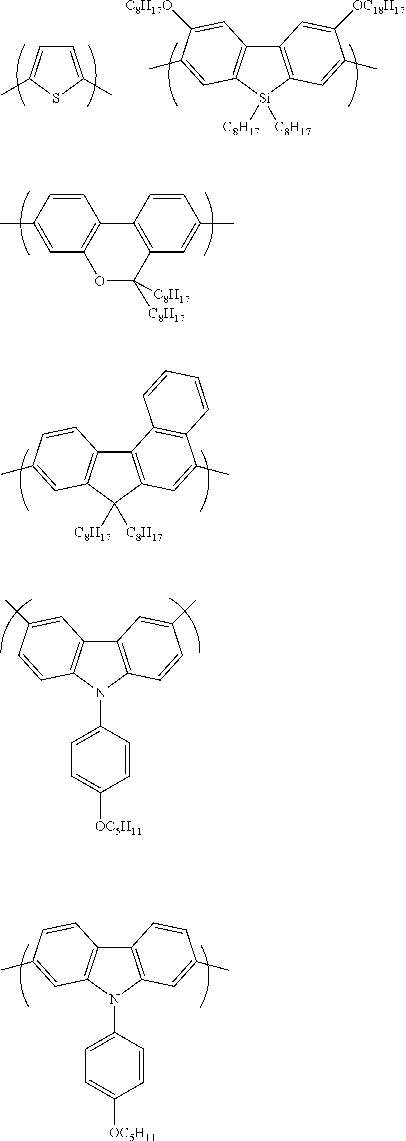

A relation of the lowest triplet excited energy of the charge transport material represented by small molecular organic compound or a polymer organic compound (TH) and the lowest triplet excited energy of the metal complex of the present invention (TM) satisfies preferably with TH>TM−0.1 (eV), more preferably satisfies with TH>TM, and further preferably satisfies with TH>TM+0.1 (eV).

In the use of the polymer organic compound as the charge transport material, the polymer organic compound has a polystyrene equivalent number average molecular weight of preferably 10³ to 10⁸, and more preferably 10⁴ to 10⁶. The polymer organic compound has a polystyrene equivalent weight average molecular weight of preferably 10³ to 10⁸, and more preferably 5×10⁴ to 5×10⁶.

As the light-emitting material, a publicly known light-emitting material can be used. It may include small molecular light-emitting materials such as naphthalene derivatives, anthracene and derivatives thereof, perylene and derivatives thereof, dyes such as polymethine dyes, xanthene dyes, coumarin dyes, and cyanine dyes, metal complexes of 8-hydroxyquinoline and derivatives thereof, aromatic amines, tetraphenylcyclopentadiene and derivatives thereof, and tetraphenylbutadiene and derivatives thereof.

The content of the metal complex of the present invention in the composition of the present invention is usually 0.1 to 80 parts by weight, preferably 0.1 to 60 parts by weight, and more preferably 0.1 to 40 parts by weight, relative to 100 parts by weight of the whole weight of the composition of the present invention. The metal complexes of the present invention may be used singly or in combination of two or more types thereof.

<Liquid Composition>

The composition of the present invention may be a composition further comprising a solvent or a dispersion medium (hereinafter, may be called a “liquid composition”). The solvent or the dispersion medium used for the liquid composition of the present invention can be appropriately selected for use from publicly known solvents which can homogeneously dissolve or disperse the component of the film and is stable. Examples of such a solvent may include chlorinated solvents (chloroform, methylene chloride, 1,2-dichloroethane, 1,1,2-trichloroethane, chlorobenzene, o-dichlorobenzene, and the like), ether solvents (tetrahydrofuran, dioxane, and the like), aromatic hydrocarbon solvents (benzene, toluene, xylene, and the like), aliphatic hydrocarbon solvents (cyclohexane, methylcyclohexane, n-pentane, n-hexane, n-heptane, n-octane, n-nonane, n-decane, and the like), ketone solvents (acetone, methyl ethyl ketone, cyclohexanone, and the like), ester solvents (ethyl acetate, butyl acetate, ethylcellosolve acetate, and the like), polyhydric alcohols and derivatives thereof (ethylene glycol, ethylene glycol monobutyl ether, ethylene glycol monoethyl ether, ethylene glycol monomethyl ether, di(methyloxy)ethane, propylene glycol, di(ethyloxy)methane, triethylene glycol monoethyl ether, glycerin, 1,2-hexanediol, and the like), alcohol solvents (methanol, ethanol, propanol, isopropanol, cyclohexanol, and the like), sulfoxide solvents (dimethylsulfoxide and the like), and amide solvents (N-methyl-2-pyrrolidone, N,N-dimethylformamide, and the like). These solvents may be used singly or in combination of two or more types thereof.

When the liquid composition is applied to an inkjet printing method, the liquid composition may comprise publicly known additives for favorable discharge properties of the liquid composition and reproducibility of the discharge properties. Examples of the publicly known additives may include solvents (anisole, bicyclohexylbenzene, and the like) having a high boiling point for suppressing evaporation of the liquid composition through a nozzle. The liquid composition comprising the publicly known additive has a viscosity at 25° C. of preferably 1 to 100 mPa·s.

<Light-Emitting Device>

The light-emitting device of the present invention comprises a pair of electrodes consisting of an anode and a cathode; and film(s) that is sandwiched between the electrodes, which is/are composed of one layer (single layer type) or a plurality of layers (multilayer type) comprising at least a light-emitting layer. At least one layer of the film(s) comprises the metal complex of the present invention. The content of the metal complex of the present invention in the film is usually 0.1 to 100% by weight, preferably 0.1 to 80% by weight, more preferably 0.1 to 60% by weight, and further preferably 0.1 to 40% by weight, based on the whole weight of the film. The light-emitting device of the present invention preferably comprises the light-emitting layer comprising the metal complex of the present invention. The content of the metal complex of the present invention in the light-emitting layer is usually 0.1 to 100% by weight, preferably 0.1 to 80% by weight, more preferably 0.1 to 60% by weight, and further preferably 0.1 to 40% by weight, based on the whole weight of the light-emitting layer.

When the light-emitting device of the present invention is single layer type, the film is the light-emitting layer comprising the metal complex of the present invention. For example, layer configurations are shown below.

a) Anode/light-emitting layer/cathode
When the light-emitting device of the present invention is a multilayer type, the light-emitting device takes, for example, layer configurations below.
b) Anode/hole injection layer (hole transport layer)/light-emitting layer/cathode
c) Anode/light-emitting layer/electron injection layer (electron transport layer)/cathode
d) Anode/hole injection layer (hole transport layer)/light-emitting layer/electron injection layer (electron transport layer)/cathode

Here, the “hole injection layer (hole transport layer)” means the hole injection layer or the hole transport layer, and the “electron injection layer (electron transport layer)” means the electron injection layer or the electron transport layer.

The anode of the light-emitting device of the present invention supplies holes to the hole injection layer, the hole transport layer, the light-emitting layer, and the like. It is effective that the anode has a work function of 4.5 eV or more. As the material for the anode, metals, alloys, metal oxides, electrically conductive compounds, mixtures thereof, and the like can be used. Specific examples thereof may include: conductive metal oxides such as tin oxide, zinc oxide, indium oxide, and indium-tin-oxide (ITO); metals such as gold, silver, chromium, and nickel; mixtures or layered products of these conductive metal oxides with the metals; inorganic conductive substances such as copper iodide and copper sulfide; organic conductive materials such as polyanilines, polythiophenes (PEDOT and the like), and polypyrroles; and layered products of these with ITO.

The cathode of the light-emitting device of the present invention supplies electrons to the electron injection layer, the electron transport layer, and the light-emitting layer. As the material for the cathode, metals, alloys, metal halogenides, metal oxides, electrically conductive compounds, and mixtures thereof can be used. Specific examples of the material for the cathode may include alkali metals (lithium, sodium, potassium, cesium, and the like) and fluorides and oxides thereof; alkaline earth metals (magnesium, calcium, barium, and the like) and fluorides and oxides thereof; gold, silver, lead, aluminum, and alloys and mixed metals (a sodium-potassium alloy, a sodium-potassium mixed metal, a lithium-aluminum alloy, a lithium-aluminum mixed metal, a magnesium-silver alloy, a magnesium-silver mixed metal, and the like); and rare earth metals (indium, ytterbium, and the like).

The hole injection layer and the hole transport layer of the light-emitting device of the present invention may be layers having any one of the function of injecting holes from the anode, the function of transporting holes, and the function of blocking electrons injected from the cathode. The material for these layers can be appropriately selected from publicly known materials to be used. Specific examples of the material may include carbazole derivatives, triazole derivatives, oxazole derivatives, oxadiazole derivatives, imidazole derivatives, polyaryl alkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidene-based compounds, porphyrin-based compounds, polysilane-based compounds, poly(N-vinylcarbazole) derivatives, organic silane derivatives, the metal complex of the present invention, and the like, and polymers comprising these compounds. Other specific examples thereof may include aniline-based copolymers and conductive macromolecular oligomers such as thiophene oligomer and polythiophene. These materials may be used singly or in combination of plural types thereof. The hole injection layer and the hole transport layer may have either a single layer structure comprising one or two or more type(s) of the above materials or a multilayer structure comprising a plurality of layers having compositions the same as or different from each other.

The electron injection layer and the electron transport layer of the light-emitting device of the present invention may be layers having any one of the function of injecting electrons from the cathode, the function of transporting electrons, and the function of blocking holes injected from the anode. The material for these layers can be appropriately selected from publicly known materials to be used. Specific examples thereof may include: triazole derivatives, oxazole derivatives, oxadiazole derivatives, imidazole derivatives, fluorenone derivatives, anthraquinodimethane derivatives, anthrone derivatives, diphenylquinone derivatives, thiopyran dioxide derivatives, carbodiimide derivatives, fluorenylidene methane derivatives, distyrylpyrazine derivatives, aromatic ring tetracarboxylic acids anhydride of naphthalene, perylene, and the like, and various metal complexes represented by metal complexes of phthalocyanine derivatives and 8-quinolinol derivatives and metal complexes having as a ligand, metal phthalocyanine, benzoxazole, or benzothiazole, organic silane derivatives, the metal complex compound of the present invention, and the like. The electron injection layer and the electron transport layer may have either a single layer structure comprising one or two or more type(s) of the above materials or a multilayer structure comprising a plurality of layers having compositions the same as or different from each other.

In the light-emitting device of the present invention, as the material for the electron injection layer and the electron transport layer, inorganic compounds of an insulator or a semiconductor can also be used. When the electron injection layer and the electron transport layer are made up with an insulator or a semiconductor, a leak of the current can be effectively prevented and electron injecting properties can be enhanced. For such an insulator, at least one metal compound selected from the group consisting of chalcogenides of alkali metals, chalcogenides of alkaline earth metals, halides of alkali metals, and halides of alkaline earth metals, can be used. Specific preferred examples of chalcogenides of alkali metals may include CaO, BaO, SrO, BeO, BaS, and CaSe. Examples of the semiconductor making up the electron injection layer and the electron transport layer may include oxides, nitrides, and oxynitrides which comprise at least one element selected from the group consisting of Ba, Ca, Sr, Yb, Al, Ga, In, Li, Na, Cd, Mg, Si, Ta, Sb, and Zn. These oxides, nitrides, and oxynitrides may be used singly or in combination of two or more types thereof.

In the present invention, a reductive dopant may be added to an interface region between the cathode and a film in contact with the cathode. As the reductive dopant, preferred is at least one compound selected from the group consisting of alkali metals, oxides of alkaline earth metals, alkaline earth metals, rare earth metals, oxides of alkali metals, halides of alkali metals, oxides of alkaline earth metals, halides of alkaline earth metals, oxides of rare earth metals, halides of rare earth metals, alkali metal complexes, alkaline earth metal complexes, and rare earth metal complexes.

The light-emitting layer of the light-emitting device of the present invention has the function of capable of injecting holes from the anode, the hole injection layer, or the hole transport layer and injecting electrons from the cathode, the electron injection layer, or the electron transport layer during the electric field application, the function of moving the injected charges (electrons and holes) by the force of the electric field, and the function of providing a field for the recombination of the electrons and the holes to lead the recombination to the light emission. The light-emitting layer of the light-emitting device of the present invention comprises preferably the metal complex of the present invention and may contain a host material with which the metal complex serves as a guest material. Examples of the host material may include the above charge transport materials. A light-emitting layer can be formed by applying a mixture of the host material and the light-emitting material such as the metal complex, or by co-deposition of the host material and the light-emitting material, for example.

In the light-emitting device of the present invention, the method for forming each of the layers is not limited and publicly known methods can be used. Specific examples of the method may include vacuum deposition methods (resistance heating deposition method, electron beam method, and the like), a sputtering method, a Langmuir-Blodgett (LB) method, a molecule stacking method, and coating methods (a casting method, a spin coating method, a bar coating method, a blade coating method, a roll coating method, a gravure printing method, a screen printing method, an inkjet printing method, and the like). Among them, because the manufacturing process can be simplified, the films are preferably formed by a coating method. The coating method can form a film by: dissolving the metal complex of the present invention in a solvent to prepare a coating liquid; and coating a desired layer (or an electrode) with the coating liquid and drying the coating liquid. The coating liquid may comprise a resin as a host material and/or a binder, and the resin may be either in a dissolved state or in a dispersed state in a solvent. The resin can be selected from, for example, polyvinyl chloride, a polycarbonate, polystyrene, polymethyl methacrylate, polybutyl methacrylate, a polyester, a polysulfone, polyphenylene oxide, polybutadiene, poly(N-vinylcarbazole), a hydrocarbon resin, a ketone resin, a phenyloxy resin, a polyamide, ethyl cellulose, vinyl acetate, an acrylonitrile-butadiene-styrene (ABS) resin, polyurethane, a melamine resin, an unsaturated polyester resin, an alkyd resin, an epoxy resin, a silicon resin, and the like, according to the purpose. The solution may comprise an antioxidant, a viscosity control agent, and the like as an optional component according to the purpose.

A preferred thickness of each layer of the light-emitting device of the present invention varies depending on the type of the material and the layer configuration and is not limited. However, generally, excessively small thickness easily causes a defect such as a pinhole while excessively large thickness requires a high applied voltage, leading to low luminous efficiency. Thus, usually, the thickness is preferably several nm to 1 μm.

The application of the light-emitting device of the present invention is not limited. Examples thereof may include a planar light source, a light source for an illumination apparatus (or a light source), a light source for a sign, a light source for a backlight, a display device, and a printer head. The display device can be selected from structures of segment-type, dot matrix-type, and the like using a publicly known driving technology, driving circuit, and the like.

<Photoelectric Device>

The metal complex of the present invention can be used for the manufacture of a photoelectric device.

Examples of the photoelectric device may include a photoelectric conversion device. Specific examples thereof may include an element in which a layer comprising the metal complex of the present invention is provided between a pair of electrodes at least one of which is transparent or translucent and an element in which an interdigital electrode is formed on a layer comprising the metal complex of the present invention which is formed into a film on a substrate. For enhancing the characteristics of the photoelectric device, the film comprising the metal complex of the present invention may comprise fullerene, carbon nanotube, and the like.

Examples of the method for manufacturing the photoelectric conversion device may include a method disclosed in Japanese Patent No. 3146296. Specific examples thereof may include a method by forming a layer (film) comprising the metal complex of the present invention on a substrate having a first electrode and forming a second electrode on the layer, and a method by forming a layer (film) comprising the metal complex of the present invention on a pair of interdigital electrodes formed on a substrate. Either the first electrode or the second electrode is transparent or translucent.

Although the method for forming the layer (film) comprising the metal complex of the present invention and the method for mixing fullerene or carbon nanotube in the layer (film) are not limited, the methods exemplified with respect to the light-emitting device can be suitably utilized.

<Other Applications>

The metal complex of the present invention not only is useful for the manufacture of the light-emitting device, but also can be used, for example, as a semiconductor material such as an organic semiconductor material, a light-emitting material, an optical material, and a conductive material (for example, the metal complex is applied by doping). Accordingly, a film (that is, a film comprising the metal complex) such as a light-emitting film, a conductive film, and an organic semiconductor film can be manufactured using the metal complex.

The film of the present invention can provide a conductive film and a semiconductor film by the same method as the above method for manufacturing the light-emitting layer of the light-emitting device. Either larger one of the electron mobility and the hole mobility of the semiconductor film is preferably 10⁻⁵ cm²/V/sec or more. The semiconductor film (that may be called as an organic semiconductor film) can be suitably used for an organic solar cell, an organic transistor, and the like.

### EXAMPLES

Hereinafter, the present invention is described more in detail referring to examples which should not be construed as limiting the scope of the present invention.

### Comparative Example 1

### Synthesis of Compound (MC-C1)

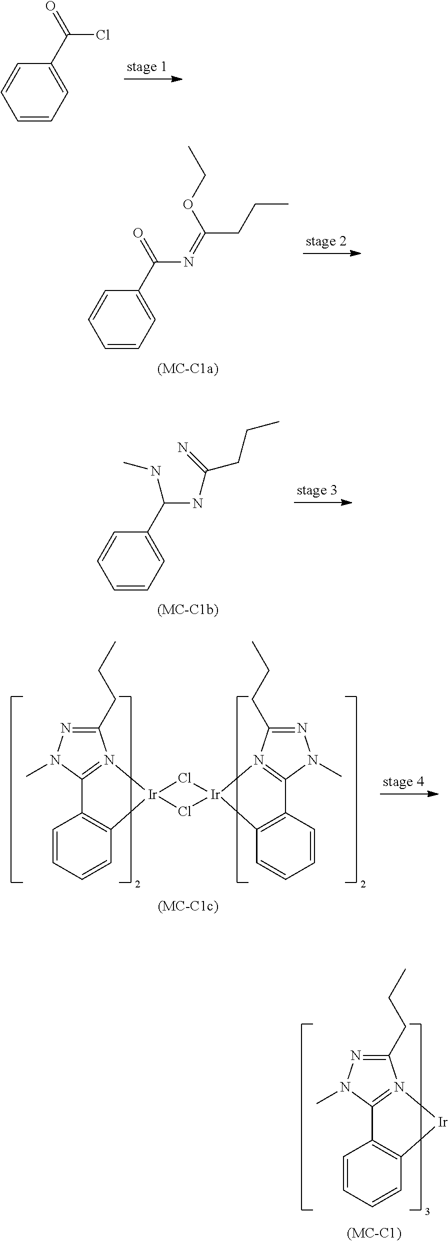

<Stage 1>

In a reaction vessel, 3 mL (26 mmol) of benzoyl chloride and 3.9 g (26 mmol) of ethyl butyrimidate hydrochloride were weighed and were dissolved in 300 mL of chloroform, and the resultant solution was placed under a nitrogen gas atmosphere. Then, into the solution, 25 mL of a chloroform solution of 7.2 mL (52 mmol) of triethylamine was added dropwise and the resultant reaction solution was stirred at room temperature under a nitrogen gas atmosphere. After 15 hours, chloroform as the solvent was concentrated and the concentrate was suspended in 200 mL of water, followed by extracting with dichloromethane. The resultant solution was concentrated under reduced pressure to give 5.3 g (24 mmol) of a compound (MC-C1a) as a light yellow liquid.

<Stage 2>

In a reaction vessel, 5.3 g (24 mmol) of the compound (MC-C1a) was dissolved in 200 mL of chloroform and the resultant solution was placed under a nitrogen gas atmosphere. Then, into the solution, 25 mL of a chloroform solution containing 1.2 mL (26 mmol) of methylhydrazine and 0.5 mL of water was added dropwise at room temperature under a nitrogen gas atmosphere. After the dropwise addition, the resultant reaction solution was stirred at room temperature under a nitrogen gas atmosphere for 15 hours and 100 mL of water was added to the reaction solution to quench the reaction. Then, the reaction solution was transferred into a separatory funnel and was washed with water, followed by recovering and concentrating the resultant oil phase. The resultant crude product was passed through a silica gel column to purify using a mixed solvent of dichloromethane-ethyl acetate. The obtained eluate was concentrated to give 2.9 g of a compound (MC-C1b) as a colorless liquid in a yield of 60%. The result of the ¹H-NMR analysis of the compound is shown below.

¹H-NMR (400 MHz/CDCl₃): δ (ppm)=7.75 (m, 3H), 7.66 (m, 2H), 3.93 (s, 3H), 2.73 (t, 2H), 1.82 (hex, 2H), 1.02 (t, 3H).

<Stage 3>

In a reaction vessel, 350 mg (1.0 mmol) of iridium chloride and 440 mg (2.2 mmol) of the compound (MC-Clb) were weighed and thereto, 10 mL of 2-ethyloxyethanol and 5 mL of water were added. The resultant reaction mixture was placed under a nitrogen gas atmosphere and was heated to reflux for 15 hours. The reaction mixture was allowed to cool down and the reaction solvent was concentrated. To the resultant residue, water and dichloromethane were added to wash the resultant oil phase with water. The oil phase was recovered and was concentrated and dried to give 660 mg of a compound (MC-C1c) as a yellow oily substance.

<Stage 4>

In a reaction vessel, 625 mg (0.5 mmol) of the compound (MC-C1c) and 1.0 g (5.0 mmol) of the compound (MC-C1b) were weighed and thereto, 260 mg of silver trifluoromethanesulfonate was added, followed by placing the resultant reaction mixture under an argon gas atmosphere. Then, the reaction mixture was heated for reaction at 165° C. for 15 hours and was allowed to cool down, and thereto, 15 mL of dichloromethane was poured. The resultant suspension was subjected to suction filtration and the resultant crude product was passed through a silica gel column to separate and purify using a mixed solvent of dichloromethane-ethyl acetate to give 630 mg of a compound (MC-C1) [fac-tris(1-methyl-3-propyl-5-phenyl-1H-[1,2,4]-triazolato-N,C2′)iridium(III)] as a yellow powder in a yield of 80%. The result of the ¹H-NMR analysis of the compound is shown below.

¹H-NMR (400 MHz/CDCl₃): δ (ppm)=7.50 (d, 3H), 6.88 (t, 3H), 6.80 (t, 3H), 6.63 (d, 3H), 4.11 (s, 9H), 2.18 (hep, 3H), 1.87 (hep, 3H), 1.38-1.30 (m, 3H), 1.18-1.10 (m, 3H), 0.68 (t, 9H).

### Comparative Example 2

### Synthesis of Compound (MC-C2)

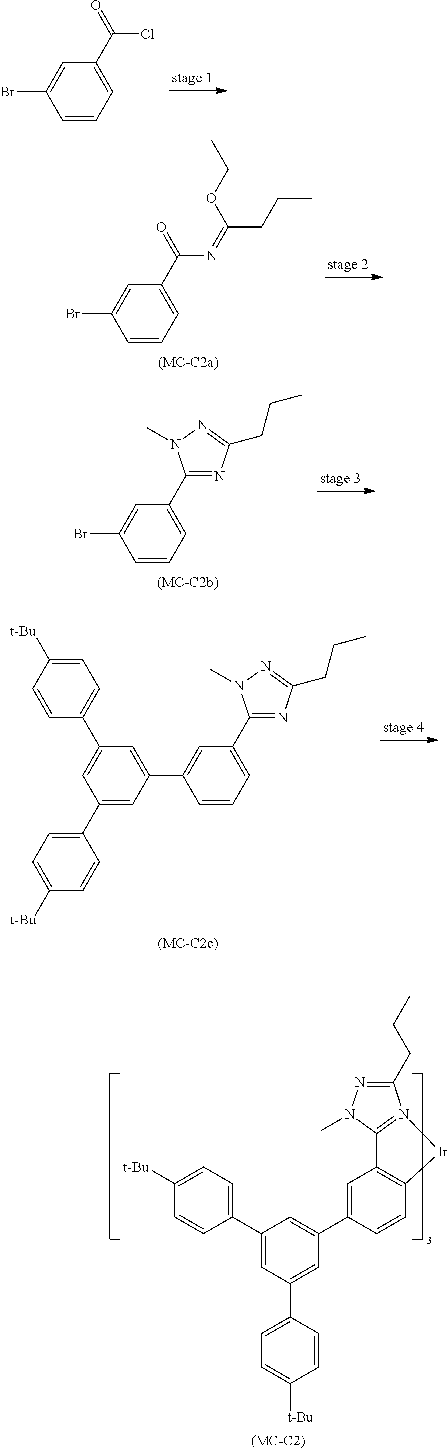

<Stage 1>

In a reaction vessel, 6.92 g (31.5 mmol) of 3-bromobenzoyl chloride and 4.95 g (32.6 mmol) of ethyl butyrimidate hydrochloride were weighed and thereto, 150 mL of chloroform was added, followed by placing the resultant reaction mixture under a nitrogen gas atmosphere. Then, into the mixture, 20 mL of a chloroform solution containing 8.0 mL (60 mmol) of triethylamine was added dropwise and the resultant mixture was stirred at room temperature under a nitrogen gas atmosphere for 15 hours. The reaction solution was concentrated and the concentrate was suspended in dichloromethane. The resultant suspension was charged into a separatory funnel and washed. The resultant oil phase was concentrated and dried to give 9.47 g of a compound (MC-C2a) as a colorless liquid. The result of the ¹H-NMR analysis of the compound is shown below.

¹H-NMR (400 MHz/CDCl₃): δ (ppm)=8.14 (t, 1H), 7.93 (dd, 1H), 7.65-7.63 (m, 1H), 7.31 (t, 1H), 4.29 (q, 2H), 2.36 (t, 2H), 1.60 (td, 2H), 1.37 (t, 3H), 0.88 (t, 3H).

<Stage 2>

In a reaction vessel, 9.0 g (30 mmol) of the compound (MC-C2a) was dissolved in 100 mL of chloroform and the resultant solution was placed under a nitrogen gas atmosphere. Then, into the solution, 15 mL of a chloroform solution containing 1.52 g (33 mmol) of methylhydrazine and 0.6 mL of water was added dropwise and the resultant reaction solution was stirred at room temperature under a nitrogen gas atmosphere for 7 hours. To the resultant reaction solution, 100 mL of water was poured and the resultant reaction mixture was charged into a separatory funnel and was washed. The resultant oil phase was recovered and concentrated. The concentrate was passed through a silica gel column to separate and purify using a mixed solvent of dichloromethane-ethyl acetate to give 5.8 g (21 mmol) of a compound (MC-C2b) as a light yellow liquid in a yield of 69%. The result of the ¹H-NMR analysis of the compound is shown below.

¹H-NMR (400 MHz/CDCl₃): δ (ppm)=7.85 (d, 1H), 7.60 (m, 2H), 7.37 (dd, 1H), 3.93 (s, 3H), 2.72 (t, 2H), 1.81 (m, 2H), 1.01 (t, 3H).

<Stage 3>

In a reaction vessel, 1.3 g (4.6 mmol) of the compound (MC-C2b), 2200 mg (4.7 mmol) of 3,5-di(4-tert-butylphenyl)phenylboronic acid pinacol ester, and 1250 mg (11.6 mmol) of sodium carbonate were weighed, and thereto, 5 mL of ethanol, 10 mL of water, and 10 mL of toluene were added, followed by placing the resultant reaction mixture under a nitrogen gas atmosphere. Then, to the reaction mixture, 260 mg (0.23 mmol) of tetrakis-triphenylphosphino palladium (0) was added and the resultant reaction mixture was placed under a nitrogen gas atmosphere again. The reaction mixture was heated at 80° C. for 15 hours. The reaction mixture was allowed to cool down, and water and toluene were poured to the reaction mixture to wash it. The resultant oil phase was recovered and concentrated. The resultant crude product was passed through a silica gel column to separate and purify using a mixed solvent of dichloromethane-ethyl acetate to give 2.18 g (4.0 mmol) of a compound (MC-C2c) as a white powder in a yield of 88%. The result of the ¹H-NMR analysis of the compound is shown below.

¹H-NMR (400 MHz/((CD₃)₂CO): δ (ppm)=8.19 (t, 1H), 7.98 (dt, 1H), 7.93 (d, 2H), 7.91 (t, 1H), 7.80 (t, ¹H), 7.77 (dt, 4H), 7.66 (t 1H), 7.54 (dt, 4H), 4.01 (s, 3H), 2.63 (t, 2H), 1.76 (td, 2H), 1.36 (s, 18H), 0.98 (t, 3H).

<Stage 4>

In a reaction vessel, 226 mg (0.64 mmol) of iridium chloride and 760 mg (1.4 mmol) of the compound (MC-C2c) were weighed and thereto, 2 mL of water and 6 mL of 2-butoxyethanol were added, followed by placing the resultant reaction mixture under a nitrogen gas atmosphere and heating to reflux the reaction mixture for 17 hours. The reaction mixture was allowed to cool down, and water and dichloromethane were poured to the reaction mixture to wash the oil phase. The resultant oil phase was concentrated and dried to give 840 mg of a yellowish-brown amber color solid.

In another reaction vessel, 840 mg of the yellowish-brown amber color solid and 1300 mg (2.4 mmol) of the compound (MC-C2c) were weighed and these substances were placed under an argon gas atmosphere, followed by adding 165 mg (0.64 mmol) of silver trifluoromethanesulfonate to these substances. Then, thereto, 1.25 mL of diethylene glycol dimethyl ester was added and the resultant reaction mixture was heated to reflux under an argon gas atmosphere for 15 hours. The reaction mixture was allowed to cool down and thereto, dichloromethane was poured, followed by subjecting the resultant suspension to suction filtration. The resultant filtrate was charged into a separatory funnel and was washed. The resultant oil phase was recovered and concentrated. The resultant crude product was passed through a silica gel column to separate and purify using a mixed solvent of dichloromethane-ethyl acetate. The obtained yellow solid was recrystallized from a mixed solvent of dichloromethane-methanol and next, was recrystallized from a mixed solvent of dichloromethane-hexane to give 850 mg (0.48 mmol) of a compound (MC-C2)[fac-tris(1-methyl-3-propyl-5-(5-(3,5-di(4-tert-butylphenyl)phenyl)phenyl)-1H-[1,2,4]-triazolato-N,C2′) iridium (III)] as a yellow powder in a yield of 73%. The result of the ¹H-NMR analysis of the compound is shown below.

¹H-NMR (400 MHz/CDCl₃): δ (ppm)=7.82 (d, 3H), 7.75 (d, 6H), 7.72 (d, 3H), 7.62 (d, 12H), 7.48 (d, 12H), 7.20 (dd, 3H), 6.87 (d, 3H), 4.27 (s, 9H), 2.26 (ddd, 3H), 1.96 (ddd, 3H), 1.37 (s, 54H), 1.05 (m, 6H), 0.73 (t, 9H).

### Comparative Example 3

### Synthesis of Compound (MC-C3)

The compound (MC-C3) was synthesized by the method shown below.

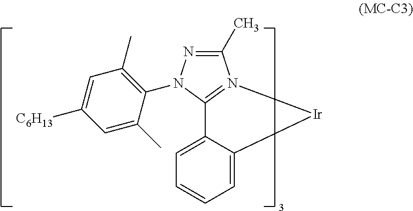

<Stage 1> Synthesis of Compound (C3-1b)

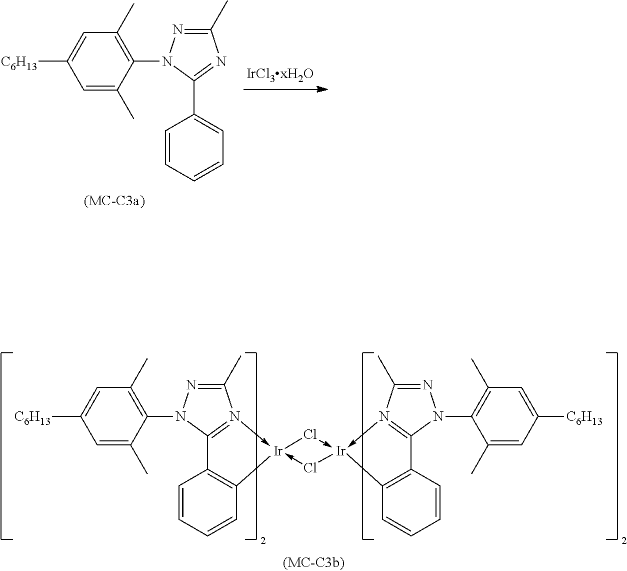

In a reaction vessel, 23.1 g of iridium chloride and 50 g of the compound (MC-C3a) were weighed and these compounds were suspended in a mixed solvent of 500 mL of 2-ethoxyethanol and 170 mL of water. Nitrogen gas was purged to the resultant reaction mixture for 1 hour and the reaction mixture was then heated and stirred using an oil bath preheated to 125° C. for 14 hours. The reaction mixture was allowed to cool down and water was added to the reaction mixture, followed by subjecting the reaction mixture to suction filtration. The filter residue was washed with water and methanol. This yellow green filter residue was vacuum-dried to give 56 g of the objective compound (MC-C3b). The yield of the compound was 92%.

<Stage 2> Synthesis of Compound (MC-C3)

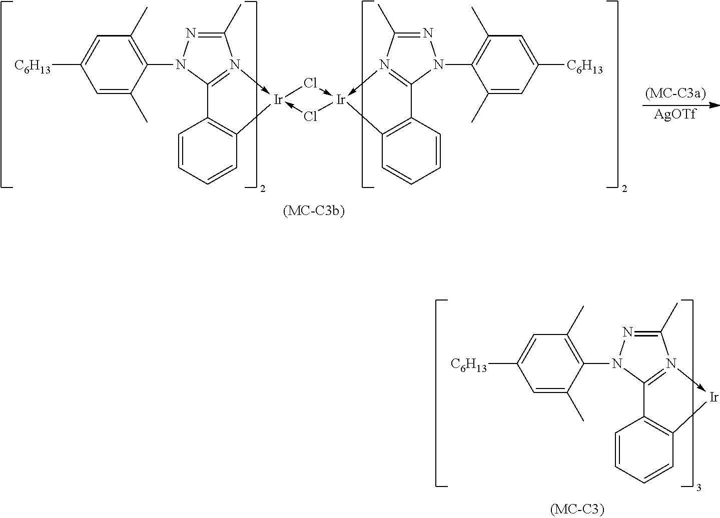

In a reaction vessel, 25 g of the compound (MC-C3b) and 11.8 g of the compound (MC-C3a) were suspended in diethylene glycol dimethyl ether. Nitrogen gas was purged to the resultant reaction mixture for 1 hour, and then 7.2 g of silver trifluoromethanesulfonate was added to the reaction mixture, followed by effecting the reaction at 150° C. for 22 hour under shaded condition. After the complete progression of the reaction was confirmed by thin layer chromatography, the heating was stopped and the reaction mixture was allowed to cool down. The resultant reaction mixture was subjected to suction filtration to remove a silver compound, and the filtrate was then distilled under reduced pressure to remove the reaction solvent. The crude product as the resultant residue was subjected to column chromatography to be eluted using a mixed solvent of ethyl acetate-hexane. Then, recrystallization from a mixed solvent of dichloromethane and methanol was performed to give 14.6 g of the objective compound (MC-C3) in a yield of 44%. For further purification, preparative high performance liquid chromatography (HPLC) was used and purification was performed using a mixed solvent of tetrahydrofuran and acetonitrile. The result of the ¹H-NMR analysis of the compound is shown below.

¹H-NMR (400 MHz/CDCl₃): δ (ppm)=7.83 (3H, d), 7.76 (6H, s), 7.73 (3H, s), 7.63 (12H, d), 7.49 (12H, d), 7.21 (3H, dd), 6.88 (3H, d), 4.28 (9H, s), 2.25 (3H, m), 1.98 (3H, m), 1.4-1.5 (57H, m), 1.23 (3H, m), 0.74 (9H, t).

### Example 1

### Synthesis of Compound (MC-1)

The compound (MC-1) was synthesized by the method below.

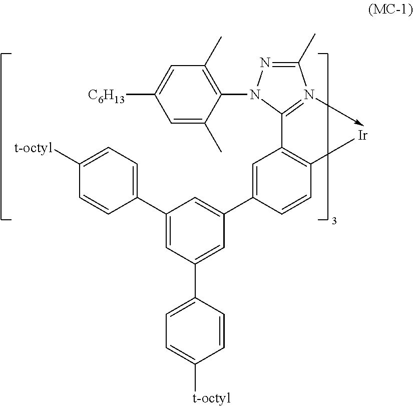

<Stage 1> Synthesis of Compound (1-1)

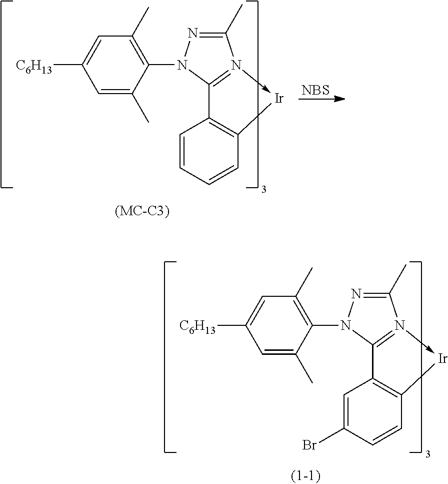

In a reaction vessel, 10 g of the compound (MC-C3) was weighed, was placed under a nitrogen gas atmosphere, and was dissolved in 150 mL of dichloromethane. Then, to the resultant solution, 4.1 g of N-bromosuccinimide was added and the resultant reaction mixture was stirred at room temperature for 24 hours under shaded condition. Then, 75% objective product and 25% dibromo-intermediate were confirmed by the HPLC analysis. To the obtained reaction mixture, 350 mg of N-bromosuccinimide was added and the reaction mixture was stirred further for 16 hours. Then, 97% objective product and about 0.5% dibromo-intermediate were confirmed by the HPLC analysis. To the obtained reaction mixture, 6 mg of N-bromosuccinimide was added and the resultant reaction mixture was stirred further for 4 hours. Then, to the reaction mixture, hot water was added, and the resultant reaction mixture was stirred for 10 minutes and was then subjected to phase separation operation to recover the oil phase. The obtained oil phase was filtered with Celite to remove impurities and was then washed with dichloromethane. The resultant filtrate was concentrated to about 30 mL and methanol was added to the concentrate to deposit a precipitate. The obtained precipitate was subjected to suction filtration and 11.2 g of the objective compound (1-1) was obtained in a yield of 96% and in an HPLC purity of about 98%. The result of the ¹H-NMR analysis of the compound is shown below.

¹H-NMR (400 MHz/CDCl₃): δ (ppm)=7.08 (3H, s), 7.04 (3H, s), 6.75 (3H, dd), 6.41 (3H, d), 6.37 (3H, d), 2.65 (6H, t), 2.13 (9H, s), 2.06 (9H, s), 1.77 (9H, s), 1.63-1.67 (6H, m), 1.31-1.36 (18H, m), 0.89 (9H, t).

<Stage 2> Synthesis of Compound (MC-1)

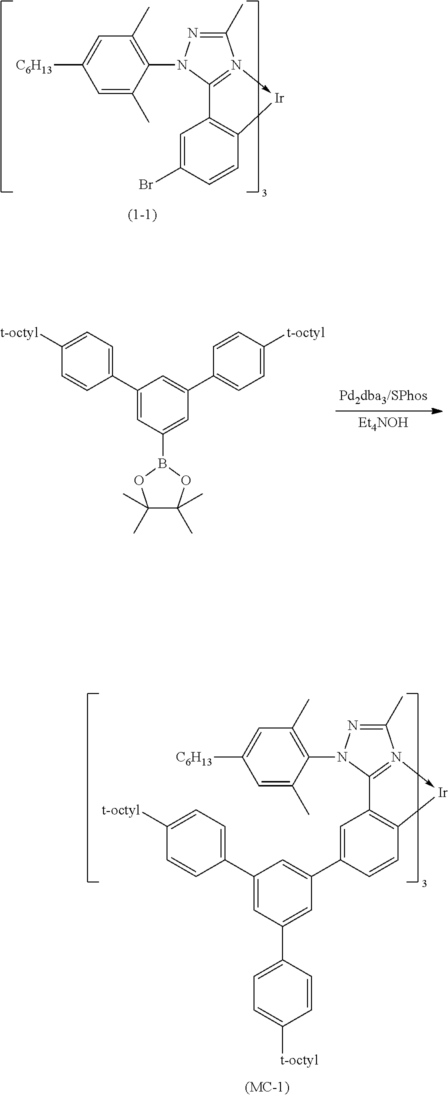

In a reaction vessel, 11 g of the compound (1-1) and 17.4 g of 3,5-bis(4-tert-octylphenyl)phenylboronic acid pinacol ester were weighed and these compounds were dissolved in 290 mL of toluene. Nitrogen gas was purged to the resultant solution for 1 hour, and then, to the solution, an additionally prepared toluene solution in which 135 mg of 2-dicyclohexylphosphino-2′,6′-dimethoxybiphenyl (SPhos) and 150 mg of tris(dibenzylidene)dipalladium were dissolved and to which nitrogen gas was purged, was added. To the resultant reaction mixture, 57 mL of a 20% aqueous tetraethylammonium hydroxide solution was added, and then the reaction mixture was heated for 18 hours using an oil bath preheated to 105° C. After the complete progression of the reaction was confirmed by thin layer chromatography, the heating was stopped and the resultant reaction solution was allowed to cool down. The resultant reaction solution was transferred into a separatory funnel and the aqueous phase was extracted with toluene. The resultant oil phase was dried over magnesium sulfate and was concentrated. The resultant orange crude product was subjected to column chromatography to separate and purify using a mixed solvent of ethyl acetate-hexane. Then, further, recrystallization from a mixed solvent of dichloromethane and methanol was performed to give 11.2 g of the objective compound (MC-1) in a yield of 58% and in an HPLC purity of 99% or more. The result of the ¹H-NMR analysis of the compound is shown below.

¹H-NMR (400 MHz/CDCl₃): δ (ppm)=7.66 (3H, s), 7.53 (12H, d), 7.42-7.46 (18H, m), 7.12 (3H, dd), 7.09 (3H, s), 7.02 (3H, s), 6.90 (3H, s), 6.76 (3H, d), 2.42 (6H, t), 2.56 (9H, s), 2.21 (9H, s), 1.92 (9H, s), 1.79 (12H, s), 1.48 (6H, m), 1.43 (36H, s), 1.23 (18H, m), 0.85 (9H, t), 0.76 (54H, s).

### Example 2

### Synthesis of Compound (MC-2)

The compound (MC-2) was synthesized by the method below.

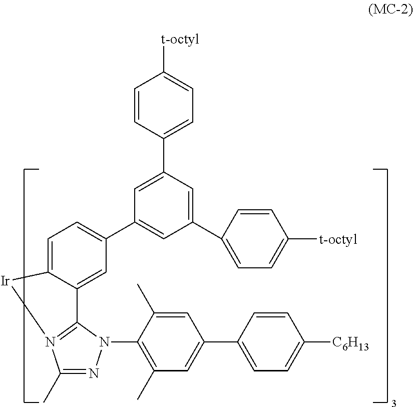

### Compound (MC-2)

<Stage 1> Synthesis of Compound (2-1)

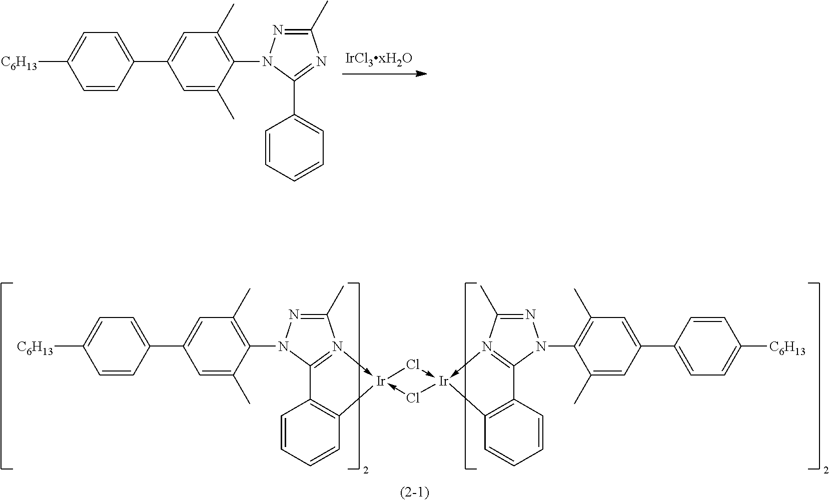

The compound (2-1) was obtained by the same synthesis method as that for the synthesis of the compound (MC-C3). More precisely, Synthesized from 15.9 g of 1-(4′-(4″-hexylphenyl)-2′,6′-dimethylphenyl)-3-methyl-5-phenyl-1,2,4-triazole and 6 g of iridium chloride hydrate using 220 mL of 2-ethoxyethanol and 75 mL of water as reaction solvents gave 17.6 g of the compound (2-1). The yield was 97%.

<Stage 2> Synthesis of Compound (2-2)

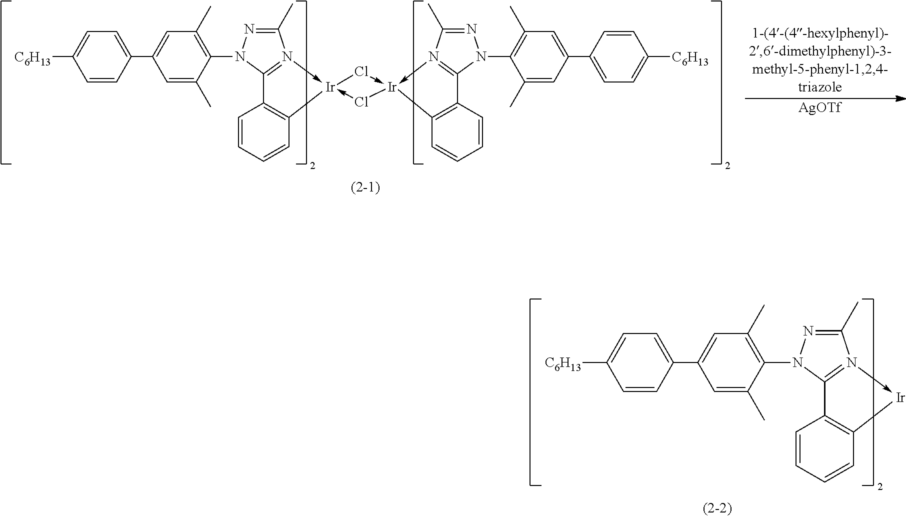

The compound (2-2) was obtained by the same synthesis method as that for the synthesis of the compound (MC3-C32). More precisely, 15.6 g of the above compound (2-1) and 8.6 g of 1-(4′-(4″-hexylphenyl)-2′,6′-dimethylphenyl)-3-methyl-5-phenyl-1,2,4-triazole were suspended in 250 mL of diethylene glycol dimethyl ether and to the resultant suspension, 3.9 g of silver trifluoromethanesulfonate was added, followed by effecting the reaction. The crude product was subjected to column chromatography to separate and purify using ethyl acetate-hexane as a solvent. Then, recrystallization from a mixed solvent of dichloromethane and methanol was performed to give 3.5 g of the objective compound (2-2) in an HPLC purity of 98% or more and in a yield of 16%. The result of the ¹H-NMR analysis of the compound is shown below.

¹H-NMR (400 MHz/CDCl₃): δ (ppm)=7.59 (6H, d), 7.49 (3H, s), 7.43 (3H, s), 7.29 (6H, d), 6.67-6.70 (3H, m), 6.58-6.61 (6H, m), 6.54 (3H, d), 2.67 (6H, t), 2.26 (9H, s), 2.14 (9H, s), 1.90 (9H, s), 1.64-1.69 (6H, m), 1.31-1.39 (18H, m), 0.90 (9H, t).

<Stage 3> Synthesis of Compound (2-3)

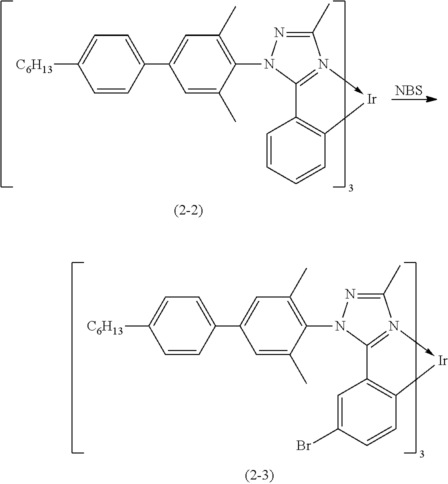

The compound (2-3) was obtained by the synthesis method for the compound (C₃₋₃). More precisely, in a reaction vessel, 2.3 g of the compound (2-2) was weighed, and from 2.3 g of the compound (2-2), 30 mL of dichloromethane, and 2.5 g of N-bromosuccinimide, 2.85 g of the objective compound (2-3) was synthesized in an HPLC purity of 98% or more and in a yield of 96%.

<Stage 4> Synthesis of Compound (MC-2)

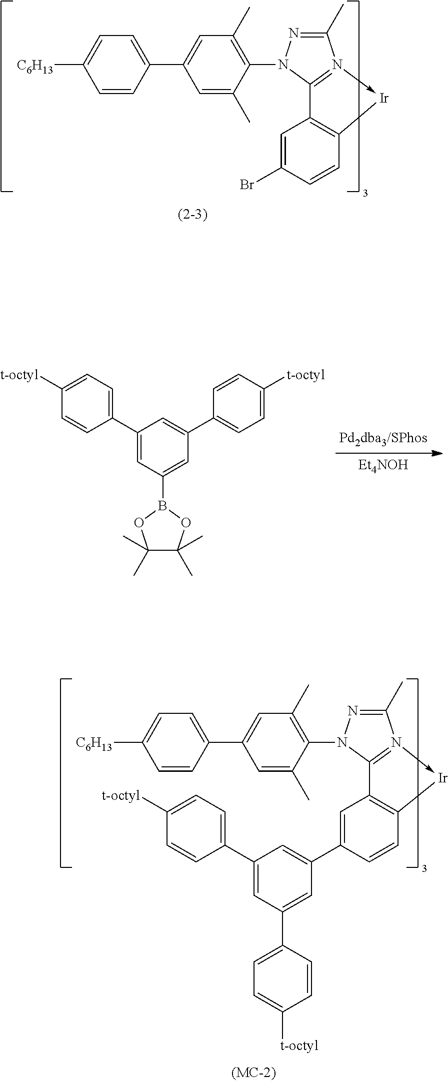

The compound (MC-2) was obtained by the synthesis method for the compound (MC-1). More precisely, in a reaction vessel, the reaction was effected using 2.8 g of the compound (2-3), 3.9 g of 3,5-bis(4-tert-octylphenyl)phenylboronic acid pinacol ester, and 70 mL of toluene, and using as catalysts, 27 mg of 2-dicyclohexylphosphino-2′,6′-dimethoxybiphenyl and 30 mg of tris(dibenzylidene)dipalladium, and using as a base, 15 mL of a 20 wt % aqueous tetraethylammonium hydroxide solution. The crude product was subjected to column chromatography to be separated and purified using a mixed solvent of ethyl acetate, hexane, and toluene. Recrystallization from a mixed solvent of dichloromethane and acetonitrile was performed to give the objective compound (MC-2) in an HPLC purity of 99% or more. As a further purification method, preparative HPLC using as a solvent, tetrahydrofuran and acetonitrile, was performed and the objective compound was obtained in a yield of 73%. The result of the ¹H-NMR analysis of the compound is shown below.

¹H-NMR (400 MHz/CDCl₃): δ (ppm)=7.56 (6H, d), 7.52 (6H, d), 7.49 (3H, s), 7.43 (6H, s), 7.38 (12H, d), 7.25 (6H, s), 7.15-7.18 (18H, m), 6.80 (3H, d), 2.65 (6H, t), 2.34 (9H, s), 2.25 (9H, s), 2.02 (9H, s), 1.71 (12H, s), 1.63-1.68 (6H, m), 1.33-1.39 (54H, m), 0.90 (0H, t), 0.71 (54H, s).

### Example 3

### Synthesis of Fac-tris-(1-(4-(3,5-di(4-tert-butylphenyl)phenyl)-2,6-dimethyl)phenyl-3-propyl-5-(3-(3,5-di(4-tert-butylphenyl)phenyl)phenyl)-1H-[1,2,4]-triazolato-N,C2′)iridium(III) (MC-3)

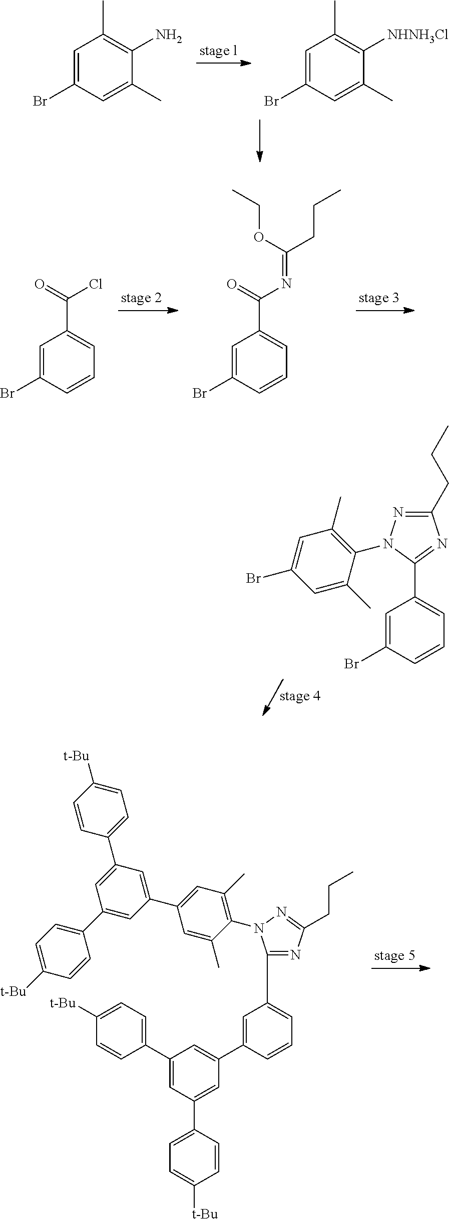

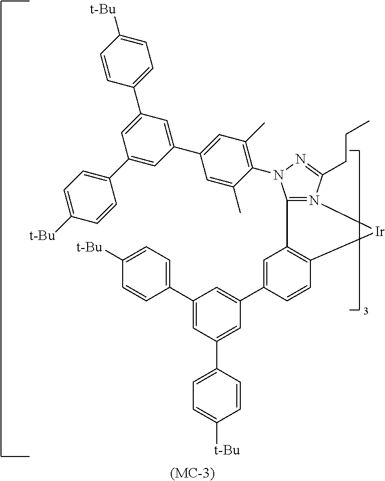

<Stage 1>

In a reaction vessel, 1.38 g (20 mmol) of sodium nitrite was weighed and was dissolved in 11 mL of 0° C. water under a nitrogen gas atmosphere. Then, a suspension prepared by suspending 4.0 g (20 mmol) of 4-bromo-2,6-dimethylaniline in 33 mL of concentrated hydrochloric acid was added dropwise into the resultant aqueous sodium nitrite solution at a temperature in a range of not more than 5° C. Then, the resultant reaction mixture was stirred at 0° C. for 15 minutes and 15 mL of a concentrated hydrochloric acid solution of 5.31 g (28 mmol) of tin(II) chloride was added to the resultant reaction solution. The temperature of the reaction solution was returned to room temperature and the reaction solution was stirred for 6 hours. The resultant suspension was subjected to suction filtration and the filter residue was washed with concentrated hydrochloric acid and cold water and was vacuum-dried to give 4.98 g of 4-bromo-2,6-dimethylphenylhydrazine hydrochloride as a milky white solid.

<Stage 2>

In a reaction vessel, 6.92 g (31.5 mmol) of 3-bromobenzoyl chloride and 4.95 g (32.6 mmol) of ethyl butyrimidate hydrochloride were weighed, and thereto, 150 mL of chloroform was added. The resultant solution was then placed under a nitrogen gas atmosphere. Then, into the solution, 20 mL of a chloroform solution containing 8.0 mL (60 mmol) of triethylamine was added dropwise and the resultant reaction mixture was stirred at room temperature under a nitrogen gas atmosphere for 15 hours. The resultant reaction solution was concentrated and was suspended in dichloromethane, and the resultant suspension was charged into a separatory funnel, followed by being washed with water. The resultant oil phase was concentrated and dried to obtain 9.47 g of ethyl N-(3-bromobenzoyl)butyrimidate as a colorless liquid. The result of the ¹H-NMR analysis of the compound is shown below.

¹H-NMR (400 MHz/CDCl₃): δ (ppm)=8.14 (t, 1H), 7.93 (dd, 1H), 7.65-7.63 (m, 1H), 7.31 (t, 1H), 4.29 (q, 2H), 2.36 (t, 2H), 1.60 (td, 2H), 1.37 (t, 3H), 0.88 (t, 3H).

<Stage 3>

In a reaction vessel, 1.26 g (5.0 mmol) of 4-bromo-2,6-dimethylphenylhydrazine hydrochloride, 1.19 g (4.0 mmol) of ethyl N-(3-bromobenzoyl)butyrimidate, and 410 mg (5.0 mmol) of sodium acetate were weighed, and thereto, 8 mL of acetic acid and 8 mL of dioxane were added, followed by placing the resultant reaction mixture under a nitrogen gas atmosphere. The resultant reaction mixture was heated at 90° C. for 15 hours and was allowed to cool down. Then, thereto, toluene was added and the resultant mixture was subjected to suction filtration, followed by concentrating the filtrate. The resultant crude product was passed through a silica gel column to separate and purify using a mixed solvent of hexane-ethyl acetate to give 1.0 g (2.2 mmol) of 1-(4-bromo-2,6-dimethylphenyl)-3-propyl-5-(3-bromophenyl)-1H-[1,2,4]-triazole as a light yellow liquid in a yield of 56%. The result of the ¹H-NMR analysis of the compound is shown below.

¹H-NMR (400 MHz/(CD₃)₂CO): δ (ppm)=7.60 (dt, 1H), 7.49 (s, 2H), 7.34-7.27 (m, 3H), 2.74 (t, 2H), 1.95 (s, 6H), 1.83 (q, 2H), 0.99 (t, 3H).

<Stage 4>

In a reaction vessel, 990 mg (2.2 mmol) of 1-(4-bromo-2,6-dimethylphenyl)-3-propyl-5-(3-bromophenyl)-1H-[1,2,4]-triazole and 2.2 g (4.7 mmol) of 3,5-di(4-tert-butylphenyl)phenylboronic acid pinacol ester and 1.4 g (13 mmol) of sodium carbonate were weighed. Thereto, 5 mL of water and 15 mL of dioxane were added, followed by heating to reflux the resultant reaction mixture under a nitrogen gas atmosphere for 6 hours. The reaction mixture was allowed to cool down, and then thereto, toluene was added and the resultant mixture was subjected to suction filtration, followed by concentrating the filtrate. Then, to the resultant concentrate, water and toluene were added to wash the concentrate with water and the resultant oil phase was recovered and then concentrated. The resultant crude product was passed through a silica gel column to be separated and purified using a mixed solvent of chloroform-ethyl acetate. The obtained eluate was concentrated and the resultant concentrate was recrystallized from hexane to give 2.0 g (2.1 mmol) of 1-(4-(3,5-di(4-tert-butylphenyl)phenyl)-2,6-dimethyl)phenyl-3-propyl-5-(3-(3,5-di(4-tert-butylphenyl)phenyl)phenyl)-1H-[1,2,4]-triazole as a white solid in a yield of 94%. The result of the ¹H-NMR analysis of the compound is shown below.

¹H-NMR (400 MHz/CDCl₃): δ (ppm)=7.97 (s, 1H), 7.82 (s, 1H), 7.75-7.70 (m, 4H), 7.62-7.54 (m, 11H), 7.49-7.46 (m, 6H), 7.42 (d, 1H), 7.37 (d, 4H), 2.88 (t, 2H), 2.10 (s, 6H), 1.92 (td, 2H), 1.37 (s, 18H), 1.31 (s, 18H), 1.06 (t, 3H).

<Stage 5>

In a reaction vessel, 91 mg (0.26 mmol) of iridium chloride and 500 mg (0.52 mmol) of 1-(4-(3,5-di(4-tert-butylphenyl)phenyl)-2,6-dimethyl)phenyl-3-propyl-5-(3-(3,5-di(4-tert-butylphenyl)phenyl)phenyl)-1H-[1,2,4]-triazole were weighed. Thereto, 10 mL of water and 10 mL of 2-butoxyethanol were added, followed by heating to reflux the resultant reaction mixture under an argon gas atmosphere for 18 hours. The reaction mixture was allowed to cool down and thereto, water and methanol were poured, followed by subjecting a deposited precipitate to suction filtration. The obtained filter residue was dried to give 500 mg of a yellowish brown solid.

In another reaction vessel, 500 mg of the yellowish brown solid, 1.23 g (1.27 mmol) of 1-(4-(3,5-di(4-tert-butylphenyl)phenyl)-2,6-dimethyl)phenyl-3-propyl-5-(3-(3,5-di(4-tert-butylphenyl)phenyl)phenyl)-1H-[1,2,4]-triazole, and 67 mg (0.26 mmol) of silver trifluoromethanesulfonate were weighed. Thereto, 10 mL of diethylene glycol dimethyl ester was added, followed by heating to reflux the resultant reaction mixture under an argon gas atmosphere for 11 hours. The reaction mixture was allowed to cool down and thereto, toluene was poured, followed by subjecting the resultant mixture to suction filtration. The resultant filtrate was concentrated and the concentrate was passed through a silica gel column to separate and purify using a mixed solvent of toluene-hexane. The obtained eluate was concentrated and the resultant concentrate was recrystallized from a mixed solvent of toluene-hexane to give 420 mg (0.14 mmol) of fac-tris(1-(4-(3,5-di(4-tert-butylphenyl)phenyl)-2,6-dimethyl)phenyl-3-propyl-5-(3-(3,5-di(4-tert-butylphenyl)phenyl)phenyl)-1H-[1,2,4]-triazolato-N,C2′)iridium(III) as a yellow solid in powder form in a yield of 52%. The result of the ¹H-NMR analysis of the compound is shown below.

¹H-NMR (400 MHz/CDCl₃): δ (ppm)=7.85-7.82 (m, 9H), 7.64 (s, 3H), 7.70 (s, 3H), 7.58-7.52 (m, 15H), 7.39-7.46 (m, 30H), 7.23-7.13 (m, 18H), 6.82 (d, 3H), 2.55 (m, 6H), 2.41 (s, 9H), 2.05 (s, 9H), 1.86-1.73 (m, 6H), 1.36 (s, 54H), 1.19 (s, 54H), 0.88 (t, 9H).

### Preparation Example 1 of Light-Emitting Device

A light-emitting device having a structure below was prepared.

Anode/HIL/HTL/LEP/Cathode

In the above structure, the anode means ITO (indium tin oxide, 45 nm); HIL means a hole injection layer (35 nm); HTL means a hole transport layer (22 nm); LEP means a light-emitting layer (75 nm); and the cathode means a layer (2 nm) of sodium fluoride in contact with the light-emitting layer, a layer (100 nm) of aluminum formed on the sodium fluoride, and a layer (100 nm) of silver formed on the aluminum.

A substrate on which ITO (45 nm) was formed into a film was washed with UV ozone. The hole injection layer was formed into a film by: spin coating the substrate with an aqueous formulation (AQ-1200; manufactured by Plextronics Inc.) of a hole injection material to form a film having a thickness of 35 nm; and heating the formed film at 170° C. under the ambient atmosphere for 15 minutes. The hole transport layer was formed by: spin coating the hole injection layer with a solution prepared by dissolving a hole transport polymer described below in xylene so that the polymer has a concentration of 0.6% by weight to form a film having a thickness of 22 nm; and heating the formed film at 180° C. under a nitrogen gas atmosphere for 60 minutes to crosslink the hole transport polymer. The light-emitting layer was formed by: spin coating the hole transport layer with a solution prepared by dissolving a composition (metal complex/host polymer=64% by weight/36% by weight) of a metal complex and a host polymer described below in xylene so that the composition has a concentration of 1.7% by weight to form a film having a thickness of 75 nm; and heating the formed film at 80° C. under a nitrogen gas atmosphere for 10 minutes. Using a vacuum deposition method, the cathode was formed by: forming sodium fluoride into a film having a thickness of 2 nm as a first layer; forming aluminum into a film having a thickness of 100 nm as a second layer; and additionally forming silver into a film having a thickness of 100 nm as a third layer.

The hole transport polymer was obtained by polymerization using the monomers below by a Suzuki polymerization method disclosed in WO00/53656.

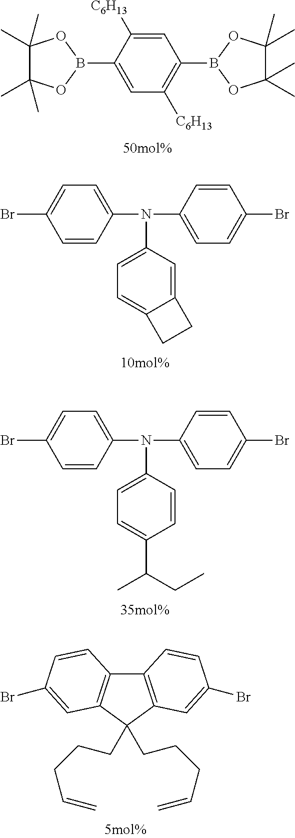

The polystyrene equivalent number average molecular weight Mn and the polystyrene equivalent weight average molecular weight Mw measured by gel permeation chromatography of the hole transport polymer, were Mn=42,000 and Mw=350,000.

The host polymer is disclosed in WO2011/141714 and was prepared by polymerizing the monomers below by a Suzuki polymerization method disclosed in WO00/53656.

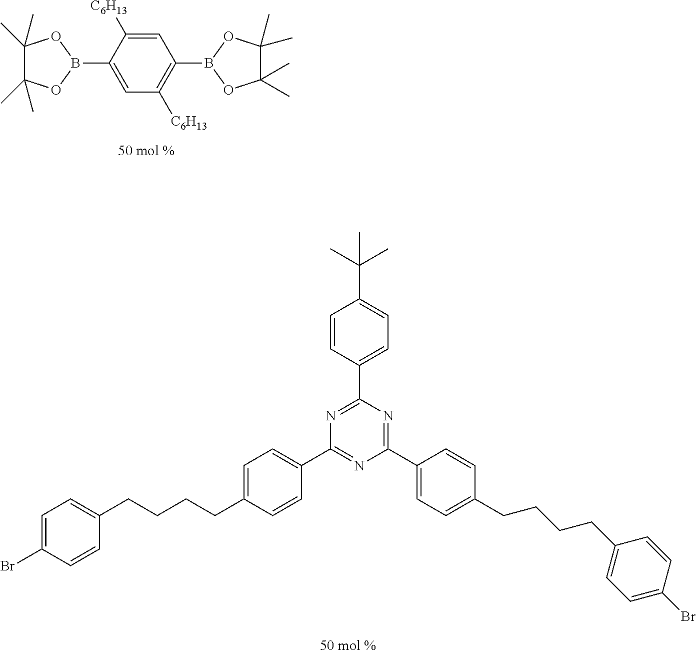

The polystyrene equivalent number average molecular weight Mn and the polystyrene equivalent weight average molecular weight Mw measured by gel permeation chromatography of the host polymer, were Mn=17,600 and Mw=235,000.

### Test Example 1 of Light-Emitting Device

Evaluation results of the light-emitting device are summarized in Table 1. A light-emitting device using a metal complex having both of (i) a phenyl ring having a dendron as a substituent and (ii) a triazole ring having an aryl group as a substituent, exhibited values of the external quantum yield (EQE) and the luminous efficiency (cd/A and 1 m/W) which were higher than the values exhibited by a light-emitting device using a metal complex having both of a phenyl ring having no dendron as a substituent and a triazole ring having no aryl group as a substituent.

TABLE 1

| | Characteristics of devices | | |
|---|---|---|---|
| | under the condition of 400 cd/m² | | |
| | EQE | Efficiency | Efficiency |
| Metal Complex | (%) | (cd/A) | (lm/W) |
| MC-C1 | 8.2 | 12.3 | 5.8 |
| (Comparative | | | |
| Example 1) | | | |
| MC-C2 | 16.0 | 27.6 | 13.9 |
| (Comparative | | | |
| Example 2) | | | |
| MC-C3 | 13.9 | 18.8 | 9.7 |
| (Comparative | | | |
| Example 3) | | | |
| MC-1 | 20.9 | 34.9 | 17.0 |
| (Example 1) | | | |
| MC-2 | 21.0 | 35.6 | 17.1 |
| (Example 2) | | | |
| MC-3 | 20.5 | 38.0 | 17.8 |
| (Example 3) | | | |

### Test Example 2 of Light-Emitting Device

Using the light-emitting device prepared in Preparation Example 1 of Light-emitting Device, further evaluations of element characteristics were performed. Table 2 shows the results thereof.

TABLE 2

Characteristics of
devices under the
condition of 400 cd/m²

| | Driving | |
|---|---|---|
| | Voltage | CIE |
| Metal Complex | (V) | (x, y) |
| MC-C1 | 7.0 | 0.153, 0.213 |
| (Comparative | | |
| Example 1) | | |
| MC-C2 | 6.3 | 0.142, 0.284 |
| (Comparative | | |
| Example 2) | | |
| MC-C3 | 6.2 | 0.144, 0.190 |
| (Comparative | | |
| Example 3) | | |
| MC-1 | 6.5 | 0.138, 0.276 |
| (Example 1) | | |
| MC-2 | 6.5 | 0.138, 0.287 |
| (Example 2) | | |
| MC-3 | 6.8 | 0.140, 0.32 |
| (Example 3) | | |

### Test Example 3 of Light-Emitting Device

Using the light-emitting device (the light-emitting device using a metal complex synthesized in any one of Examples 1 to 3) prepared in Preparation Example 1 of Light-emitting Device, after the current value was set so that the initial brightness became 400 cd/m², the brightness half-lifetime (LT50) was measured by driving the light-emitting device with a constant current. As a result, the light-emitting device using the metal complex obtained in the examples of the present invention exhibited excellent brightness half-lifetime (Table 3).

TABLE 3

| | LT50 |
|---|---|
| Metal Complex | (Hour) |
| MC-1 | 13.2 |
| (Example 1) | |
| MC-2 | 14.1 |
| (Example 2) | |
| MC-3 | 11.7 |
| (Example 3) | |

In this specification and the appended claims, the singular forms “a,” “an” and “the” include plural references unless the content clearly dictates otherwise.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A metal complex represented by Formula (1): 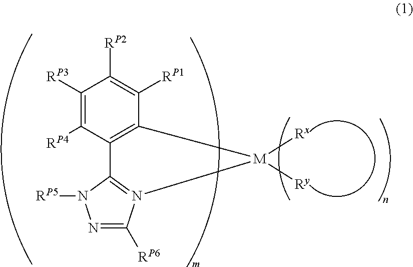
wherein
M represents a ruthenium atom, a rhodium atom, a palladium atom, an osmium atom, an iridium atom, or a platinum atom;
R^{P1}, R^{P2}, R^{P3}, R^{P4}, R^{P5}, and R^{P6} each independently represent a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, a carbamoyl group, an amido group, an acid imido group, an imine residue, a substituted amino group, a substituted silyl group, a substituted silyloxy group, a substituted silylthio group, a substituted silylamino group, a monovalent heterocyclic group, a heteroaryloxy group, a heteroarylthio group, an arylalkenyl group, an arylalkynyl group, a substituted carboxy group, or a cyano group, wherein R^{P1} and R^{P2} may be bonded to each other to form a ring structure together with carbon atoms to which R^{P1} and R^{P2} are individually bonded, R^{P2} and R^{P3} may be bonded to each other to form a ring structure together with carbon atoms to which R^{P2} and R^{P3} are individually bonded, and R^{P3} and R^{P4} may be bonded to each other to form a ring structure together with carbon atoms to which R^{P3} and R^{P4} are individually bonded, with the proviso that at least one of R^{P1}, R^{P2}, R^{P3}, and R^{P4} is a dendron and at least one of R^{P5} and R^{P6} is an aryl group or a monovalent heterocyclic group;
m is an integer of 1 to 3 and n is an integer of 0 to 2, wherein m+n is 2 or 3; and
a moiety represented by Formula (2) represents a bidentate ligand: 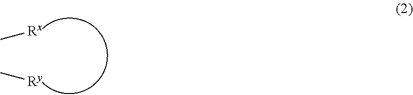
wherein R^{x} and R^{y} are atoms bonded to a metal atom M and each independently represent a carbon atom, an oxygen atom, or a nitrogen atom.

2. The metal complex according to claim 1, wherein at least one of R^{P1}, R^{P2}, R^{P3}, and R^{P4} is a dendron represented by Formula (D-1): 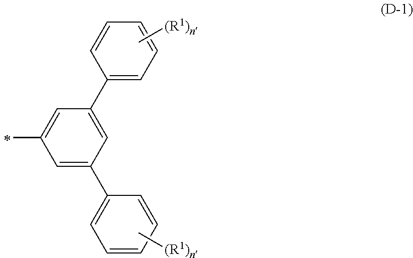
wherein
* represents a bond;
R¹ represents a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, a carbamoyl group, an amido group, an acid imido group, an imine residue, a substituted amino group, a substituted silyl group, a substituted silyloxy group, a substituted silylthio group, a substituted silylamino group, a monovalent heterocyclic group, a heteroaryloxy group, a heteroarylthio group, an arylalkenyl group, an arylalkynyl group, a substituted carboxy group, or a cyano group; and
n′ is an integer of 0 to 3 and two n's may be same as or different from each other.

3. The metal complex according to claim 1, wherein the metal complex represented by Formula (1) is a metal complex represented by Formula (1a) or (1b): 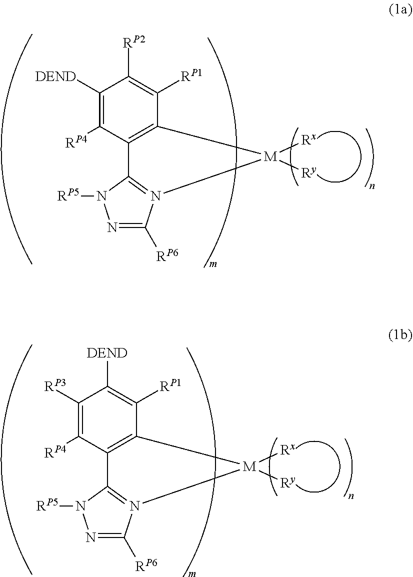
wherein
M, R^{P1}, R^{P2}, R^{P3}, R^{P4}, R^{P5}, R^{P6}, the moiety represented by Formula (2), R^{x}, R^{y}, m, and n are same as defined in claim 1; and
DEND represents a dendron].

4. The metal complex according to claim 1, wherein R^{P5} is an aryl group.

5. The metal complex according to claim 4, wherein R^{P5} is a phenyl group comprising an alkyloxy group with the number of carbon atom(s) of 1 to 12 as a substituent, or a phenyl group comprising an alkyl group with the number of carbon atom(s) of 1 to 12 as a substituent.

6. The metal complex according to claim 1, wherein n is 0.

7. The metal complex according to claim 1, wherein M is an iridium atom or a platinum atom.

8. A composition comprising:
the metal complex according to claim 1; and
a charge transport material.

9. The composition according to claim 8, wherein the charge transport material is a polymer organic compound.

10. A composition comprising:
the metal complex according to claim 1; and
a solvent or a dispersion medium.

11. A film comprising:
the metal complex according to claim 1.

12. A light-emitting device comprising:
electrodes including an anode and a cathode; and
a layer that is provided between the electrodes and that contains the metal complex according to claim 1.

13. A planar light source comprising:
the light-emitting device according to claim 12.

14. An illumination apparatus comprising:
the light-emitting device according to claim 12.
